(19) United States
(12) Patent Application Publication
(10) Pub. No.: US 2024/0276834 A1
(43) Pub. Date: Aug. 15, 2024

(54) Display Device, Method For Manufacturing Display Device, Display Module, and Electronic Device

(71) Applicant: Semiconductor Energy Laboratory Co., Ltd., Kanagawa-ken (JP)

(72) Inventors: Ryota HODO, Atsugi, Kanagawa (JP); Yuichi YANAGISAWA, Atsugi, Kanagawa (JP); Nobuharu OHSAWA, Zama, Kanagawa (JP); Shunpei YAMAZAKI, Setagaya, Tokyo (JP)

(73) Assignee: Semiconductor Energy Laboratory Co., Ltd., Kanagawa-ken (JP)

(21) Appl. No.: 18/567,228

(22) PCT Filed: May 25, 2022
(86) PCT No.: PCT/IB2022/054865

§ 371 Date: Dec. 5, 2023

(30) Foreign Application Priority Data
Jun. 8, 2021 (JP) 2021-096127
Jun. 8, 2021 (JP) 2021-096128

(51) Int. Cl. H10K 59/00; H10K 59/12; H10K 59/124

(52) U.S. Cl. CPC H10K 59/771; H10K 59/1201; H10K 59/124

(57) ABSTRACT

A highly reliable display device is provided. The display device includes a first light-emitting element and a second light-emitting element adjacent to the first light-emitting element. The first light-emitting element includes a first pixel electrode, a first EL layer over the first pixel electrode, and a common electrode over the first EL layer, and the second light-emitting element includes a second pixel electrode, a second EL layer over the second pixel electrode, and the common electrode over the second EL layer. An end portion of the first pixel electrode and an end portion of the second pixel electrode each have a tapered shape. The first EL layer covers the end portion of the first pixel electrode, and the second EL layer covers the end portion of the second pixel electrode. The first EL layer includes a region with a thickness less than or equal to 150 nm.

### TECHNICAL FIELD

One embodiment of the present invention relates to a display device and a manufacturing method thereof. One embodiment of the present invention relates to a display module including a display device. One embodiment of the present invention relates to an electronic device including a display device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, display devices have been required to have higher resolution in order to display high-definition images. In addition, display devices used in information terminal devices such as smartphones, tablet terminals, and laptop PCs (personal computers) have been required to have lower power consumption as well as higher resolution. Furthermore, display devices have been required to have a variety of functions such as a function of a touch panel and a function of capturing images of fingerprints for authentication in addition to a function of displaying images.

Light-emitting apparatuses including light-emitting elements have been developed, for example, as display devices. Light-emitting elements (also referred to as EL elements) utilizing an electroluminescence (hereinafter referred to as EL) phenomenon have features such as ease of reduction in thickness and weight, high-speed response to an input signal, and driving with a direct-constant voltage source, and have been used in display devices. For example, Patent Document 1 discloses a flexible light-emitting apparatus including an organic EL element.

Non-Patent Document 1 discloses a method for manufacturing an organic optoelectronic device using standard UV photolithography.

### REFERENCES

### Patent Document

[Patent Document 1] Japanese Published Patent Application No. 2014-197522

### Non-Patent Document

[Non-Patent Document 1] B. Lamprecht et al., “Organic optoelectronic device fabrication using standard UV photolithography”. phys. stat. sol. (RRL) 2, No. 1, pp. 16-18 (2008).

### SUMMARY OF THE INVENTION

### Problems to be Solved by the Invention

An object of one embodiment of the present invention is to provide a highly reliable display device. Another object of one embodiment of the present invention is to provide an inexpensive display device. Another object of one embodiment of the present invention is to provide a high-resolution display device. Another object of one embodiment of the present invention is to provide a display device with a high aperture ratio. Another object of one embodiment of the present invention is to provide a high-definition display device. Another object of one embodiment of the present invention is to provide a novel display device.

Another object of one embodiment of the present invention is to provide a method for manufacturing a highly reliable display device. Another object of one embodiment of the present invention is to provide a method for manufacturing a display device with high yield. Another object of one embodiment of the present invention is to provide a method for manufacturing a high-resolution display device. Another object of one embodiment of the present invention is to provide a method for manufacturing a display device with a high aperture ratio. Another object of one embodiment of the present invention is to provide a method for manufacturing a high-definition display device. Another object of one embodiment of the present invention is to provide a method for manufacturing a novel display device.

Note that the description of these objects does not preclude the existence of other objects. Note that one embodiment of the present invention does not have to achieve all the objects. Note that other objects can be derived from the description of the specification, the drawings, the claims, and the like.

### Means for Solving the Problems

One embodiment of the present invention is a display device including a first light-emitting element and a second light-emitting element adjacent to the first light-emitting element. The first light-emitting element includes a first pixel electrode, a first EL layer over the first pixel electrode, and a common electrode over the first EL layer; the second light-emitting element includes a second pixel electrode, a second EL layer over the second pixel electrode, and the common electrode over the second EL layer; an end portion of the first pixel electrode and an end portion of the second pixel electrode each have a tapered shape; the first EL layer covers the end portion of the first pixel electrode; the second EL layer covers the end portion of the second pixel electrode; and the first EL layer includes a region where a thickness is less than or equal to 150 nm.

In the above embodiment, the first light-emitting element may include a common layer between the first EL layer and the common electrode; the second light-emitting element may include the common layer between the second EL layer and the common electrode; and a region where a distance between a top surface of the first pixel electrode and a bottom surface of the common layer is less than or equal to 150 nm may be included.

Another embodiment of the present invention is a display device including a first light-emitting element and a second light-emitting element adjacent to the first light-emitting element. The first light-emitting element includes a first pixel electrode, a first EL layer over the first pixel electrode, and a common electrode over the first EL layer; the second light-emitting element includes a second pixel electrode, a second EL layer over the second pixel electrode, and the common electrode over the second EL layer; an end portion of the first pixel electrode and an end portion of the second pixel electrode each have a tapered shape; the first EL layer covers the end portion of the first pixel electrode; the second EL layer covers the end portion of the second pixel electrode; and a region where a difference between a thickness of the first EL layer and a thickness of the second EL layer is less than or equal to 100 nm is included.

In the above embodiment, the first light-emitting element may include a common layer between the first EL layer and the common electrode; the second light-emitting element may include the common layer between the second EL layer and the common electrode; and a region where a difference between a distance between a top surface of the first pixel electrode and a bottom surface of the common layer and a distance between a top surface of the second pixel electrode and the bottom surface of the common layer is less than or equal to 100 nm may be included.

In each of the above embodiments, the common layer may include a carrier-injection layer.

In each of the above embodiments, an insulating layer may be provided in a region between the first EL layer and the second EL layer.

In the above embodiment, the insulating layer may contain an organic material.

In each of the above embodiments, a pixel portion and a connection portion may be included; the pixel portion may include the first light-emitting element and the second light-emitting element; the connection portion may include a connection electrode and the common electrode which is provided over the connection electrode and electrically connected to the connection electrode; a third EL layer may be provided in a region between the pixel portion and the connection portion; and an end portion of the connection electrode and an end portion of the third EL layer may be covered with a protective layer.

One embodiment of the present invention is a display module including the display device of one embodiment of the present invention and at least one of a connector and an integrated circuit.

One embodiment of the present invention is an electronic device including the display module of one embodiment of the present invention and at least one of a battery, a camera, a speaker, and a microphone.

Another embodiment of the present invention is a method for manufacturing a display device, which includes forming a first pixel electrode and a second pixel electrode adjacent to the first pixel electrode such that their end portions have tapered shapes; forming a first EL film over the first and second pixel electrodes; forming a first sacrificial film over the first EL film; forming a first EL layer covering the end portion of the first pixel electrode and including a region where a thickness is less than or equal to 150 nm, and a first sacrificial layer over the first EL layer by processing the first EL film and the first sacrificial film; forming a second EL film over the first sacrificial layer and over the second pixel electrode; forming a second sacrificial film over the second EL film; forming a second EL layer covering the end portion of the second pixel electrode, and a second sacrificial layer over the second EL layer by processing the second EL film and the second sacrificial film; removing at least a part of the first sacrificial layer and at least a part of the second sacrificial layer; and forming a common electrode over the first EL layer and over the second EL layer.

In the above embodiment, a common layer may be formed over the first EL layer and over the second EL layer after at least the part of the first sacrificial layer and at least the part of the second sacrificial layer are removed; the common electrode may be formed over the common layer; and a region where a distance between a top surface of the first pixel electrode and a bottom surface of the common layer is less than or equal to 150 nm may be included.

Another embodiment of the present invention is a method for manufacturing a display device, which includes forming a first pixel electrode and a second pixel electrode adjacent to the first pixel electrode such that their end portions have tapered shapes; forming a first EL film over the first and second pixel electrodes; forming a first sacrificial film over the first EL film; forming a first EL layer covering the end portion of the first pixel electrode, and a first sacrificial layer over the first EL layer by processing the first EL film and the first sacrificial film; forming a second EL film over the first sacrificial layer and over the second pixel electrode; forming a second sacrificial film over the second EL film; forming a second EL layer covering the end portion of the second pixel electrode and including a region where a difference from the thickness of the first EL layer is less than or equal to 100 nm, and a second sacrificial layer over the second EL layer by processing the second EL film and the second sacrificial film; removing at least a part of the first sacrificial layer and at least a part of the second sacrificial layer; and forming a common electrode over the first EL layer and over the second EL layer.

In the above embodiment, a common layer may be formed over the first EL layer and over the second EL layer after at least the part of the first sacrificial layer and at least the part of the second sacrificial layer are removed; the common electrode may be formed over the common layer; and a region where a difference between a distance between a top surface of the first pixel electrode and a bottom surface of the common layer and a distance between a top surface of the second pixel electrode and the bottom surface of the common layer is less than or equal to 100 nm may be included.

In each of the above embodiments, the common layer may include a carrier-injection layer.

In each of the above embodiments, an insulating layer may be formed in a region between the first EL layer and the second EL layer after the first and second sacrificial layers are formed but before at least the parts of the first and second sacrificial layers are removed.

In the above embodiment, the insulating layer may be formed using a spin coating method, a spraying method, a screen printing method, or a painting method.

In each of the above embodiments, a conductive film may be formed; the first pixel electrode, the second pixel electrode, and a connection electrode may be formed by processing the conductive film such that their end portions have tapered shapes; the first EL film may be formed; the first sacrificial film may be formed so as to cover an end portion of the first EL film; a third EL layer and a third sacrificial layer that covers an end portion of the connection electrode and an end portion of the third EL layer may be formed in a region between the first and second pixel electrodes and the connection electrode by processing the first EL film and the first sacrificial film; at least a part of a region of the third sacrificial layer that overlaps with the connection electrode may be removed in parallel with a removal of at least the part of the first sacrificial layer and at least the part of the second sacrificial layer; and the common electrode may be formed over the connection electrode.

In the above embodiment, the common electrode is not necessarily electrically connected to the third EL layer.

### Effect of the Invention

According to one embodiment of the present invention, a highly reliable display device can be provided. According to another embodiment of the present invention, an inexpensive display device can be provided. According to another embodiment of the present invention, a high-resolution display device can be provided. According to another embodiment of the present invention, a display device with a high aperture ratio can be provided. According to another embodiment of the present invention, a high-definition display device can be provided. According to another embodiment of the present invention, a novel display device can be provided.

According to another embodiment of the present invention, a method for manufacturing a highly reliable display device can be provided. According to another embodiment of the present invention, a method for manufacturing a display device with high yield can be provided. According to another embodiment of the present invention, a method for manufacturing a high-resolution display device can be provided. According to another embodiment of the present invention, a method for manufacturing a display device with a high aperture ratio can be provided. According to another embodiment of the present invention, a method for manufacturing a high-definition display device can be provided. According to another embodiment of the present invention, a method for manufacturing a novel display device can be provided.

Note that the description of these effects does not preclude the existence of other effects. Note that one embodiment of the present invention does not need to have all the effects. Note that other effects can be derived from the description of the specification, the drawings, the claims, and the like.

### BRIEF DESCRIPTION OF THE DRAWINGS

FIG. 1 is a plan view illustrating a structure example of a display device.

FIG. 2A, FIG. 2B, FIG. 2C1, and FIG. 2C2 are cross-sectional views illustrating a structure example of a display device.

FIG. 3A to FIG. 3C are cross-sectional views each illustrating a structure example of a display device.

FIG. 4A to FIG. 4C are cross-sectional views each illustrating a structure example of a display device.

FIG. 5A and FIG. 5B are cross-sectional views each illustrating a structure example of a display device.

FIG. 6A, FIG. 6B, FIG. 6C1, and FIG. 6C2 are cross-sectional views each illustrating a structure example of a display device.

FIG. 7A to FIG. 7C are cross-sectional views each illustrating a structure example of a display device.

FIG. 8A and FIG. 8B are cross-sectional views each illustrating a structure example of a display device.

FIG. 9A, FIG. 9B, FIG. 9C, FIG. 9D1, and FIG. 9D2 are cross-sectional views illustrating an example of a method for manufacturing a display device.

FIG. 10A to FIG. 10D are cross-sectional views illustrating an example of a method for manufacturing a display device.

FIG. 11A to FIG. 11D are cross-sectional views illustrating an example of a method for manufacturing a display device.

FIG. 12A to FIG. 12C are cross-sectional views illustrating an example of a method for manufacturing a display device.

FIG. 13A and FIG. 13B are cross-sectional views illustrating an example of a method for manufacturing a display device.

FIG. 14A to FIG. 14D are cross-sectional views illustrating an example of a method for manufacturing a display device.

FIG. 15A and FIG. 15B are cross-sectional views illustrating an example of a method for manufacturing a display device.

FIG. 16A to FIG. 16G are plan views each illustrating a structure example of a pixel.

FIG. 17A to FIG. 17H are plan views each illustrating a structure example of a pixel.

FIG. 18 is a perspective view illustrating an example of a display device.

FIG. 19A is a cross-sectional view illustrating an example of a display device. FIG. 19B and

FIG. 19C are cross-sectional views each illustrating an example of a transistor.

FIG. 20 is a cross-sectional view illustrating an example of a display device.

FIG. 21A to FIG. 21D are cross-sectional views each illustrating an example of a display device.

FIG. 22A and FIG. 22B are perspective views illustrating an example of a display module.

FIG. 23 is a cross-sectional view illustrating an example of a display device.

FIG. 24 is a cross-sectional view illustrating an example of a display device.

FIG. 25 is a cross-sectional view illustrating an example of a display device.

FIG. 26 is a cross-sectional view illustrating an example of a display device.

FIG. 27 is a cross-sectional view illustrating an example of a display device.

FIG. 28 is a cross-sectional view illustrating an example of a display device.

FIG. 29 is a cross-sectional view illustrating an example of a display device.

FIG. 30 is a cross-sectional view illustrating an example of a display device.

FIG. 31 is a cross-sectional view illustrating an example of a display device.

FIG. 32 is a cross-sectional view illustrating an example of a display device.

FIG. 33A to FIG. 33F are diagrams each illustrating a structure example of a light-emitting element.

FIG. 34A to FIG. 34D are diagrams illustrating examples of electronic devices.

FIG. 35A to FIG. 35F are diagrams illustrating examples of electronic devices.

FIG. 36A to FIG. 36G are diagrams illustrating examples of electronic devices.

FIG. 37A to FIG. 37F are diagrams illustrating examples of electronic devices.

FIG. 38A and FIG. 38B are STEM images of a cross section of a sample fabricated in this Example.

FIG. 39 is a plan view illustrating a structure of a display panel fabricated in this Example.

FIG. 40 is an optical micrograph of the display panel fabricated in this Example.

FIG. 41 is a photograph of an image displayed on the display panel fabricated in this Example.

FIG. 42 is a graph showing a change over time of a luminance of the display panel fabricated in this Example.

FIG. 43 shows measurement results of spectra of the display panel fabricated in this Example.

### MODE FOR CARRYING OUT THE INVENTION

Hereinafter, embodiments will be described with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatching pattern is used for the portions having similar functions, and the portions are not especially denoted by reference numerals in some cases.

In each drawing described in this specification, the size, the layer thickness, or the region of each component is exaggerated for clarity in some cases. Thus, they are not limited to the illustrated scale.

In this specification and the like, the ordinal numbers such as “first” and “second” are used in order to avoid confusion among components and do not limit the number.

Note that the expressions indicating directions, such as “over” and “under,” are basically used to correspond to the directions in the drawings. However, in some cases, the term “over” or “under” in the specification indicates a direction that does not correspond to the apparent direction in the drawings, for the purpose of easy description or the like. For example, when the stacked order (or formation order) of a stack is described, even in the case where a surface on which the stack is provided (e.g., a formation surface, a support surface, a bonding surface, or a flat surface) is positioned above the stack in the drawings, the direction and the opposite direction are referred to as “under” and “over”, respectively, in some cases.

In this specification and the like, the term “film” and the term “layer” can be interchanged with each other depending on the case or depending on circumstances. For example, in some cases, the term “conductive layer” or the term “insulating layer” can be interchanged with the term “conductive film” or the term “insulating film”, respectively.

Note that in this specification and the like, an EL layer means a layer containing at least a light-emitting substance (also referred to as a light-emitting layer) or a stack including the light-emitting layer provided between a pair of electrodes of a light-emitting element.

In this specification and the like, a display panel that is one embodiment of a display device has a function of displaying (outputting), for example, an image on (to) a display surface. Thus, the display panel is one embodiment of an output device.

In this specification and the like, a structure in which a connector such as an FPC (Flexible Printed Circuit) or a TCP (Tape Carrier Package) is attached to a substrate of a display panel, or a structure in which an IC is mounted on a substrate by a COG (Chip On Glass) method or the like is referred to as a display panel module or a display module, or simply referred to as a display panel or the like in some cases.

### Embodiment 1

In this embodiment, a structure example of a display device of one embodiment of the present invention and an example of a method for manufacturing the display device will be described.

One embodiment of the present invention is a display device including a pixel portion and a connection portion. Pixels are arranged in a matrix in the pixel portion. Each pixel includes at least two subpixels emitting light of different colors, and a light-emitting element (also referred to as a light-emitting device) is provided in each subpixel. Each light-emitting element includes a pixel electrode and a common electrode, and an EL layer is provided between the pixel electrode and the common electrode. The pixel electrode can be divided for each light-emitting element, and the common electrode can be shared by the light-emitting elements. Here, the EL layer includes at least a light-emitting layer and preferably includes a plurality of layers. The EL layer preferably includes, for example, a light-emitting layer and a carrier-transport layer (a hole-transport layer or an electron-transport layer) over the light-emitting layer.

The connection portion includes a connection electrode, and the common electrode is provided so as to be electrically connected to the connection electrode. The connection electrode is electrically connected to an FPC, for example. Accordingly, for example, when a power supply potential is supplied to the FPC, the power supply potential can be supplied to the common electrode through the connection electrode.

As the light-emitting elements provided in the pixel portion, electroluminescent elements such as organic EL elements or inorganic EL elements can be used. Besides, a light-emitting diode (LED) can be used. The light-emitting element of one embodiment of the present invention is preferably an organic EL element (organic electroluminescent element). The two or more light-emitting elements that exhibit different colors include EL layers containing different materials. For example, three kinds of light-emitting elements emitting red (R), green (G), and blue (B) light are included, whereby a full-color display device can be achieved.

Here, in the case where the EL layers are separately formed for light-emitting elements of different colors, an evaporation method using a shadow mask such as a metal mask is known. However, this method causes a deviation from the designed shape and position of an island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve high resolution and a high aperture ratio. In addition, dust derived from a material attached to the metal mask in evaporation is generated in some cases. Such dust might cause defective patterning of the light-emitting elements. In addition, a short circuit derived from the dust may occur. A step of cleaning the material attached to the metal mask is necessary. Thus, a measure has been taken for pseudo increase in resolution (also referred to as a pixel density) by employing unique pixel arrangement such as PenTile arrangement, for example.

In one embodiment of the present invention, fine patterning of an EL layer is performed without a shadow mask such as a metal mask. This can achieve a display device with high resolution and a high aperture ratio, which has been difficult to achieve. Moreover, EL layers can be formed separately, enabling the display device to perform extremely clear display with high contrast and high display quality.

In this specification and the like, a device formed using a metal mask or an FMM (a fine metal mask, a high-resolution metal mask) may be referred to as a device having an MM (a metal mask) structure. In this specification and the like, a device formed without using a metal mask or an FMM is sometimes referred to as a device having an MML (metal maskless) structure.

Here, a description is made on a case where light-emitting elements of two colors (a first light-emitting element and a second light-emitting element) are separately formed over an insulating layer, for simplicity. First, a first pixel electrode, a second pixel electrode, and the connection electrode are formed over the insulating layer. Next, a first EL film is formed over the insulating layer, over the first pixel electrode, and over the second pixel electrode. Here, the first EL film is formed also in a region between the pixel portion and the connection portion.

Next, a first sacrificial film is formed over the first EL film, over the insulating layer, and over the connection electrode. Specifically, the first sacrificial film is formed so as to cover an end portion of the first EL film and an end portion of the connection electrode. Next, a resist mask is formed over the first sacrificial film. Then, the first sacrificial film and the first EL film are processed using the resist mask. Accordingly, a first EL layer including a region overlapping with the first pixel electrode and a first sacrificial layer over the first EL layer are formed. In addition, a second EL layer provided in the region between the pixel portion and the connection portion and a second sacrificial layer which covers an end portion of the second EL layer and the end portion of the connection electrode are formed.

As a method for processing a film such as the first sacrificial film and the first EL film, a method in which part of a film is removed by etching can be given. In this specification and the like, processing a film using a resist mask, for example, means removing the film in a region not overlapping with the resist mask by etching.

Note that in the case where the first EL film is processed, a method can be considered in which processing is performed by a photolithography method directly on a film that functions as a light-emitting layer and is included in the first EL film. In this case, damage to the light-emitting layer (e.g., processing damage) might significantly degrade the reliability. In view of this, in order to manufacture a display device of one embodiment of the present invention, a sacrificial layer or the like is formed over a film (e.g., a film functioning as a carrier-transport layer or a carrier-injection layer, or more specifically, a film functioning as an electron-transport layer, a hole-transport layer, an electron-injection layer, or a hole-injection layer) positioned above a film functioning as a light-emitting layer, and then the film functioning as the light-emitting layer is processed. Accordingly, the display device of one embodiment of the present invention can be a highly reliable display device. The same applies to a second EL film described below.

Next, the second EL film is formed over the insulating layer, over the first sacrificial layer, over the second pixel electrode, and over the second EL layer. Then, a second sacrificial film is formed over the second EL film and over the second sacrificial layer. Subsequently, a resist mask is formed over the second sacrificial film. Then, the second sacrificial film and the second EL film are processed using the resist mask. Thus, a third EL layer including a region overlapping with the second pixel electrode and a third sacrificial layer over the second EL layer are formed. Here, the second sacrificial film and the second EL film are processed so that the second sacrificial film over the second sacrificial layer and the second EL film over the second EL layer are removed.

The first to third EL layers each include at least a light-emitting layer as described above. Moreover, the first to third EL layers can each include, in addition to the light-emitting layer, one or more of a hole-injection layer, a hole-transport layer, a hole-blocking layer, an electron-blocking layer, an electron-transport layer, and an electron-injection layer. For example, the first to third EL layers can each have a structure in which a hole-injection layer, a hole-transport layer, a light-emitting layer, and an electron-transport layer are stacked in this order from the insulating layer side. Alternatively, the first to third EL layers can each have a structure in which an electron-injection layer, an electron-transport layer, a light-emitting layer, and a hole-transport layer are stacked in this order from the above-described insulating layer side.

Next, at least parts of the first to third sacrificial layers is removed, whereby the top surface of the first EL layer, the top surface of the third EL layer, and the top surface of the connection electrode are exposed. Then, the common electrode is formed, so that the first light-emitting element and the second light-emitting element are formed. The common electrode is electrically connected to the connection electrode as described above.

As described above, in the method for manufacturing a display device of one embodiment of the present invention, the second EL film is deposited over the first EL layer after the first EL layer is formed. Accordingly, when the first EL layer has a large thickness, the side surface of the first EL layer is not sufficiently covered with the second EL film in some cases. This sometimes forms a depressed portion of the second EL film in a region between the first EL layer and the second pixel electrode. Then, in some cases, the second sacrificial film enters the depressed portion, and a residue of the second sacrificial film remains in the depressed portion after processing of the second sacrificial film. This degrades the reliability of the display device in some cases. In view of this, it is preferable that the first EL layer have a small thickness. Specifically, the thickness of the first EL layer is less than or equal to 200 nm, preferably less than or equal to 180 nm, further preferably less than or equal to 150 nm, still further preferably less than or equal to 130 nm. Even in the case where the second EL film is deposited by a method offering low coverage, a small thickness of the first EL layer enables the second EL film to sufficiently cover the side surface of the first EL layer and inhibits the depressed portion from being formed in the second EL film. Accordingly, the display device of one embodiment of the present invention can be a highly reliable display device.

After the first EL layer and the third EL layer are formed but before the common electrode is formed, an insulating layer containing an organic material can be formed in a region between the first EL layer and the third EL layer. For example, an insulating film containing a photosensitive material is applied and processed by a photolithography method to form an insulating layer. Here, when a difference in the thickness between the first EL layer and the third EL layer is large, a cavity is sometimes formed between the side surface of the first EL layer and the insulating layer or between the side surface of the third EL layer and the insulating layer. The cavity makes it easy for impurities to enter the EL layers, in which case the reliability of the display device may be degraded. Accordingly, the difference in the thickness between the first EL layer and the third EL layer is preferably small. Specifically, the difference in the thickness between the first EL layer and the third EL layer is preferably less than or equal to 100 nm, further preferably less than or equal to 80 nm, still further preferably less than or equal to 60 nm, yet further preferably less than or equal to 40 nm, yet still further preferably less than or equal to 30 nm. In this manner, a highly reliable display device without the above-described cavity can be obtained. Note that the display device of one embodiment of the present invention does not necessarily include the above-descried insulating layer containing an organic material.

Here, the first EL layer can be provided so as to cover an end portion of the first pixel electrode, and the third EL layer can be provided so as to cover an end portion of the second pixel electrode. The end portion of the first pixel electrode preferably has a tapered shape, in which case the first EL layer is also formed so as to have a tapered shape, and coverage of the first pixel electrode with the first EL layer can be increased. Similarly, the end portion of the second pixel electrode preferably has a tapered shape, in which case the third EL layer is also formed so as to have a tapered shape, and coverage of the second pixel electrode with the third EL layer can be increased. Moreover, the end portions of the first and second pixel electrodes preferably have tapered shapes, in which case foreign matter (also referred to as dust, particles, or the like) attached during the manufacturing process can be suitably removed by treatment such as cleaning.

### Structure Example 1

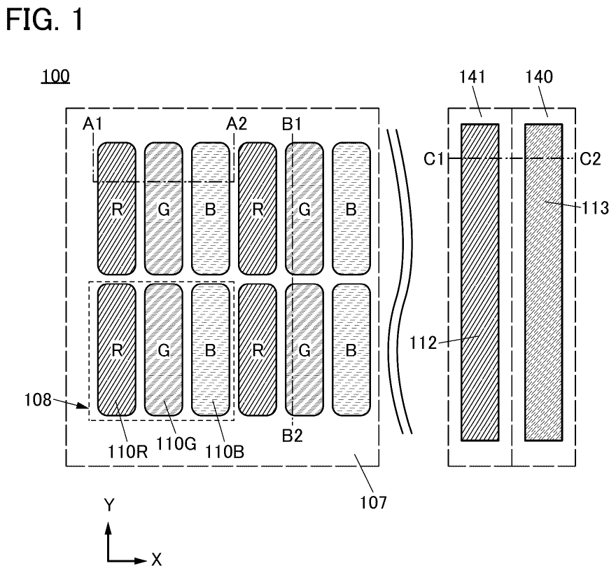

FIG. 1 is a plan view illustrating a structure example of a display device 100. The display device 100 includes a pixel portion 107 in which a plurality of pixels 108 are arranged in a matrix. The pixel 108 includes a subpixel 110R, a subpixel 110G, and a subpixel 110B. FIG. 1 illustrates subpixels 110 arranged in two rows and six columns, which form pixels 108 in two rows and two columns.

In this specification and the like, for example, matters common to the subpixel 110R, the subpixel 110G, and the subpixel 110B are sometimes described using the collective term “subpixel 110”. In the same manner, in the description common to other components that are distinguished by alphabets, reference numerals without alphabets are sometimes used.

The subpixel 110R emits red light, the subpixel 110G emits green light, and the subpixel 110B emits blue light. Accordingly, an image can be displayed on the pixel portion 107. Thus, the pixel portion 107 can be referred to as a display portion. Note that in this embodiment, subpixels of three colors of red (R), green (G), and blue (B) are given as examples; however, subpixels of three colors of yellow (Y), cyan (C), and magenta (M) may be used, for example. Moreover, the number of types of subpixels is not limited to three, and four or more types of subpixels may be used. The four subpixels can be of four colors of R, G, B, and white (W), of four colors of R, G, B, and Y, or of four colors of R, G, B, and infrared light (IR), for example.

It also can be said that stripe arrangement is employed for the pixels 108 illustrated in FIG. 1. Note that the arrangement method that can be employed for the pixels 108 is not limited thereto; another arrangement method such as stripe arrangement, S stripe arrangement, delta arrangement, Bayer arrangement, or zigzag arrangement may be used, or PenTile arrangement, diamond arrangement, or the like can be used.

In this specification and the like, the row direction and the column direction are sometimes referred to as the X direction and the Y direction, respectively. The X direction and the Y direction intersect with each other and are perpendicular to each other, for example.

FIG. 1 illustrates an example where subpixels of different colors are arranged in the X direction and subpixels of the same color are arranged in the Y direction. Note that subpixels of different colors may be arranged in the Y direction, and subpixels of the same color may be arranged in the X direction.

A region 141 and a connection portion 140 are provided outside the pixel portion 107, and the region 141 is positioned between the pixel portion 107 and the connection portion 140. An EL layer 112 is provided in the region 141. A connection electrode 113 is provided in the connection portion 140.

Although FIG. 1 illustrates an example where the region 141 and the connection portion 140 are positioned on the right side of the pixel portion 107 in the plan view, the position of the region 141 and the connection portion 140 is not particularly limited. The region 141 and the connection portion 140 only needs to be provided on at least one of the upper side, the right side, the left side, and the lower side of the pixel portion 107 in the plan view, and may be provided to surround the four sides of the pixel portion 107. The top surface shapes of the region 141 and the connection portion 140 can be a belt-like shape, an L shape, a U shape, a frame-like shape, or the like. In addition, the numbers of the regions 141 and the connection portions 140 can be one or more.

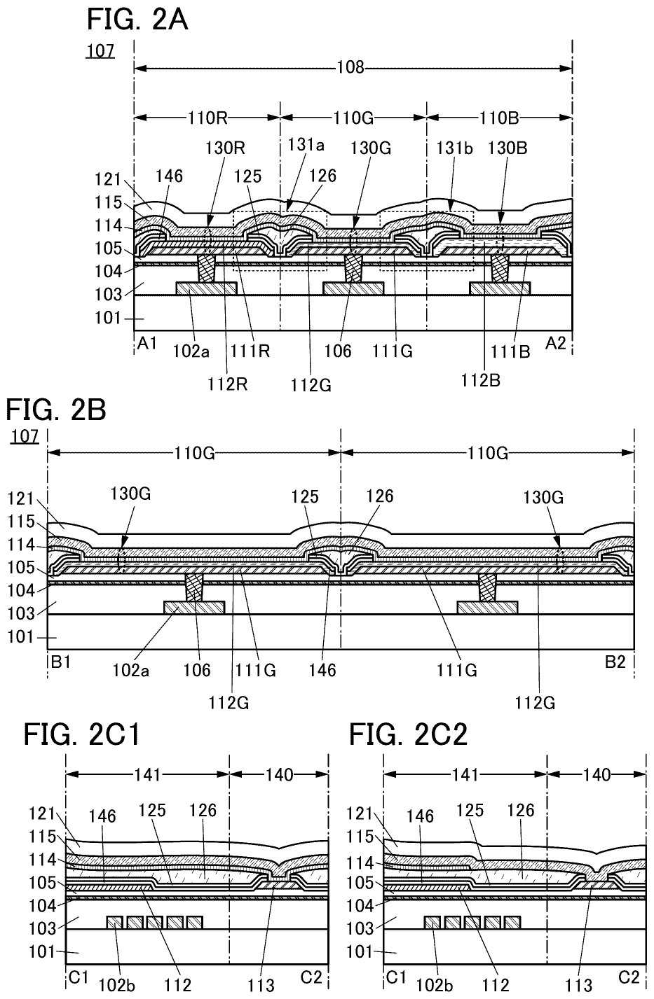

FIG. 2A is a schematic cross-sectional view taken along dashed-dotted line A1-A2 in FIG. 1, and FIG. 2B is a schematic cross-sectional view taken along dashed-dotted line B1-B2 in FIG. 1, and FIG. 2C1 is a schematic cross-sectional view taken along dashed-dotted line C1-C2 in FIG. 1.

As illustrated in FIG. 2A to FIG. 2C1, the display device 100 includes an insulating layer 101, a conductive layer 102a and a conductive layer 102b over the insulating layer 101, an insulating layer 103 over the insulating layer 101, over the conductive layer 102a, and over the conductive layer 102b, an insulating layer 104 over the insulating layer 103, and an insulating layer 105 over the insulating layer 104. The insulating layer 101 is provided over a substrate (not illustrated). An opening reaching the conductive layer 102a is provided in the insulating layer 105, the insulating layer 104, and the insulating layer 103, and a plug 106 is provided so as to fill the opening.

In the pixel portion 107, a light-emitting element 130 is provided over the insulating layer 105 and over the plug 106. Here, the insulating layer 101, the insulating layer 103, and the insulating layer 105 function as interlayer insulating layers. As the insulating layer 101, the insulating layer 103, and the insulating layer 105, a variety of inorganic insulating films such as an oxide insulating film, a nitride insulating film, an oxynitride insulating film, and a nitride oxide insulating film can be suitably used; specifically, a silicon oxide film, a silicon oxynitride film, an aluminum oxide film, a silicon nitride film, or a silicon nitride oxide film can be used, for example.

Note that in this specification and the like, oxynitride refers to a material that contains more oxygen than nitrogen, and nitride oxide refers to a material that contains more nitrogen than oxygen. For example, silicon oxynitride refers to a material that contains more oxygen than nitrogen in its composition, and silicon nitride oxide refers to a material that contains more nitrogen than oxygen in its composition.

The insulating layer 104 functions as a barrier layer that inhibits entry of impurities such as water into, for example, the light-emitting element 130. As the insulating layer 104, it is possible to use, for example, a film in which hydrogen or oxygen is less likely to be diffused than in a silicon oxide film, such as a silicon nitride film, an aluminum oxide film, or a hafnium oxide film.

The conductive layer 102a and the conductive layer 102b function as wirings. The conductive layer 102a is provided in the pixel portion 107 and the conductive layer 102b is provided in the region 141. The conductive layer 102a is electrically connected to the light-emitting element 130 through the plug 106.

For the conductive layer 102a, the conductive layer 102b, and the plug 106, it is possible to use a variety of conductive materials, for example, a metal such as aluminum (Al), titanium (Ti), chromium (Cr), nickel (Ni), copper (Cu), yttrium (Y), zirconium (Zr), tin (Sn), zinc (Zn), silver (Ag), platinum (Pt), gold (Au), molybdenum (Mo), tantalum (Ta), or tungsten (W) or an alloy containing the metal as its main component (e.g., an alloy of silver, palladium (Pd), and copper (Ag—Pd—Cu (APC))). For the conductive layer 102a, the conductive layer 102b, and the plug 106, an oxide such as tin oxide or zinc oxide may be used.

FIG. 2A illustrates a cross-sectional structure example of the light-emitting element 130R provided in the subpixel 110R, the light-emitting element 130G provided in the subpixel 110G, and the light-emitting element 130B provided in the subpixel 110B. FIG. 2B illustrates a cross-sectional structure example of the light-emitting element 130G.

As the light-emitting element 130R, the light-emitting element 130G, and the light-emitting element 130B, EL elements such as OLEDs (Organic Light Emitting Diodes) or QLEDs (Quantum-dot Light Emitting Diodes) are preferably used. As a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given.

The light-emitting element 130R includes a pixel electrode 111R over the insulating layer 105 and over the plug 106, an EL layer 112R over the pixel electrode 111R, a common layer 114 over the EL layer 112R, and a common electrode 115 over the common layer 114. The light-emitting element 130G includes a pixel electrode 111G over the insulating layer 105 and over the plug 106, an EL layer 112G over the pixel electrode 111G, the common layer 114 over the EL layer 112G, and the common electrode 115 over the common layer 114. The light-emitting element 130B includes a pixel electrode 111B over the insulating layer 105 and over the plug 106, an EL layer 112B over the pixel electrode 111B, the common layer 114 over the EL layer 112B, and the common electrode 115 over the common layer 114. Note that a pixel electrode 111 is sometimes referred to as a lower electrode, and the common electrode 115 is sometimes referred to as an upper electrode.

As illustrated in FIG. 2A and FIG. 2B, the pixel electrode 111 and the EL layer 112 are divided for each light-emitting element 130. By contrast, the common layer 114 and the common electrode 115 are shared by the light-emitting elements 130.

The EL layer 112R can be provided so as to cover an end portion of the pixel electrode 111R, the EL layer 112G can be provided so as to cover an end portion of the pixel electrode 111G, and the EL layer 112B can be provided so as to cover an end portion of the pixel electrode 111B. For example, the EL layer 112R can be provided so as to cover an upper end portion and a lower end portion of the pixel electrode 111R, the EL layer 112G can be provided so as to cover an upper end portion and a lower end portion of the pixel electrode 111G, and the EL layer 112B can be provided so as to cover an upper end portion and a lower end portion of the pixel electrode 111B. Here, the end portion of the pixel electrode 111 preferably has a tapered shape, in which case the EL layer 112 is also formed so as to have a tapered shape, and the coverage of the pixel electrode 111 with the EL layer 112 can be increased. Furthermore, the end portion of the pixel electrode 111 preferably has a tapered shape, in which case foreign matter (also referred to as dust, particles, or the like) attached during the manufacturing process can be suitably removed by treatment such as cleaning. Note that the EL layer 112 does not necessarily cover the end portion of the pixel electrode 111; for example, an end portion of the EL layer 112 may be positioned inward from the end portion of the pixel electrode 111.

In this specification and the like, a tapered shape indicates a shape in which at least part of the side surface of a structure is inclined with respect to a substrate surface. For example, a tapered shape indicates a shape including a region where an angle between the inclined side surface and the substrate surface (such an angle is also referred to as a taper angle) is less than 90°.

As illustrated in FIG. 2A and FIG. 2B, the insulating layer 105 has a depressed portion between adjacent light-emitting elements 130 in some cases. Specifically, the thickness of the insulating layer 105 in a region not overlapping with the pixel electrode 111 is sometimes smaller than that of the insulating layer 105 in a region overlapping with the pixel electrode 111. Note that the insulating layer 105 does not include the depressed portion between the adjacent light-emitting elements 130 in some cases.

The EL layer 112R included in the light-emitting element 130R contains at least a light-emitting organic compound that emits light with intensity in the red wavelength range. The EL layer 112G included in the light-emitting element 130G contains at least a light-emitting organic compound that emits light with intensity in a green wavelength range. The EL layer 112B included in the light-emitting element 130B contains at least a light-emitting organic compound that emits light with intensity in a blue wavelength range. A layer that is included in the EL layer 112 and contains a light-emitting organic compound can be referred to as a light-emitting layer.

The EL layer 112 includes at least a light-emitting layer. It is preferable that the EL layer 112 include a light-emitting layer and a carrier-transport layer over the light-emitting layer. Accordingly, the light-emitting layer is inhibited from being exposed on the outermost surface in the fabrication process of the display device 100, so that damage to the light-emitting layer can be reduced. Thus, the reliability of the display device 100 can be increased.

The EL layer 112 can include one or more of a hole-injection layer, a hole-transport layer, a hole-blocking layer, an electron-blocking layer, an electron-transport layer, and an electron-injection layer. For example, the EL layer 112 can have a structure in which a hole-injection layer, a hole-transport layer, a light-emitting layer, and an electron-transport layer are stacked in this order from the electrode 111 side. Alternatively, the EL layer 112 can have a structure in which an electron-injection layer, an electron-transport layer, a light-emitting layer, and a hole-transport layer are stacked in this order from the electrode 111 side.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other depending on the cross-sectional shape, properties, or the like. One layer may have two or three functions of the carrier-injection layer, the carrier-transport layer, and the carrier-blocking layer in some cases.

The common layer 114 can be an electron-injection layer or a hole-injection layer. In the case where the common layer 114 includes an electron-injection layer, the EL layer 112 does not need to include an electron-injection layer; in the case where the common layer 114 includes a hole-injection layer, the EL layer 112 does not need to include a hole-injection layer. In this case, for the common layer 114, a material with as low electric resistance as possible is preferably used. Alternatively, it is preferable to form the common layer 114 as thin as possible, in which case the electric resistance of the common layer 114 in the thickness direction can be reduced. For example, the thickness of the common layer 114 is preferably greater than or equal to 1 nm and less than or equal to 5 nm, further preferably greater than or equal to 1 nm and less than or equal to 3 nm.

Note that the common layer 114 may include a hole-transport layer, a hole-blocking layer, an electron-blocking layer, or an electron-transport layer. Thus, the common layer 114 can include at least one of a hole-injection layer, a hole-transport layer, a hole-blocking layer, an electron-blocking layer, an electron-transport layer, and an electron-injection layer. A structure can be employed in which a layer included in the common layer 114 is not included in the EL layer 112.

A metal material can be used for the pixel electrode 111, for example. For example, a metal material such as gold, silver, platinum, magnesium, nickel, tungsten, chromium, molybdenum, iron, cobalt, copper, palladium, or titanium, or an alloy material containing the metal material (e.g. an alloy of silver and magnesium) can be used. Alternatively, a nitride of the metal material (e.g., titanium nitride) or the like may be used for the pixel electrode 111.

The common electrode 115 can be a conductive layer having a transmitting property with respect to visible light. For example, a conductive oxide such as indium oxide, indium tin oxide, indium zinc oxide, zinc oxide, or zinc oxide containing gallium or graphene can be used for the common electrode 115. Alternatively, a metal material such as gold, silver, platinum, magnesium, nickel, tungsten, chromium, molybdenum, iron, cobalt, copper, palladium, or titanium, or an alloy material containing the metal material can be used for the common electrode 115. Alternatively, a nitride of the metal material (e.g., titanium nitride) or the like may be used for the common electrode 115. Note that in the case of using a metal material or an alloy material (or a nitride thereof), the thickness is preferably set small enough to transmit light. Alternatively, a stacked film of any of the above materials can be used for the conductive layers. For example, a stacked-layer film of indium tin oxide and an alloy of silver and magnesium is preferably used for the common electrode 115, in which case the conductivity of the common electrode 115 can be increased.

A protective layer 146 is provided over the EL layer 112. For example, the protective layer 146 is provided in a region of the EL layer 112 that is not in contact with the common layer 114.

As described above, the end portion of the pixel electrode 111 can have a tapered shape. Thus, coverage with the protective layer 146 provided along the end portion of the pixel electrode 111 can be improved. Moreover, foreign matter (also referred to as dust, particles, or the like) generated during the manufacturing process of the display device 100 can be suitably removed by treatment such as cleaning.

An insulating layer 125 and an insulating layer 126 are provided in a region between two adjacent light-emitting elements 130. Specifically, the insulating layer 125 is provided along the side surface of the EL layer 112, the side surface of the protective layer 146, the top surface of the protective layer 146, and the top surface of the insulating layer 105, for example. Providing the insulating layer 125 can inhibit entry of impurities such as water into the EL layer 112 through its side surface.

The insulating layer 126 is provided over the insulating layer 125. The insulating layer 126 can fill the depressed portion positioned between the adjacent light-emitting elements 130. This can improve the coverage with the common electrode 115 over the insulating layer 126. Thus, generation of disconnection of the common electrode 115 can be suppressed, and generation of a connection defect can be suppressed. In addition, it is possible to inhibit an increase in electric resistance due to local thinning of the common electrode 115 by a step. Consequently, the display device 100 can be a highly reliable display device.

The insulating layer 125 is provided in contact with the side surface of the EL layer 112, so that a structure can be obtained in which the EL layer 112 and the insulating layer 126 are not in contact with each other. If the EL layer 112 and the insulating layer 126 are in contact with each other, the EL layer 112 might be dissolved by an organic solvent contained in the insulating layer 126, for example, particularly when the EL layer 112 contains an organic compound. Thus, providing the insulating layer 125 between the EL layer 112 and the insulating layer 126 as illustrated in FIG. 2A and FIG. 2B can protect the side surface of the EL layer 112.

The protective layer 146 and the insulating layer 125 can contain an inorganic material. For each of the protective layer 146 and the insulating layer 125, an inorganic insulating film such as an oxide insulating film, a nitride insulating film, an oxynitride insulating film, or a nitride oxide insulating film can be used, for example. The protective layer 146 and the insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when an inorganic insulating film such as an aluminum oxide film, a hafnium oxide film, or a silicon oxide film that is formed by an atomic layer deposition (ALD) method is employed for the protective layer 146 and the insulating layer 125, it is possible to form the protective layer 146 and the insulating layer 125 that has few pinholes and an excellent function of protecting the EL layer 112.

The protective layer 146 and the insulating layer 125 can be formed by a sputtering method, a chemical vapor deposition (CVD) method, a pulsed laser deposition (PLD) method, an ALD method, or the like. The insulating layer 125 is preferably formed by an ALD method achieving good coverage.

The insulating layer 126 can contain an organic material. For the insulating layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. In the case where the insulating layer 126 contains a resin, the insulating layer 126 can be referred to as a resin layer.

For the insulating layer 126, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

Moreover, for the insulating layer 126, a photosensitive resin can be used. A photoresist may be used as the photosensitive resin. As the photosensitive resin, a positive material or a negative material can be used.

A colored material (e.g., a material containing a black pigment) may be used for the insulating layer 126 so that the resin layer 126 has a function of blocking stray light from adjacent pixels and inhibiting color mixture.

A reflective film (e.g., a metal film containing one or more selected from silver, palladium, copper, titanium, aluminum, and the like) may be provided between the insulating layer 125 and the insulating layer 126 so that light emitted from the light-emitting layer is reflected by the reflective film; hence, the function of increasing the light extraction efficiency may be added to the display device 100.

A protective layer 121 is provided over the common electrode 115 to cover the light-emitting elements 130. The protective layer 121 has a function of preventing diffusion of impurities such as water into the light-emitting elements 130 from above.

The protective layer 121 can have, for example, a single-layer structure or a stacked-layer structure at least including an inorganic insulating film. For the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide a may be used for the protective layer 121.

As the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. With this structure, the top surface of the organic insulating film can be flat, and accordingly, coverage with the inorganic insulating film over the organic insulating film is improved, leading to an improvement in barrier properties. Moreover, the top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

FIG. 2C1 is a cross-sectional view illustrating a structure example of the region 141 and the connection portion 140. As described above, in the region 141, the conductive layer 102b is provided over the insulating layer 101, and the insulating layer 103 is provided over the insulating layer 101 and over the conductive layer 102b.

In the region 141, the EL layer 112 over the insulating layer 105, the protective layer 146 over the insulating layer 105 and over the EL layer 112, the insulating layer 125 over the protective layer 146, the insulating layer 126 over the insulating layer 125, the common layer 114 over the insulating layer 126, the common electrode 115 over the common layer 114, and the protective layer 121 over the common electrode 115 are provided. In the region 141, the protective layer 146 is provided so as to cover the end portion of the EL layer 112, for example.

The EL layer 112 provided in the region 141 is not electrically connected to the common electrode 115. Accordingly, a structure can be employed in which a voltage is not applied to the EL layer 112 provided in the region 141, which offers a structure in which the EL layer 112 provided in the region 141 does not emit light.

The EL layer 112 provided in the region 141 includes at least any of a light-emitting organic compound that emits light with intensity in a red wavelength range, a light-emitting organic compound that emits light with intensity in a green wavelength range, and a light-emitting organic compound that emits light with intensity in a blue wavelength range. That is, the EL layer 112 provided in the region 141 can have the same structure as any of the EL layer 112R, the EL layer 112G, and the EL layer 112B of the light-emitting element 130.

As will be described in detail later, in the display device in which the EL layer 112 and the protective layer 146 are provided in the region 141, it is possible to prevent the insulating layer 105, the insulating layer 104, and the insulating layer 103 from being partly removed by etching or the like during the manufacturing process of the display device and thus prevent the conductive layer 102b from being exposed. Hence, the conductive layer 102b can be prevented from being unintentionally in contact with other electrodes, layers, or the like. For example, a short circuit between the conductive layer 102b and the common electrode 115 can be prevented. Consequently, the display device 100 can be a highly reliable display device. In addition, the display device 100 can be manufactured by a method with a high yield, whereby the display device 100 can be an inexpensive display device.

The connection portion 140 includes the connection electrode 113 over the insulating layer 105, the common layer 114 over the connection electrode 113, the common electrode 115 over the common layer 114, and the protective layer 121 over the common electrode 115. The protective layer 146 is provided so as to cover an end portion of the connection electrode 113; the insulating layer 125, the insulating layer 126, the common layer 114, the common electrode 115, and the protective layer 121 are stacked in this order over the protective layer 146.

The connection electrode 113 and the common electrode 115 are electrically connected to each other in the connection portion 140. The connection electrode 113 is electrically connected to an FPC (not illustrated), for example. Thus, by supplying a power supply potential to the FPC, for example, the common electrode 115 can be supplied with the power supply potential through the connection electrode 113.

Here, in the case where the electric resistance of the common layer 114 in the thickness direction is small enough to be negligible, electrical continuity between the connection electrode 113 and the common electrode 115 can be maintained even when the common layer 114 is provided between the connection electrode 113 and the common electrode 115. When the common layer 114 is provided not only in the pixel portion 107 but also in the region 141 and the connection portion 140, the common layer 114 can be formed, for example, without using a metal mask such as a mask for specifying a deposition area (also referred to as an area mask, a rough metal mask, or the like to be distinguished from a fine metal mask). Thus, the manufacturing process of the display device 100 can be simplified.

FIG. 2C2 is a modification example of the structure illustrated in FIG. 2C1. FIG. 2C2 illustrates a structure example in which the common layer 114 is not provided in the connection portion 140. In the example illustrated in FIG. 2C2, the connection electrode 113 and the common electrode 115 can be in contact with each other. Thus, electric resistance between the connection electrode 113 and the common electrode 115 can be decreased. Although FIG. 2C2 illustrates a structure where in the region 141, the common layer 114 is provided in a region overlapping with the EL layer 112 and the common layer 114 is not provided in a region not overlapping with the EL layer 112, one embodiment of the present invention is not limited thereto. For example, in the region 141, it is acceptable that the common layer 114 is not provided in the region overlapping with the EL layer 112, or the common layer 114 is provided in the region not overlapping with the EL layer 112.

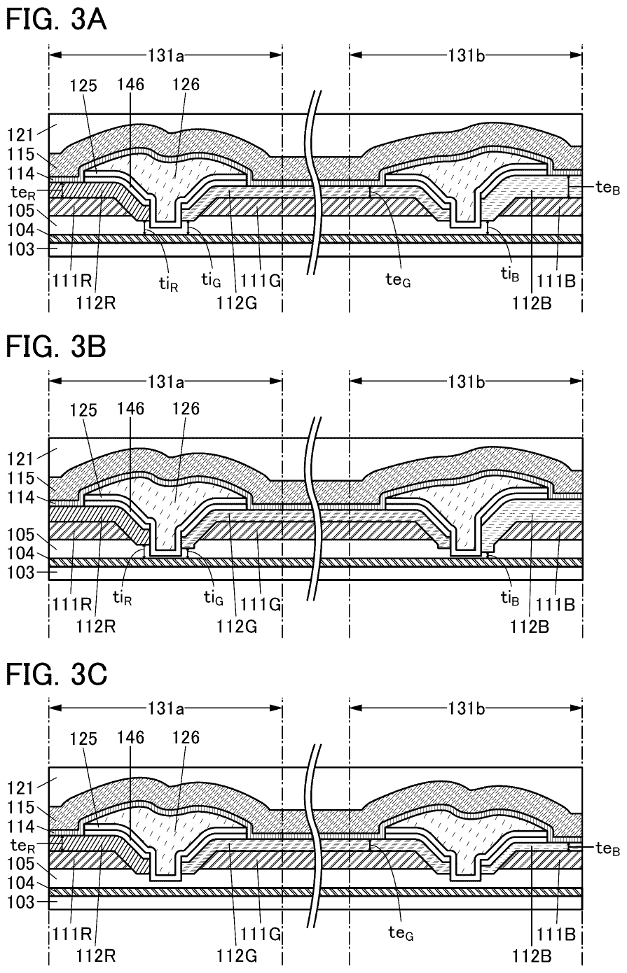

FIG. 3A is an enlarged view of a region 131a between the light-emitting element 130R and the light-emitting element 130G and a region 131b between the light-emitting element 130G and the light-emitting element 130B in FIG. 2A.

FIG. 3A illustrates a structure example in which a thickness te_{B} of the EL layer 112B is larger than a thickness te_{R} of the EL layer 112R, and the thickness te_{R} of the EL layer 112R is larger than a thickness te_{G} of the EL layer 112G. Here, although details will be described later, when the thickness te_{R}, the thickness te_{G}, and the thickness te_{B} are made small, generation of a defect due to a manufacturing process of the display device 100 can be suppressed. Thus, the display device 100 can be a highly reliable display device. In addition, the yield in manufacturing the display device 100 can be increased, and the display device 100 can be an inexpensive display device. For example, in the case where the EL layer 112 includes the light-emitting layer over the pixel electrode 111 and a carrier-transport layer over the light-emitting layer, the thickness te_{R}, the thickness te_{G}, and the thickness te_{B} are preferably less than or equal to 200 nm, further preferably less than or equal to 180 nm. Furthermore, two of the thickness te_{R}, the thickness te_{G}, and the thickness te_{B} are preferably less than or equal to 150 nm, further preferably less than or equal to 130 nm.

Here, a distance between the top surface of the pixel electrode 111R and the bottom surface of the common layer 114 can be the thickness te_{R}, a distance between the top surface of the pixel electrode 111G and the bottom surface of the common layer 114 can be the thickness te_{G}, and a distance between the top surface of the pixel electrode 111B and the bottom surface of the common layer 114 can be the thickness te_{R}. Alternatively, a distance between the top surface of the pixel electrode 111R and the bottom surface of the common layer 115 can be the thickness te_{R}, a distance between the top surface of the pixel electrode 111G and the bottom surface of the common layer 115 can be the thickness te_{G}, and a distance between the top surface of the pixel electrode 111B and the bottom surface of the common layer 115 can be the thickness te_{B}. For example, in the case where the boundary between the EL layer 112 and the common layer 114 cannot be clearly observed, or in the case where the common layer 114 is not provided, the distance between the top surface of the pixel electrode 111R and the bottom surface of the common layer 115 can be the thickness te_{R}, the distance between the top surface of the pixel electrode 111G and the bottom surface of the common layer 115 can be the thickness te_{G}, and the distance between the top surface of the pixel electrode 111B and the bottom surface of the common layer 115 can be the thickness te_{B}.

When a difference between the thickness te_{R} and the thickness te_{R} is large, a void is formed between the side surface of the EL layer 112 and the insulating layer 126 in the region 131a in some cases. In particular, a void is sometimes formed between the insulating layer 126 and the side surface of the EL layer 112 which is either the EL layer 112R or the EL layer 112G which has a smaller thickness than the other. When a difference between the thickness te_{G} and the thickness te_{R} is large, a void is formed between the side surface of the EL layer 112 and the insulating layer 126 in the region 131b in some cases. In particular, a void is sometimes formed between the insulating layer 126 and the side surface of the EL layer 112 which is either the EL layer 112G or the EL layer 112B which has a smaller thickness than the other. Formation of such a void makes impurities easily enter the EL layer 112, and the reliability of the display device might accordingly be degraded.

Thus, a difference between the thickness te_{R}, the thickness te_{G}, and the thickness te_{B} is preferably small. Specifically, among the thickness te_{R}, the thickness te_{G}, and the thickness te_{B}, a difference between the largest thickness and the smallest thickness is preferably less than or equal to 100 nm, further preferably less than or equal to 90 nm, still further preferably less than or equal to 85 nm, yet further preferably less than or equal to 80 nm. Accordingly, the void is not formed, so that the display device 100 can be a highly reliable display device.

In this specification and the like, “difference” between a first value and a second value is the absolute value of a value obtained by subtracting the second value form the first value. For example, the difference between a first thickness and a second thickness is the absolute value obtained by subtracting the second thickness from the first thickness. Note that a value including a reference numeral is sometimes referred to as “difference”. For example, in the case where the first value is smaller than the second value, the difference between the first value and the second value may be a negative value.

Although FIG. 3A illustrates an example in which a thickness ti_{R} in a region in contact with the bottom surface of the EL layer 112R, a thickness ti_{G} in a region in contact with the bottom surface of the EL layer 112G, and a thickness tip in a region in contact with the bottom surface of the EL layer 112B are equal to each other, one embodiment of the prevent invention is not limited thereto. FIG. 3B shows an example in which the thickness ti_{G} is smaller than the thickness ti_{R} and the thickness tip is smaller than the thickness ti_{G}. Due to the manufacturing process of the display device 100 described later, the thickness ti_{R}, the thickness ti_{G}, and the thickness tip are different from each other in some cases. As illustrated in FIG. 3B, the thickness of a region in contact with the bottom surface of the insulating layer 125 of the insulating layer 105 is sometimes smaller than the thickness ti_{R}, the thickness ti_{G}, and the thickness ti_{B}.

FIG. 3C is a modification example of the structure illustrated in FIG. 3A and illustrates an example in which the thickness te_{R} is smaller than the thickness te_{R} and the thickness te_{G}. In the example illustrated in FIG. 3C, the thickness te_{R} is smaller than the thickness te_{G}, and the thickness te_{G} is smaller than the thickness te_{R}.

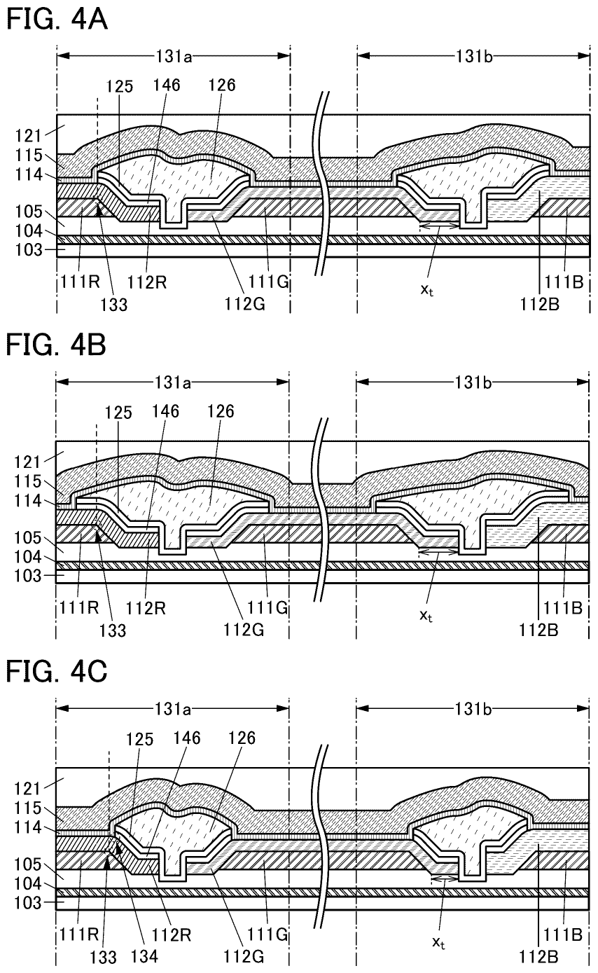

FIG. 4A is a modification example of the structure illustrated in FIG. 3A and illustrates an example in which an end portion of the protective layer 146, an end portion of the insulating layer 125, and an end portion of the insulating layer 126 are aligned with an upper end portion 133 of the pixel electrode 111. FIG. 4B is a modification example of the structure illustrated in FIG. 4A and illustrates an example in which the end portion of the protective layer 146, the end portion of the insulating layer 125, and the end portion of the insulating layer 126 are positioned inward from the upper end portion 133 of the pixel electrode 111 (positioned on the light-emitting region side). In other words, FIG. 4B illustrates an example in which part of the top surface of the pixel electrode 111 overlaps with the protective layer 146, the insulating layer 125, and the insulating layer 126. FIG. 4C is a modification example of the structure illustrated in FIG. 4A and illustrates an example in which the end portion of the protective layer 146, the end portion of the insulating layer 125, and the end portion of the insulating layer 126 are aligned with an upper end portion 134 of the EL layer 112 which overlaps with the side surface of the pixel electrode 111 (a tapered portion). Since the upper end portion 134 is positioned outward from the upper end portion 133 (positioned on the side opposite to the light-emitting region), the end portion of the protective layer 146, the end portion of the insulating layer 125, and the end portion of the insulating layer 126 are positioned outward from the upper end portion 133 of the pixel electrode 111 (positioned on the side opposite to the light-emitting region).

In the structure illustrated in FIG. 4A and the structure illustrated in FIG. 4C, the area of a region where the pixel electrode 111, the EL layer 112, and the common electrode 115 overlap with each other without the insulating layer 126 therebetween can be made larger than that in the structure illustrated in FIG. 4B. Accordingly, the display device 100 having the structure illustrated in FIG. 4A and the display device 100 having the structure illustrated in FIG. 4C can each have a larger light-emitting region than the display device 100 having the structure illustrated in FIG. 4B and thus can each have an increased aperture ratio. On the other hand, the display device 100 having the structure illustrated in FIG. 4B can be manufactured more easily than the display device 100 having the structure illustrated in FIG. 4A and the display device 100 having the structure illustrated in FIG. 4C.

FIG. 4C illustrates an example in which a length xt of a region of the EL layer 112 in contact with the top surface of the insulating layer 105 in the X direction is shorter than those in the structures illustrated in FIG. 4A and FIG. 4B. Accordingly, the area of the pixel electrode 111 in the structure illustrated in FIG. 4C can be made larger than those in the structure illustrated in FIG. 4A and the structure illustrated in FIG. 4B. Thus, the area of the region where the pixel electrode 111, the EL layer 112, and the common electrode 115 overlap with each other without the insulating layer 126 therebetween in the structure illustrated in FIG. 4C can be made larger than those in the structure illustrated in FIG. 4A and the structure illustrated in FIG. 4B. In this manner, the display device 100 having the structure illustrated in FIG. 4C can have a higher aperture ratio than the display device 100 having the structure illustrated in FIG. 4A and the display device 100 having the structure illustrated in FIG. 4B.

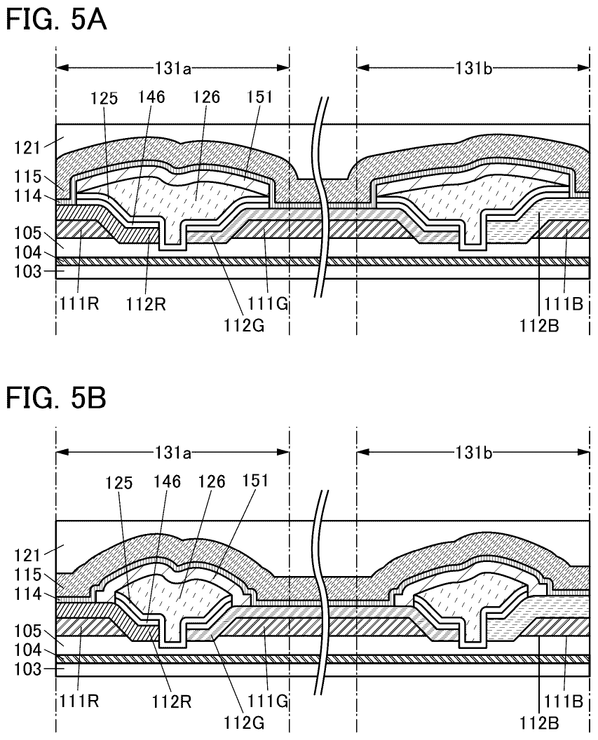

FIG. 5A illustrates an example in which a protective layer 151 is provided between the insulating layer 126 and the common layer 114, and an end portion of the protective layer 151 is aligned with the end portion of the insulating layer 126 in the structure illustrated in FIG. 4B. FIG. 5B illustrates an example in which the protective layer 151 is provided between the insulating layer 126 and the common layer 114, and the protective layer 151 covers the end portion of the insulating layer 126 in the structure illustrated in FIG. 4C. That is, in the structure illustrated in FIG. 5B, the end portion of the protective layer 151 overlaps with the top surface of the pixel electrode 111.

The protective layer 151 is preferably a layer having a high barrier property against oxygen, water, and the like. This can inhibit impurities such as oxygen and water contained in the insulating layer 126 that can contain an organic insulating material such as a resin from entering the common layer 114. Accordingly, the display device 100 can be a highly reliable display device.

An inorganic insulating material can be used for the protective layer 151; for example, a nitride can be used. Specifically, the protective layer 151 can contain at least one of silicon nitride, aluminum nitride, and hafnium nitride. For the protective layer 151, an oxide or an oxynitride can be used; for example, an oxide film or a oxynitride film of silicon oxide, silicon oxynitride, aluminum oxide, aluminum oxynitride, hafnium oxide, hafnium oxynitride, or the like can be used. The protective layer 151 can be formed by a sputtering method, a CVD method, a vacuum evaporation method, a PLD method, or an ALD method, for example.

The display device 100 having the structure illustrated in FIG. 5A can have a higher aperture ratio than the display device 100 having the structure illustrated in FIG. 5B. On the other hand, the display device 100 having the structure illustrated in FIG. 5B can be manufactured more easily than the display device 100 having the structure illustrated in FIG. 5A.

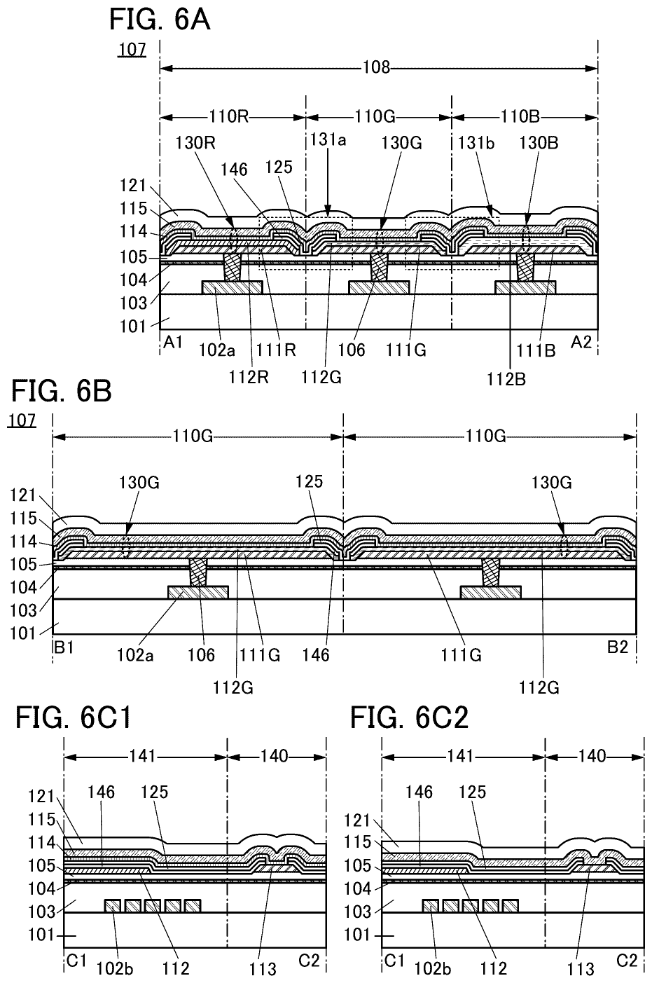

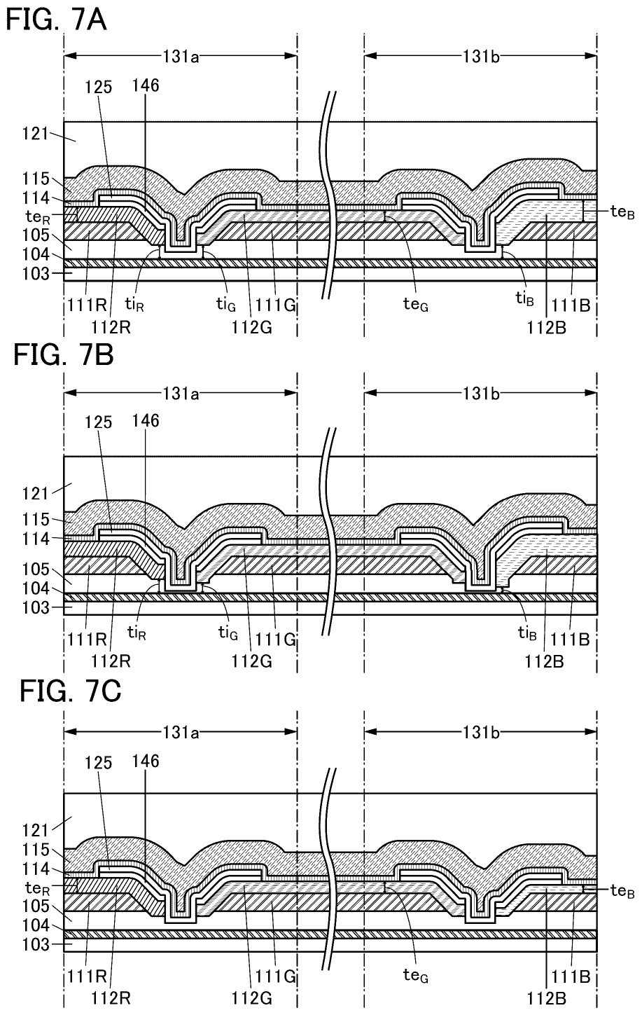

FIG. 6A, FIG. 6B, FIG. 6C1, FIG. 6C2, FIG. 7A, FIG. 7B, and FIG. 7C illustrate modification examples of the structures illustrated in FIG. 2A, FIG. 2B, FIG. 2C1, FIG. 2C2, FIG. 3A, FIG. 3B, and FIG. 3C, respectively, and each illustrate an example in which the insulating layer 126 is not provided. In the case where the insulating layer 126 is not provided, the common layer 114 includes a region positioned between adjacent EL layers 112 as illustrated in FIG. 7A, for example. Furthermore, the common electrode 115 also includes a region positioned between the adjacent EL layers 112 in some cases.

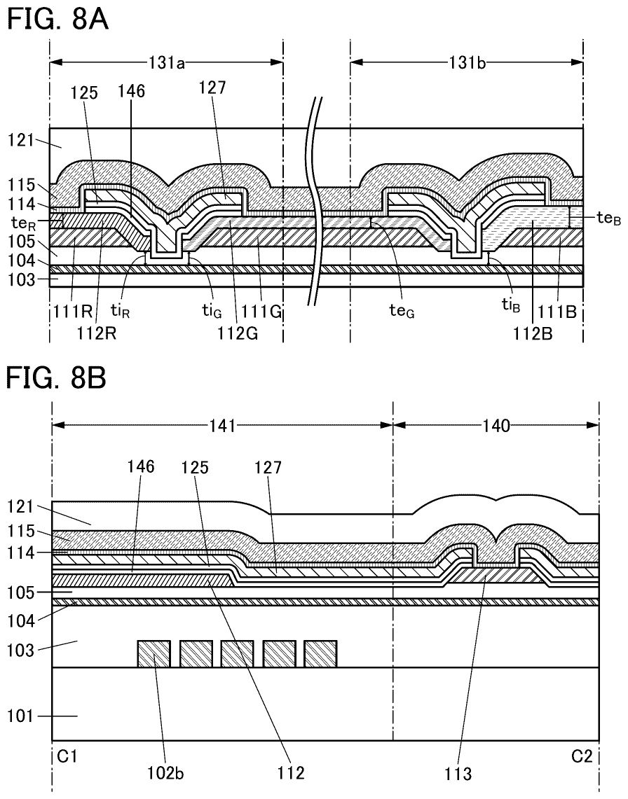

FIG. 8A is a modification example of the structure illustrated in FIG. 7A and illustrates an example in which a protective layer 127 is provided between the insulating layer 125 and the common layer 114. FIG. 8B is a cross-sectional view illustrating a structure example of the connection portion 140 and the region 141 of the display device 100 having the structure illustrated in FIG. 8A. As illustrated in FIG. 8A, an end portion of the protective layer 127 can be aligned with the end portion of the insulating layer 125.

When the protective layer 127 is provided over the insulating layer 125, entry of impurities such as water into the EL layer 112 can be suitably inhibited. Accordingly, the display device 100 can be a highly reliable display device.

For the protective layer 127, a material usable for the insulating layer 125 can be used. In this case, as the protective layer 127, a nitride insulating film such as a silicon nitride film and an aluminum nitride film can be suitably used. In the case of using a material usable for the insulating layer 125 for the protective layer 127, although the protective layer 127 can be formed by a sputtering method, a CVD method, a PLD method, an ALD method, or the like, it is preferable that the protective layer 127 be formed by an ALD method achieving favorable coverage.

Alternatively, for the protective layer 127, a metal oxide such as an indium gallium zinc oxide (an In—Ga—Zn oxide) can be used. It is also possible to use indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, for example, an indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be employed instead of gallium. Specifically, M is preferably one or more kinds selected from gallium, aluminum, and yttrium.

When the metal oxide is used for the protective layer 127, the protective layer 127 can be formed by a sputtering method.

### Manufacturing Method Example 1

An example of a method for manufacturing the display device of one embodiment of the present invention will be described below with reference to drawings. Here, description is made using the display device 100 described in the above structure example as an example.

Note that thin films included in the display device (insulating films, semiconductor films, conductive films, and the like) can be formed by a sputtering method, a CVD method, a vacuum evaporation method, a PLD method, an ALD method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given. Examples of an ALD method include a PEALD method and a thermal ALD method.

Alternatively, the thin films included in the display device (insulating films, semiconductor films, conductive films, and the like) can be formed by a method such as spin coating, dipping, spray coating, ink-jetting, dispensing, screen printing, offset printing, a doctor knife method, slit coating, roll coating, curtain coating, or knife coating.

In addition, when the thin films included in the display device are processed, a photolithography method can be used, for example. Besides, the thin films may be processed by a nanoimprinting method, a sandblasting method, a lift-off method, or the like. An island-shaped thin film may be directly formed by a deposition method using a shielding mask such as a metal mask.

There are the following two typical examples of a photolithography method. In one of the methods, a resist mask is formed over a thin film that is to be processed, the thin film is processed by etching or the like, and the resist mask is removed. In the other method, a photosensitive thin film is deposited and then processed into a desired shape by exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. In addition, light exposure may be performed by liquid immersion exposure technique. As the light used for the light exposure, extreme ultraviolet (EUV) light or X-rays may be used. Furthermore, instead of the light used for the light exposure, an electron beam can also be used. It is preferable to use extreme ultraviolet light, X-rays, or an electron beam because extremely minute processing is possible. Note that when light exposure is performed by scanning of a beam such as an electron beam, a photomask is not needed.

For etching of the thin films, a dry etching method, a wet etching method, a sandblasting method, or the like can be used.

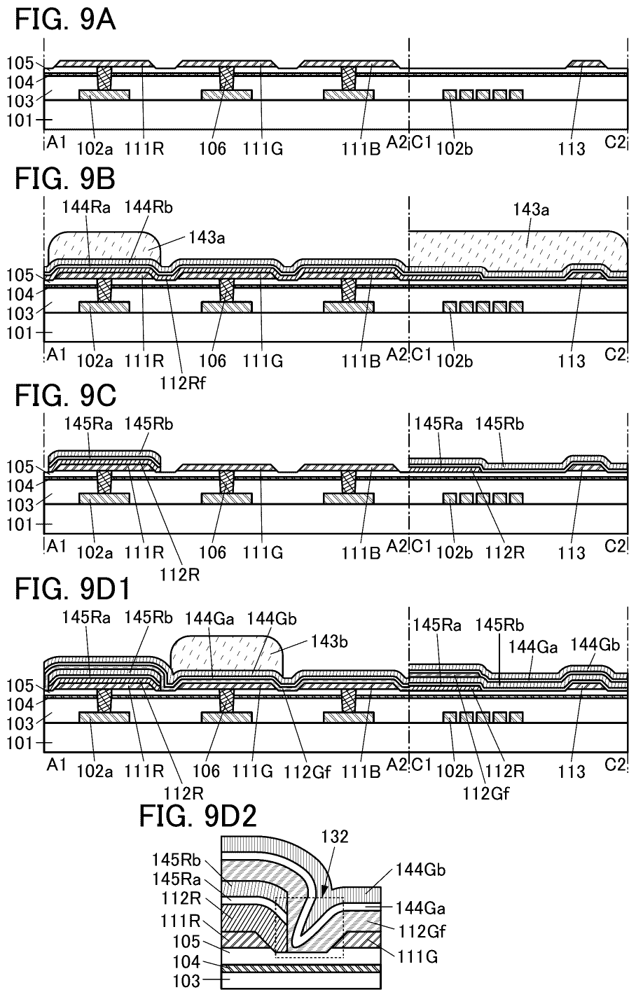

FIG. 9A to FIG. 11D are cross-sectional views illustrating a manufacturing method example of the display device 100 in which the light-emitting element 130 has the structure illustrated in FIG. 2A, and the connection portion 140 has the structure illustrated in FIG. 2C1. FIG. 9A to FIG. 11D illustrate cross-sectional views taken along dashed-dotted line A1-A2 and cross-sectional views taken along dashed-dotted line C1-C2 in FIG. 1.

To manufacture the above-described display device 100, firstly, the insulating layer 101 is formed over a substrate (not illustrated). Next, the conductive layer 102a and the conductive layer 102b are formed over the insulating layer 101, and the insulating layer 103 is formed over the insulating layer 101 so as to cover the conductive layer 102a and the conductive layer 102b. Then, the insulating layer 104 is formed over the insulating layer 103, and the insulating layer 105 is formed over the insulating layer 104.

As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate of silicon, silicon carbide, or the like; a compound semiconductor substrate of silicon germanium or the like; or an SOI substrate.

Next, openings reaching the conductive layer 102a are formed in the insulating layer 105, the insulating layer 104, and the insulating layer 103. Then, the plugs 106 are formed to fill the openings.

Subsequently, a conductive film to be the pixel electrode 111 and the connection electrode 113 later is deposited over the insulating layer 105 and over the plug 106. Then, part of the conductive film is processed by etching or the like, and the pixel electrode 111R, the pixel electrode 111G, and the pixel electrode 111B are formed over the insulating layer 105 and over the plug 106. Moreover, the connection electrode 113 is formed over the insulating layer 105 (FIG. 9A).

Here, the conductive film is preferably processed such that the side surface of the pixel electrode 111 and the side surface of the connection electrode 113 each have a tapered shape. Accordingly, a foreign matter generated in a later process can be suitably removed by treatment such as cleaning.

Note that when the conductive film is etched, part of the insulating layer 105 is etched and accordingly a depressed portion is formed in the insulating layer 105 in some cases. Specifically, the thickness of the insulating layer 105 in a region not overlapping with the pixel electrode 111 and the connection electrode 113 is sometimes smaller than the thickness of the insulating layer 105 in a region overlapping with the pixel electrode 111 or the connection electrode 113. Note that in the case where the above-described conductive film has high etching selectivity over the insulating layer 105, a depressed portion is sometimes not formed in the insulating layer 105.

Next, an EL film 112Rf to be the EL layer 112R later is formed over the insulating layer 105, over the pixel electrode 111, and over the connection electrode 113. Here, the EL film 112Rf can be provided so as not to overlap with the connection electrode 113. For example, the EL film 112Rf can be formed so as not to overlap with the connection electrode 113 when formed by shielding a region including the connection electrode 113 with a metal mask. The metal mask used here does not need to shield a pixel region of the display portion, so that a fine mask is not required; for example, a rough metal mask can be used.

The EL film 112Rf includes at least a film containing a light-emitting compound (a light-emitting film). Furthermore, the EL film 112Rf preferably includes a light-emitting film and a film functioning as a carrier-transport layer over the light-emitting film. Accordingly, the light-emitting film is inhibited from being exposed on the outermost surface in the process of manufacturing the display device 100, so that damage to the light-emitting film can be reduced. Thus, the reliability of the display device 100 can be increased.

The EL film 112Rf can have a structure in which one or more of films functioning as a hole-injection layer, a hole-transport layer, a hole-blocking layer, an electron-blocking layer, an electron-transport layer, and an electron-injection layer are stacked. For example, the EL film 112Rf can have a structure in which a film functioning as a hole-injection layer, a film functioning as a hole-transport layer, the light-emitting film, and a film functioning as an electron-transport layer are stacked in this order. Alternatively, the EL film 112Rf can have a structure in which a film functioning as an electron-injection layer, a film functioning as an electron-transport layer, the light-emitting film, and a film functioning as a hole-transport layer are stacked in this order.

The EL film 112Rf can be formed by, for example, an evaporation method, a sputtering method, or an inkjet method. Note that without limitation to this, the above deposition method can be used as appropriate.

Next, a sacrificial film 144Ra is formed over the insulating layer 105, over the EL film 112Rf, and over the connection electrode 113, and a sacrificial film 144Rb is formed over the sacrificial film 144Ra. In other words, a sacrificial film having a two-layer stacked structure is formed over the insulating layer 105, over the EL film 112Rf, and over the connection electrode 113. Note that the sacrificial film may have a single-layer structure or a stacked-layer structure of three or more layers. In a subsequent process of forming another sacrificial film, a sacrificial film has a two-layer stacked structure; however, the sacrificial film may have a single-layer structure or a stacked-layer structure of three or more layers. Here, the sacrificial film 144Ra can be formed so as to cover an end portion of the EL film 112Rf.

The sacrificial film 144Ra and the sacrificial film 144Rb can be formed by, for example, a sputtering method, a CVD method, an ALD method, or a vacuum evaporation method. Note that a formation method that causes less damage to the EL film is preferable, and the sacrificial film 144Ra formed directly on the EL film 112Rf is preferably formed by an ALD method or a vacuum evaporation method.

As the sacrificial film 144Ra, an inorganic film such as a metal film, an alloy film, a metal oxide film, a semiconductor film, or an inorganic insulating film or an organic film such as an organic insulating film can be suitably used.

Alternatively, an oxide film can be used as the sacrificial film 144Ra. An oxide film or an oxynitride film of silicon oxide, silicon oxynitride, aluminum oxide, aluminum oxynitride, hafnium oxide, hafnium oxynitride, or the like can be typically used. For example, a nitride film can also be used as the sacrificial film 144Ra. Specifically, it is also possible to use a nitride such as silicon nitride, aluminum nitride, hafnium nitride, titanium nitride, tantalum nitride, tungsten nitride, gallium nitride, or germanium nitride. Such a film containing an inorganic insulating material can be formed by a deposition method such as a sputtering method, a CVD method, or an ALD method; the sacrificial film 144Ra, which is formed directly on the EL film 112Rf, is particularly preferably formed by an ALD method.

For the sacrificial film 144Ra, a metal material such as nickel, tungsten, chromium, molybdenum, cobalt, palladium, titanium, aluminum, yttrium, zirconium, or tantalum or an alloy material containing the metal material can be used, for example. It is particularly preferable to use a low-melting-point material such as aluminum or silver.

Alternatively, for the sacrificial film 144Ra, a metal oxide such as an indium gallium zinc oxide (an In—Ga—Zn oxide) can be used. It is also possible to use indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, for example, an indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be employed instead of gallium. Specifically, M is preferably one or more kinds selected from gallium, aluminum, and yttrium.

Any of the above-described materials usable for the sacrificial film 144Ra can be used for the sacrificial film 144Rb. For example, from the above materials usable for the sacrificial film 144Ra, one material can be selected for the sacrificial film 144Ra and another material can be selected for the sacrificial film 144Rb. Alternatively, one or more materials can be selected for the sacrificial film 144Ra from the above materials usable for the sacrificial film 144Ra, and one or more materials selected from the materials excluding the material(s) selected for the sacrificial film 144Ra can be used for the sacrificial film 144Rb.

Specifically, aluminum oxide formed by an ALD method is preferably used as the sacrificial film 144Ra, and silicon nitride formed by a sputtering method is suitably used as the sacrificial film 144Rb. In the case of employing this structure, the deposition temperature at the time of depositing the materials by an ALD method and a sputtering method is preferably higher than or equal to room temperature and lower than or equal to 120° C., further preferably higher than or equal to room temperature and lower than or equal to 100° C., in which case adverse effects on the EL film 112Rf can be reduced. In the case of the stacked-layer structure of the sacrificial film 144Ra and the sacrificial film 144Rb, a stress applied to the stacked-layer structure is preferably small. Specifically, a stress applied to the stacked-layer structure is preferably higher than or equal to −500 MPa and less than or equal to +500 MPa, further preferably higher than or equal to −200 MPa and lower than or equal to +200 MPa, in which case troubles in the process, such as film separation and peeling, can be inhibited.

As the sacrificial film 144Ra, it is possible to use a film highly resistant to etching treatment performed on various EL films such as the EL film 112Rf, i.e., a film having high etching selectivity. Moreover, as the sacrificial film 144Ra, it is particularly preferable to use a film that can be removed by a wet etching method less likely to cause damage to EL films.

For the sacrificial film 141Ra, a material that can be dissolved in a chemically stable solvent may be used. In particular, a material that is dissolved in water or alcohol can be suitably used for the sacrificial film 144Ra. In deposition of the sacrificial film 144Ra, it is preferable that application of such a material dissolved in a solvent such as water or alcohol be performed by a wet deposition method and followed by heat treatment for evaporating the solvent. At this time, the heat treatment is preferably performed in a reduced-pressure atmosphere, in which case the solvent can be removed at a low temperature in a short time and thermal damage to the EL film 112Rf can be reduced accordingly.

Examples of the wet deposition method that can be used for forming the sacrificial film 144Ra include spin coating, dipping, spray coating, ink-jetting, dispensing, screen printing, offset printing, a doctor knife method, slit coating, roll coating, curtain coating, knife coating, and the like.

For the sacrificial film 144Ra, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

A film, which has high etching selectivity over the sacrificial film 144Ra, is used as the sacrificial film 144Rb.

Preferably, an inorganic insulating material such as aluminum oxide, hafnium oxide, or silicon oxide formed by an ALD method is used as the sacrificial film 144Ra, and a metal material such as nickel, tungsten, chromium, molybdenum, cobalt, palladium, titanium, aluminum, yttrium, zirconium, or tantalum or an alloy material containing any of the metal materials formed by a sputtering method is used as the sacrificial film 144Rb. Tungsten formed by a sputtering method is particularly preferably used as the sacrificial film 144Rb. Alternatively, a metal oxide containing indium, such as an indium gallium zinc oxide (an In—Ga—Zn oxide), formed by a sputtering method may be used as the sacrificial film 144Rb. Furthermore, an inorganic material may be used for the sacrificial film 144Rb. For example, it is possible to use an oxide film or a nitride film such as a silicon oxide film, a silicon oxynitride film, a silicon nitride oxide film, a silicon nitride film, an aluminum oxide film, an aluminum oxynitride film, or a hafnium oxide film.

Alternatively, as the sacrificial film 144Rb, an organic film usable for the EL film 112Rf and the like may be used. For example, the same film as the organic film used for the EL film 112Rf can be used as the sacrificial film 144Rb. The use of such an organic film is preferable, in which case the deposition apparatus for the EL film 112Rf can be used in common. Furthermore, the sacrificial film 144Rb can be removed at the same time as the etching of the EL film 112Rf; thus, the process can be simplified.

Next, a resist mask 143a is formed over the sacrificial film 144Rb (FIG. 9B). For the resist mask 143a, a resist material containing a photosensitive resin, such as a positive type resist material or a negative type resist material can be used.

Then, part of the sacrificial film 144Rb and part of the sacrificial film 144Ra that are not covered with the resist mask 143a are removed by etching, whereby a sacrificial layer 145Rb and a sacrificial layer 145Ra each having an island shape or a band shape are formed. The sacrificial layer 145Rb and the sacrificial layer 145Ra can be formed, for example, over the pixel electrode 111R and in a region indicated by dashed-dotted line C1-C2 (a region corresponding to the region 141 and the connection portion 140 that are illustrated in FIG. 1).

When part of the sacrificial film 144Rb and part of the sacrificial film 144Ra are removed by etching, part of the insulating layer 105 is etched in some cases. Here, when the sacrificial film 144Rb and the sacrificial film 144Ra in the region corresponding to the region 141 illustrated in FIG. 1 are removed by etching, the insulating layer 105, the insulating layer 104, and the insulating layer 103 in the region are etched, so that the conductive layer 102b is exposed in some cases. This might cause a short circuit, for example, when a film to be formed in a later step and the conductive layer 102b are unintentionally in contact with each other. For example, the conductive layer 102b might be short-circuited with the common electrode 115 to be formed in a later step. In view of this, in one embodiment of the present invention, the sacrificial layer 145Ra and the sacrificial layer 145Rb are formed also in the region corresponding to the region 141 illustrated in FIG. 1. Specifically, the sacrificial layer 145Ra and the sacrificial layer 145Rb are formed so as to cover the end portion of the EL layer 112R and the end portion of the connection electrode 113, which are provided in the region corresponding to the region 141. This prevents exposure of the conductive layer 102b, so that the display device 100 can be a highly reliable display device. In addition, the display device 100 can be manufactured by a high-yield method, whereby the display device 100 can be an inexpensive display device.

Preferably, part of the sacrificial film 144Rb is removed by etching using the resist mask 143a to form the sacrificial layer 145Rb; then, the resist mask 143a is removed; after that, the sacrificial film 144Ra is etched using the sacrificial layer 145Rb as a hard mask. In this case, the etching of the sacrificial film 144Rb preferably employs etching conditions with high selectivity over the sacrificial film 144Ra. Although a wet etching method or a dry etching method can be used for the etching for forming the hard mask, a shrinkage of the pattern can be reduced by using a dry etching method.

Processing of the sacrificial film 144Ra and the sacrificial film 144Rb and removal of the resist mask 143a can be performed by a wet etching method or a dry etching method. For example, the sacrificial film 144Ra and the sacrificial film 144Rb can be processed by a dry etching method using a fluorine-containing gas. The resist mask 143a can be removed by a dry etching method using an oxygen-containing gas (also referred to as an oxygen gas) (such a method is also referred to as a plasma ashing method).

When the sacrificial film 144Ra is etched using the sacrificial layer 145Rb as a hard mask, the resist mask 143a can be removed while the EL film 112Rfis covered with the sacrificial film 144Ra. For example, if the EL film 112Rfis exposed to oxygen, the electrical characteristics of the light-emitting element 130R are adversely affected in some cases. Thus, in the case where the resist mask 143a is removed by a method using an oxygen gas, such as plasma ashing, the sacrificial film 144Ra is preferably etched using the sacrificial layer 145Rb as a hard mask.

Next, part of the EL film 112Rf that is not covered by the sacrificial layer 145Ra is removed by etching, so that an island-shaped or band-shaped EL layer 112R is formed (FIG. 9C). Here, the EL layer 112R is formed in a region corresponding to the region 141 illustrated in FIG. 1.

The insulating layer 105 is sometimes etched in a region overlapping with neither the sacrificial layer 145R nor the pixel electrode 111 by the etching of the EL film 112Rf. Accordingly, the thickness of the insulating layer 105 in a region where its top surface is exposed is sometimes smaller than the thickness of the insulating layer 105 in another region in the step illustrated in FIG. 9C. Thus, as illustrated in FIG. 3B, the thickness ti_{G} and the thickness tip are sometimes smaller than the thickness ti_{R}. Note that in the case where the EL film 112Rf has high etching selectivity over the insulating layer 105, the insulating layer 105 is sometimes not etched.

In this specification and the like, for example, a description common to the sacrificial layer 145Ra and the sacrificial layer 145Rb is sometimes made using the term “sacrificial layer 145R”. A description common to the sacrificial layer 145Ra, a sacrificial layer 145Ga, and a sacrificial layer 145Ba is sometimes made using the term “sacrificial layer 145a”. A description common to the sacrificial layer 145Rb, a sacrificial layer 145Gb, and a sacrificial layer 145Bb is sometimes made using the term “sacrificial layer 145b”. Furthermore, a description common to the sacrificial layer 145a and the sacrificial layer 145b is sometimes made using the term “sacrificial layer 145”. Moreover, other components are sometimes described using reference numerals with the letters of the alphabet omitted, as described above.

In addition, when a dry etching method using an oxygen gas is used for the etching of the EL film 112Rf, the etching rate can be increased. Thus, etching under a low-power condition can be performed while the etching rate is kept adequately high; hence, damage due to the etching can be reduced. Furthermore, for example, a defect such as attachment of a reaction product generated at the etching onto the EL layer 112R can be inhibited.

Alternatively, when the EL film 112Rf is etched by a dry etching method using an etching gas that does not contain oxygen as its main component, a change in properties of the EL film 112Rf can be inhibited, so that the display device 100 can be a highly reliable display device. Examples of the etching gas that does not contain oxygen as its main component include a gas containing CF₄, C₄F₈, SF₆, CHF₃, Cl₂, H₂O, BCl₃, or the like and a gas containing a Group 18 element such as He. Alternatively, a mixed gas of the above gas and a dilution gas that does not contain oxygen can be used as the etching gas. Note that etching of the EL film 112Rf is not limited to the above and may be performed by a dry etching method using another gas or a wet etching method.

If impurities are attached to the side surface of the EL layer 112R when the EL layer 112R is formed by the etching of the EL film 112Rf, the impurities might enter the inside of the EL layer 112R in the subsequent process. This degrades the reliability of the display device 100 in some cases. Thus, it is preferable to remove impurities attached to the surface of the EL layer 112R after the formation of the EL layer 112R, in which case the reliability of the display device 100 can be increased.

Impurities attached to the surface of the EL layer 112R can be removed, for example, by irradiation of the surface of the EL layer 112R with an inert gas. Here, the surface of the EL layer 112R is exposed immediately after the EL layer 112R is formed. Specifically, the side surface of the EL layer 112R is exposed. Accordingly, impurities attached to the EL layer 112R can be removed, for example, when the substrate where the EL layer 112R is formed is put in an inert gas atmosphere after the formation of the EL layer 112R. As the inert gas, one or more selected from Group 18 elements (typically, helium, neon, argon, xenon, krypton, and the like) and nitrogen can be used, for example.

Note that in the case where the EL film 112Rf is processed, a method can be considered in which processing is performed by a photolithography method directly on a light-emitting film included in the EL film 112Rf. In this case, damage to the light-emitting layer (e.g., processing damage) might significantly degrade the reliability. In view of this, in order to manufacture the display device 100, the sacrificial layer 145Ra and the sacrificial layer 145Rb are formed over a film (e.g., a film functioning as a carrier-transport layer or a carrier-injection layer, more specifically, an electron-transport layer, a hole-transport layer, an electron-injection layer, and a hole-injection layer) positioned above the light-emitting film, so that the light-emitting film is processed. Thus, the display device 100 can be a highly reliable display device.

Next, an EL film 112Gf to be the EL layer 112G later is formed over the insulating layer 105, over the sacrificial layer 145Rb, over the pixel electrode 111G, and over the pixel electrode 111B. Forming the EL film 112Gf after the formation of the sacrificial layer 145Ra can prevent the EL film 112Gf from being in contact with the top surface of the EL layer 112R. For the formation of the EL film 112Gf, for example, the description of the formation of the EL film 112Rf can be referred to.

Subsequently, a sacrificial film 144Ga is formed over the EL film 112Gf, over the sacrificial layer 145Rb, and over the sacrificial film 144Ga, and a sacrificial film 144Gb is formed over the sacrificial film 144Ga. Then, a resist mask 143b is formed over the sacrificial film 144Gb (FIG. 9D1). Here, the sacrificial film 144Ga can be formed so as to cover an end portion of the EL film 112Gf. The description of the formation and the like of the sacrificial film 144Ra, the sacrificial film 144Rb, and the resist mask 143a can be referred to for the formation and the like of the sacrificial film 144Ga, the sacrificial film 144Gb, and the resist mask 143b.

Then, part of the sacrificial film 144Gb and the sacrificial film 144Ga, which is not covered with the resist mask 143b, is removed by etching, whereby island-shaped or band-shaped sacrificial layer 145Gb and sacrificial layer 145Ga are formed. In addition, the resist mask 143b is removed. Here, the sacrificial layer 145Gb and the sacrificial layer 145Ga can be formed over the pixel electrode 111G. The description of the formation of the sacrificial layer 145Rb and the sacrificial layer 145Ra, removal of the resist mask 143a, and the like can be referred to for the formation of the sacrificial layer 145Gb and the sacrificial layer 145Ga, removal of the resist mask 143b, and the like. Here, it is possible that the sacrificial layer 145Gb and the sacrificial layer 145Ga are not formed in the region indicated by dashed-dotted line C1-C2. Even in this case, the sacrificial layer 145Ra and the sacrificial layer 145Rb are formed in the region indicated by dashed-dotted line C1-C2; thus, in the region, the insulating layer 105, the insulating layer 104, and the insulating layer 103 can be prevented from being etched to expose the conductive layer 102b.

When the EL layer 112R is thick, the side surface of the EL layer 112R is not sufficiently covered with the EL film 112Gf in some cases. Accordingly, as illustrated in FIG. 9D2, a depressed portion is sometimes formed in the EL film 112Gf in a region 132 between the EL layer 112R and the pixel electrode 111G. Then, in some cases, the sacrificial film 144Ga and the sacrificial film 144Gb enter the depressed portion, and after processing of the sacrificial film 144Ga and the sacrificial film 144Gb, a residue thereof remains in the depressed portion. This degrades the reliability of the display device in some cases.

Thus, the EL layer 112R is preferably thin, and specifically, the thickness of the EL layer 112R is less than or equal to 200 nm, preferably less than or equal to 180 nm, further preferably less than or equal to 150 nm, still further preferably less than or equal to 130 nm. Even in the case where the EL film 112Gf is deposited by a method providing low coverage, the small thickness of the EL layer 112R enables the EL layer 112Gf to sufficiently cover the EL layer 112R and inhibits the depressed portion from being formed in the EL layer 112Gf. Accordingly, the display device 100 can be a highly reliable display device.

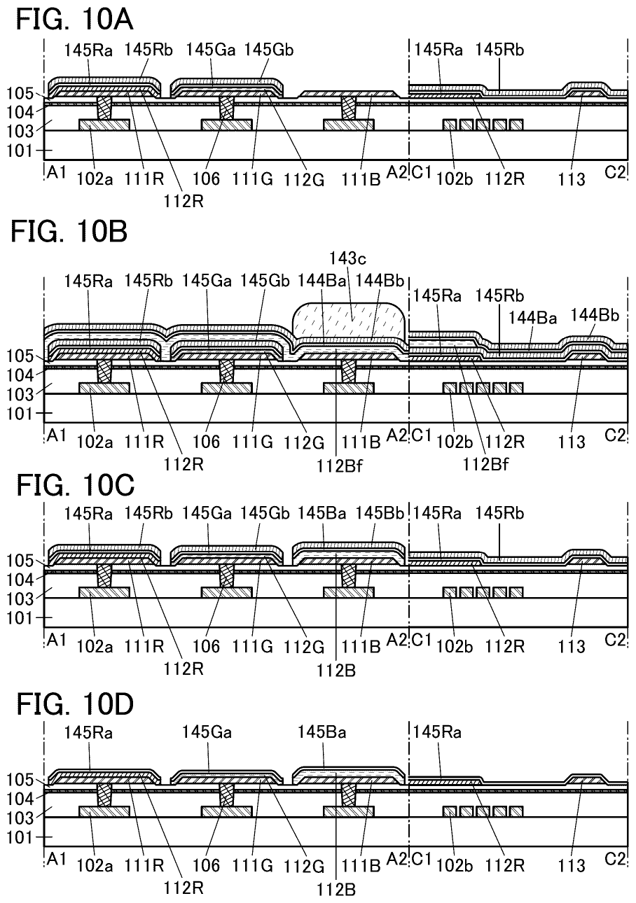

Next, part of the EL film 112Gf that is not covered with the sacrificial layer 145Ga is removed by etching, so that the island-shaped or band-shaped EL layer 112G is formed (FIG. 10A). For the formation of the EL layer 112G, for example, the description of the formation of the EL layer 112R can be referred to. Here, it is possible that the EL layer 112G is not formed in the region indicated by dashed-dotted line C1-C2. As in the case of the EL layer 112R, it is preferable to remove impurities attached to the surface of the EL layer 112G. For example, impurities attached to the EL layer 112G can be removed when the substrate where the EL layer 112G is formed is put in an inert gas atmosphere after the formation of the EL layer 112G.

The insulating layer 105 is sometimes etched in a region overlapping with neither the sacrificial layer 145R, a sacrificial layer 145G, nor the pixel electrode 111 by the etching of the EL film 112Gf. Accordingly, the thickness of the insulating layer 105 in a region where its top surface is exposed is smaller than that of the insulating layer 105 in another region in the step illustrated in FIG. 10A in some cases. Thus, as illustrated in FIG. 3B, the thickness tip is sometimes smaller than the thickness ti_{G}. Note that in the case where the EL film 112Gf has high etching selectivity over the insulating layer 105, the insulating layer 105 is sometimes not etched.

Here, when the EL film 112Gf is etched, the EL layer 112R, the sacrificial layer 145Ra, and the sacrificial layer 145Rb are formed in a region between the pixel electrode 111 and the connection electrode 113, that is, the region corresponding to the region 141 illustrated in FIG. 1. Accordingly, the insulating layer 105 in the region is not etched. Thus, the conductive layer 102b can be prevented from being exposed. This can thus prevent a short circuit from being generated, for example, when a film to be formed in a later step is unintentionally in contact with each other. For example, the conductive layer 102b can be prevented from being short-circuited with the common electrode 115 to be formed in a later step. Consequently, the display device 100 can be a highly reliable display device. In addition, the display device 100 can be manufactured by a method with a high yield, whereby the display device 100 can be an inexpensive display device.

Next, an EL film 112Bf to be the EL layer 112B later is formed over the insulating layer 105, over the sacrificial layer 145Rb, over the sacrificial layer 145Gb, and over the pixel electrode 111B. Forming the EL film 112Bf after the formation of the sacrificial layer 145Ga can inhibit the EL film 112Bf from being in contact with the top surface of the EL layer 112G. For the formation of the EL film 112Bf, for example, the description of the formation of the EL film 112Rf can be referred to.

Subsequently, a sacrificial film 144Ba is formed over the EL film 112Bf and over the sacrificial layer 145Rb, and a sacrificial film 144Bb is formed over the sacrificial film 144Ba. Then, a resist mask 143c is formed over the sacrificial film 144Bb (FIG. 10B). Here, the sacrificial film 144Ba can be formed so as to cover an end portion of the EL film 112Bf. The description of the formation and the like of the sacrificial film 144Ra, the sacrificial film 144Rb, and the resist mask 143a can be referred to for the formation and the like of the sacrificial film 144Ba, the sacrificial film 144Bb, and the resist mask 143c.

Next, part of the sacrificial film 144Bb and the sacrificial film 144Ba, which is not covered with the resist mask 143c, is removed by etching, whereby island-shaped or band-shaped sacrificial layer 145Bb and sacrificial layer 145Ba are formed. Furthermore, the resist mask 143c is removed. Here, the sacrificial layer 145Bb and the sacrificial layer 145Ba can be formed over the pixel electrode 111B. The description of the formation of the sacrificial layer 145Rb and the sacrificial layer 145Ra, the removal of the resist mask 143a, and the like can be referred to for the formation of the sacrificial layer 145Bb and the sacrificial layer 145Ba, the removal of the resist mask 143c, and the like. Here, it is possible that the sacrificial layer 145Bb and the sacrificial layer 145Ba are not formed in the region indicated by dashed-dotted line C1-C2. Even in this case, the sacrificial layer 145Ra and the sacrificial layer 145Rb are formed in the region indicated by dashed-dotted line C1-C2; thus, in the region, the insulating layer 105, the insulating layer 104, and the insulating layer 103 can be prevented from being etched to expose the conductive layer 102b.

When the thickness of the EL layer 112R and the EL layer 112G are large, the side surface of the EL layer 112R and the side surface of the EL layer 112G are not sufficiently covered with the EL film 112Bf in some cases. Thus, like the example described with reference to FIG. 9D2, the reliability of the display device might be degraded. In view of this, it is preferable that the EL layer 112G has a small thickness like the EL layer 112R. The thickness of the EL layer 112G is less than or equal to 200 nm, preferably less than or equal to 180 nm, further preferably less than or equal to 150 nm, still further preferably less than or equal to 130 nm. Accordingly, the display device 100 can be a highly reliable display device.

Next, part of the EL film 112Bf that is not covered with the sacrificial layer 145Ba is removed by etching, so that the island-shaped or band-shaped EL layer 112B is formed (FIG. 10C). For the formation of the EL layer 112B, for example, the description of the formation of the EL layer 112R can be referred to. Here, it is possible that the EL layer 112B is not formed in the region indicated by dashed-dotted line C1-C2. As in the case of the EL layer 112R and the EL layer 112G, it is preferable to remove impurities attached to the surface of the EL layer 112B. For example, impurities attached to the EL layer 112B can be removed when the substrate where the EL layer 112B is formed is put in an inert gas atmosphere after the formation of the EL layer 112B.

The insulating layer 105 is sometimes etched in a region not overlapping with the sacrificial layer 145 by the etching of the EL film 112Bf. Accordingly, the thickness of the insulating layer 105 in a region where its top surface is exposed is smaller than that of the insulating layer 105 in another region in the step illustrated in FIG. 10C in some cases. Thus, as illustrated in FIG. 3B, the thickness of the insulating layer 105 in a region overlapping with neither the pixel electrode 111 nor the EL layer 112 is smaller than the thickness ti_{R}, the thickness ti_{G}, and the thickness tip in some cases. Note that in the case where the EL film 112Bf has high etching selectivity over the insulating layer 105, the insulating layer 105 is sometimes not etched.

Here, when the EL film 112Bf is etched, the EL layer 112R, the sacrificial layer 145Ra, and the sacrificial layer 145Rb are formed in the region between the pixel electrode 111 and the connection electrode 113, that is, the region corresponding to the region 141 illustrated in FIG. 1. Accordingly, the insulating layer 105 in the region is not etched. Thus, as in the etching of the EL film 112Gf, the conductive layer 102b can be prevented from being exposed, whereby the display device 100 can be a highly reliable display device. In addition, the display device 100 can be manufactured by a method with a high yield, whereby the display device 100 can be an inexpensive display device.

Subsequently, the sacrificial layer 145Rb, the sacrificial layer 145Gb, and the sacrificial layer 145Bb are removed by etching or the like (FIG. 10D). The sacrificial layer 145Rb, the sacrificial layer 145Gb, and the sacrificial layer 145Bb are preferably removed by a method having high selectivity over the sacrificial layer 145Ra, the sacrificial layer 145Ga, and the sacrificial layer 145Ba. For example, the sacrificial layer 145Rb, the sacrificial layer 145Gb, and the sacrificial layer 145Bb can be removed by a dry etching method. Note that it is acceptable that the sacrificial layer 145Rb, the sacrificial layer 145Gb, and the sacrificial layer 145Bb are not removed immediately after the EL layer 112B is formed, and are removed in a later step.

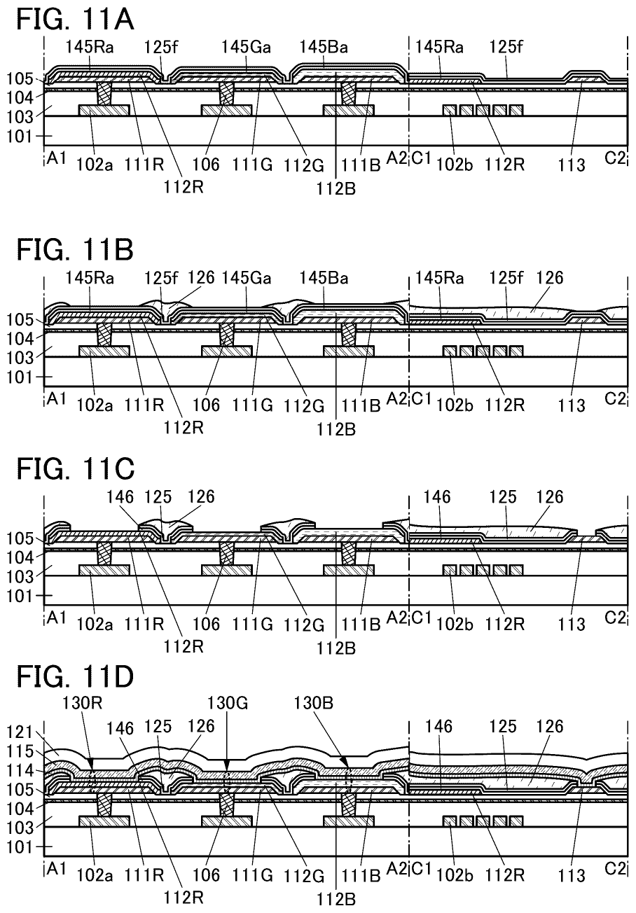

Next, an insulating film 125f to be the insulating layer 125 later is formed so as to cover the top surface of the insulating layer 105, the side surface of the EL layer 112, and the top and side surfaces of the sacrificial layer 145a (FIG. 11A).

Although the insulating film 125f can be formed by a sputtering method, a CVD method, a PLD method, an ALD method, or the like, it is preferably formed by an ALD method achieving favorable coverage. For the insulating film 125f, an inorganic material can be used, for example, and specifically, an inorganic insulating film such as an oxide insulating film, a nitride insulating film, an oxynitride insulating film, or a nitride oxide insulating film can be used. In particular, the insulating film 125f that is an inorganic insulating film such as an aluminum oxide film, a hafnium oxide film, or a silicon oxide film formed by an ALD method can be an insulating film with few pinholes.

Next, the insulating layer 126 is formed over the insulating film 125f (FIG. 11B). Specifically, a resin containing an organic material is applied to the insulating film 125f as a film to be the insulating layer 126, and the film is processed to form the insulating layer 126. It is preferable to use a photosensitive resin as the film to be the insulating layer 126. As the photosensitive resin, a positive material or a negative material can be used. In the case where a photosensitive resin is used as the film to be the insulating layer 126, the film to be the insulating layer 126 can be formed by a spin coating method, a spraying method, a screen printing method, a painting method, or the like.

Subsequently, the insulating layer 126 is formed. Here, when a photosensitive resin is used as the film to be the insulating layer 126, the insulating layer 126 can be formed without providing an etching mask such as a resist mask or a hard mask. Since a photosensitive resin can be processed only by light exposure and development steps, the insulating layer 126 can be formed without using a dry etching method, for example. Thus, the process can be simplified. In addition, damage to the EL layer 112 due to etching of the film to be the insulating layer 126 can be reduced.

The insulating layer 126 may alternatively be formed by performing etching substantially uniformly on the top surface of the film to be the insulating layer 126. Such uniform etching for planarization is also referred to as etch back.

To form the insulating layer 126, the light exposure and development steps and the etch back step may be used in combination.

Here, when a difference between the thickness of the EL layer 112R and the thickness of the EL layer 112G is large, a void is formed between the side surface of the EL layer 112 and the insulating layer 126 in a region between the EL layer 112R and the EL layer 112G. In particular, a void is sometimes formed between the insulating layer 126 and the side surface of the EL layer 112 which is either the EL layer 112R or the EL layer 112G which has a smaller thickness than the other. Similarly, when a difference between the thickness of the EL layer 112G and the thickness of the EL layer 112B is large, or when a difference between the thickness of the EL layer 112B and the thickness of the EL layer 112R is large, a void is formed between the side surface of the EL layer 112 and the insulating layer 126 in some cases. When such a void is formed, impurities easily enter the EL layer 112, and the reliability of the display device might accordingly be degraded.

Thus, a difference between the thickness of the EL layer 112R, the thickness of the EL layer 112G, and the thickness of the EL layer 112B is preferably small. Specifically, among the thickness of the EL layer 112R, the thickness of the EL layer 112G, and the thickness of the EL layer 112B, a difference between the largest thickness and the smallest thickness is preferably less than or equal to 100 nm, further preferably less than or equal to 80 nm. Accordingly, the void is not formed, so that the display device 100 can be a highly reliable display device.

Next, the insulating layer 125 is formed by etching of the insulating film 125f, and the protective layer 146 is formed by etching of the sacrificial layer 145a (FIG. 11C). Here, the protective layer 146 is formed by etching of the sacrificial layer 145a; accordingly, the protective layer 146 can also be referred to as a sacrificial layer.

The insulating film 125f and the sacrificial layer 145a can be etched using the insulating layer 126 as a mask. Accordingly, the insulating layer 125 and the protective layer 146 are formed so as to overlap with the insulating layer 126. Note that in the case where a step illustrated in FIG. 10D is not performed, that is, the case where the insulating film 125f is deposited without a removal of the sacrificial layer 145b after the formation of the EL layer 112B, the protective layer 146 is formed by etching of the sacrificial layer 145b and the sacrificial layer 145a.

Anisotropic etching is preferably performed for the etching of the insulating film 125f, in which case the insulating layer 125 can be suitably formed without patterning using a photolithography method, for instance. Forming the insulating layer 125 without patterning using a photolithography method, for example, enables simplification of the manufacturing process of the display device 100, resulting in lower manufacturing cost of the display device 100. Thus, the display device 100 can be an inexpensive display device. For example, a dry etching method can be given as anisotropic etching. In the case where the insulating film 125f is etched by a dry etching method, for example, the insulating film 125f can be etched with the use of an etching gas usable in etching of the sacrificial film 144.

The sacrificial layer 145a is preferably etched by a method that causes damage to the EL film 112 as little as possible. For example, the sacrificial layer 145a can be etched by a wet etching method.

Next, vacuum baking treatment is performed to remove, for example, water adsorbed on the surface of the EL layer 112. The vacuum baking is preferably performed, for instance, in a range of temperatures with which properties of the organic compounds contained in the EL layer 112 are not changed and can be performed, for example, at higher than or equal to 70° C. and lower than or equal to 120° C., preferably higher than or equal to 80° C. and lower than or equal to 100° C. Note that the vacuum baking treatment is not necessarily performed when, for example, water adsorbed on the surface of the EL layer 112 is small in amount and is less likely to adversely affect the reliability of the display device 100.

Next, the common layer 114 is formed over the EL layer 112, over the insulating layer 126, and over the connection electrode 113. As described above, the common layer 114 includes at least one of a hole-injection layer, a hole-transport layer, a hole-blocking layer, an electron-blocking layer, an electron-transport layer, and an electron-injection layer and includes, for example, an electron-injection layer or a hole-injection layer. The common layer 114 can be formed by, for example, an evaporation method, a sputtering method, an inkjet method, or the like. Note that in the case where the common layer 114 is not provided over the connection electrode 113, a metal mask that shields the upper portion of the connection electrode 113 is used in the formation of the common layer 114. The metal mask used here does not need to shield a pixel region of the display portion, so that a fine mask is not required; for example, a rough metal mask can be used.

Subsequently, the common electrode 115 is formed over the common layer 114. The common electrode 115 can be formed by a sputtering method or a vacuum evaporation method, for example.

Next, the protective layer 121 is formed over the common electrode 115 (FIG. 11D). When an inorganic insulating film is used as the protective layer 121, the protective layer 121 is preferably formed by a sputtering method, a CVD method, or an ALD method, for example. When an organic insulating film is used as the protective layer 121, the protective layer 121 is preferably formed by an inkjet method, for example, in which case a uniform film can be formed in a desired area.

Through the above steps, the display device 100 in which the light-emitting element 130 has the structure illustrated in FIG. 2A and the connection portion 140 has the structure illustrated in FIG. 2C1 can be manufactured.

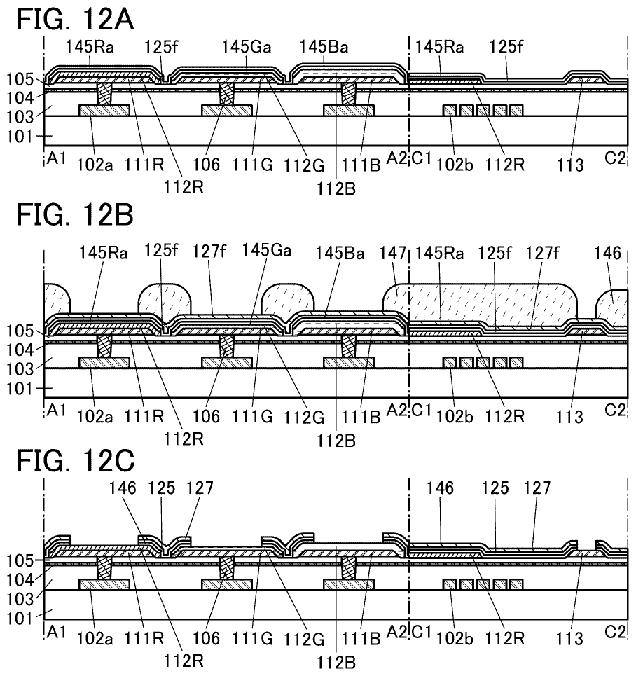

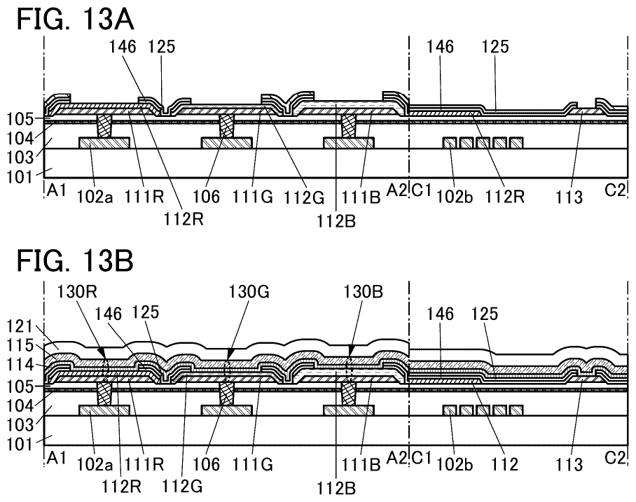

FIG. 12A to FIG. 13B are cross-sectional views illustrating an example of a method for manufacturing the display device 100 in which the light-emitting element 130 has the structure illustrated in FIG. 6A and the connection portion 140 has the structure illustrated in FIG. 6C1. FIG. 12A to FIG. 13B illustrate cross-sectional views taken along dashed-dotted line A1-A2 and cross-sectional views taken along dashed-dotted line C1-C2 in FIG. 1. Note that description of steps similar to those illustrated in FIG. 9A to FIG. 11D is omitted as appropriate.

In order to manufacture the above-described display device 100, steps similar to those illustrated in FIG. 9A to FIG. 11A are performed first. In other words, steps up to the formation of the insulating film 125f are performed (FIG. 12A). Then, a protective film 127f to be the protective layer 127 later is formed over the insulating film 125f. The protective film 127f can be deposited by a deposition method similar to that for the insulating film 125f, and is preferably formed by an ALD method achieving favorable coverage like the insulating film 125f. Alternatively, for the protective film 127f, an inorganic material can be used, for example, and a nitride insulating film such as a silicon nitride film and an aluminum nitride film can be suitably used.

Next, a resist mask 147 is formed over the protective film 127f (FIG. 12B). For the resist mask 147, a resist material containing a photosensitive resin, such as a positive type resist material or a negative type resist material can be used like the resist mask 143.

When the resist mask 147 is formed over the protective film 127f, components contained in the resist mask 147 can be inhibited from entering the EL layer 112 as compared with the case where the resist mask 147 is formed so as to be in contact with the insulating film 125f. Accordingly, the display device 100 can be a highly reliable display device.

Subsequently, the protective layer 127 and the insulating layer 125 are formed by etching of the protective film 127f and the insulating film 125f, and the protective layer 146 is formed by etching of the sacrificial layer 145a. Furthermore, the resist mask 147 is removed (FIG. 12C). Here, the following is preferable: part of the protective film 127f is removed by etching using the resist mask 147 to form the protective layer 127; the resist mask 147 is removed; and then the insulating film 125f and the sacrificial layer 145a are etched using the protective layer 127 as a hard mask.

The protective film 127f can be etched by a method similar to the method that can be used for the etching of the sacrificial film 144b. For example, the protective film 127f can be processed by a dry etching method. Here, the etching of the protective film 127f preferably employs etching conditions with high selectivity over the insulating film 125f. Moreover, the insulating film 125f can be etched by a method similar to the method that can be used for the etching of the sacrificial film 144a. For example, the insulating film 125f can be etched by a wet etching method. Furthermore, the resist mask 147 can be removed by a method similar to that for removing the resist mask 143; for example, a plasma ashing method can be used.

Next, the protective layer 127 is removed by an etching method, for example (FIG. 13A). The protective layer 127 is preferably removed by a method that causes damage to the EL film 112 as little as possible. The protective layer 127 can be etched by a wet etching method, for instance.

In the case where the protective layer 127 is removed by an etching method, for example, a metal oxide such as an indium gallium zinc oxide (an In—Ga—Zn oxide) is preferably used for the protective layer 127. Accordingly, the protective layer 127 can be suitably removed by a wet etching method, for example. Note that the protective layer 127 is not necessarily removed. In this case, an insulator such as a nitride insulator can be used for the protective layer 127.

Next, vacuum baking treatment is performed to remove water, for example, adsorbed on the surface of the EL layer 112. As described above, the vacuum baking is preferably performed, for instance, in a range of temperatures with which properties of the organic compounds contained in the EL layer 112 is not changed, for example, at higher than or equal to 70° C. and lower than or equal to 120° C., preferably higher than or equal to 80° C. and lower than or equal to 100° C. Note that the vacuum baking treatment is not necessarily performed when, for example, water adsorbed on the surface of the EL layer 112 is small in amount and is less likely to adversely affect the reliability of the display device 100.

Subsequently, a step similar to that illustrated in FIG. 11D is performed. In this manner, the common layer 114, the common electrode 115, and the protective layer 121 are formed (FIG. 13B). Through the above steps, the display device 100 in which the light-emitting element 130 has the structure illustrated in FIG. 6A and the connection portion 140 has the structure illustrated in FIG. 6C1 can be manufactured.

In the method for manufacturing a display device having an MML structure like that illustrated in FIG. 9A to FIG. 13B, an island-shaped EL layer 112 is formed not by patterning with the use of a metal mask but by processing after a deposition of an EL film 112f over the entire surface. Accordingly, a high-resolution display device or a display device with a high aperture ratio can be obtained. Moreover, EL layers 112 can be formed separately for the respective colors, enabling the display device to perform extremely clear display with high contrast and high display quality. In addition, a sacrificial layer provided over the EL layer 112 can reduce damage to the EL layer 112 in the manufacturing process of the display device 100, increasing the reliability of the light-emitting element 130.

The display device 100 can have a structure in which an insulator covering the end portion of the pixel electrode 111 is not provided. In other words, an insulating layer is not provided between the pixel electrode 111 and the EL layer 112 in the structure. With this structure, light emitted from the EL layer 112 can be efficiently extracted.

In the display device 100, light can be efficiently extracted from the EL layer 112, leading to extremely low viewing angle dependence. For example, in the display device 100, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction. The display device of one embodiment of the present invention can have improved viewing angle dependence and high image visibility.

Note that in the case where the display device 100 is a device with a fine metal mask (FMM) structure, the pixel arrangement structure or the like is limited in some cases. Here, a device with an FMM structure will be described below.

In the case of forming a device with an FMM structure, a metal mask provided with an opening portion (also referred to as an FMM) is set to be opposed to a substrate so that an EL material is deposited to a desired region at the time of EL evaporation. Then, the EL is deposited to the desired region by EL evaporation through the FMM. When the area of the substrate at the time of EL evaporation is larger, the area of the FMM is increased and accordingly the weight thereof is also increased. In addition, heat or the like is applied to the FMM at the time of EL evaporation and may change the shape of the FMM. For example, there is a method in which EL evaporation is performed while a certain level of tension is applied to the FMM; accordingly, the weight and strength of the FMM are important parameters.

Thus, the pixel arrangement structure with an FMM needs to be designed under certain restrictions and the above-described parameters need to be considered. Meanwhile, the display device of one embodiment of the present invention, which is a device with the MML structure, has an excellent effect of a higher degree of freedom in a configuration of pixel arrangement and the like than a device with the FMM structure. Note that the MML structure has higher design flexibility than the FMM structure and thus is highly compatible with flexible devices, for example.

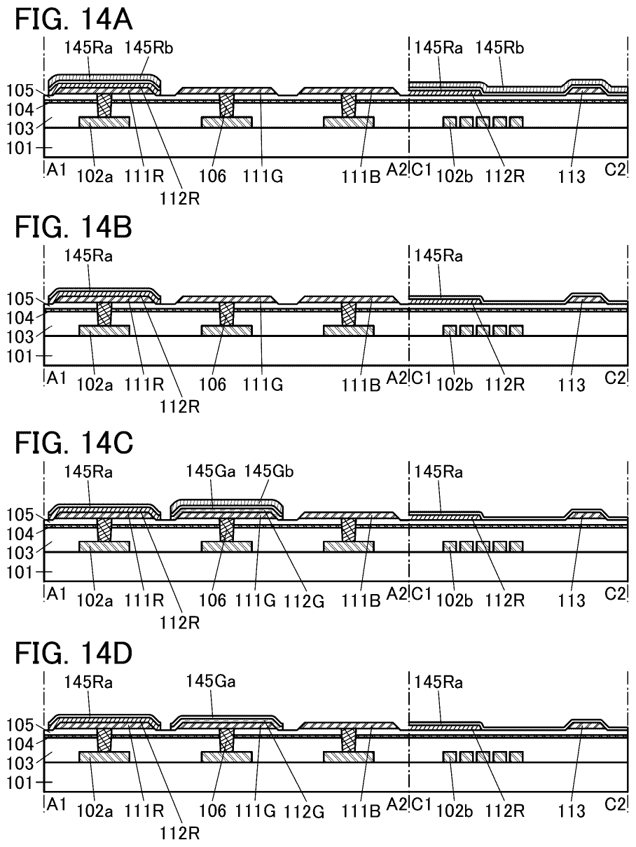

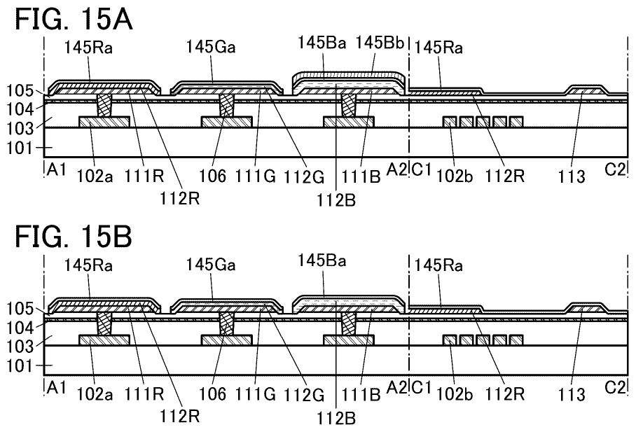

Although an example in which the sacrificial layer 145Rb, the sacrificial layer 145Gb, and the sacrificial layer 145Bb are removed in parallel after all of the EL layer 112R, the EL layer 112G, and the EL layer 112B are formed is shown in the above-described method for manufacturing a display device, one embodiment of the present invention is not limited thereto. FIG. 14A to FIG. 15B illustrate a modification example of the above-described method for manufacturing a display device and illustrate an example in which the sacrificial layer 145Rb is removed after the formation of the EL layer 112G but before the formation of the EL layer 112B, and the sacrificial layer 145Gb is removed after the formation of the EL layer 112G but before the formation of the EL layer 112B.

First, steps similar to those in FIG. 9A to FIG. 9C are performed (FIG. 14A). Next, the sacrificial layer 145Rb is removed by etching, for example (FIG. 14B). Then, steps similar to those in FIG. 9D1 and FIG. 10A are performed (FIG. 14C). Subsequently, the sacrificial layer 145Gb is removed by etching, for example (FIG. 14D). Next, steps similar to those in FIG. 10B and FIG. 10C are performed (FIG. 15A). Then, the sacrificial layer 145Bb is removed by etching, for example (FIG. 15B). Subsequently, steps similar to those in FIG. 11A to FIG. 11D are performed. The display device 100 can be manufactured also by the above-described method.

At least part of the structure examples, the drawings corresponding thereto, and the like described in this embodiment as an example can be combined with the other structure examples, the other drawings, and the like as appropriate.

At least part of this embodiment can be implemented in combination with the other embodiments or an example described in this specification as appropriate.

### Embodiment 2

In this embodiment, examples of pixel layouts of a display device of one embodiment of the present invention are described.

There is no particular limitation on an arrangement of subpixels 110 included in the display device 100, which is a display device of one embodiment of the present invention; a variety of methods can be employed. Examples of the arrangement of the subpixels 110 include stripe arrangement, S-stripe arrangement, matrix arrangement, delta arrangement, Bayer arrangement, and PenTile arrangement.

Examples of the top surface shape of the subpixel 110 include polygons such as a triangle, a tetragon (including a rectangle and a square), and a pentagon; polygons with rounded corners; an ellipse; and a circle. Here, the top surface shape of the subpixel 110 corresponds to the top surface shape of a light-emitting region of the light-emitting element 130.

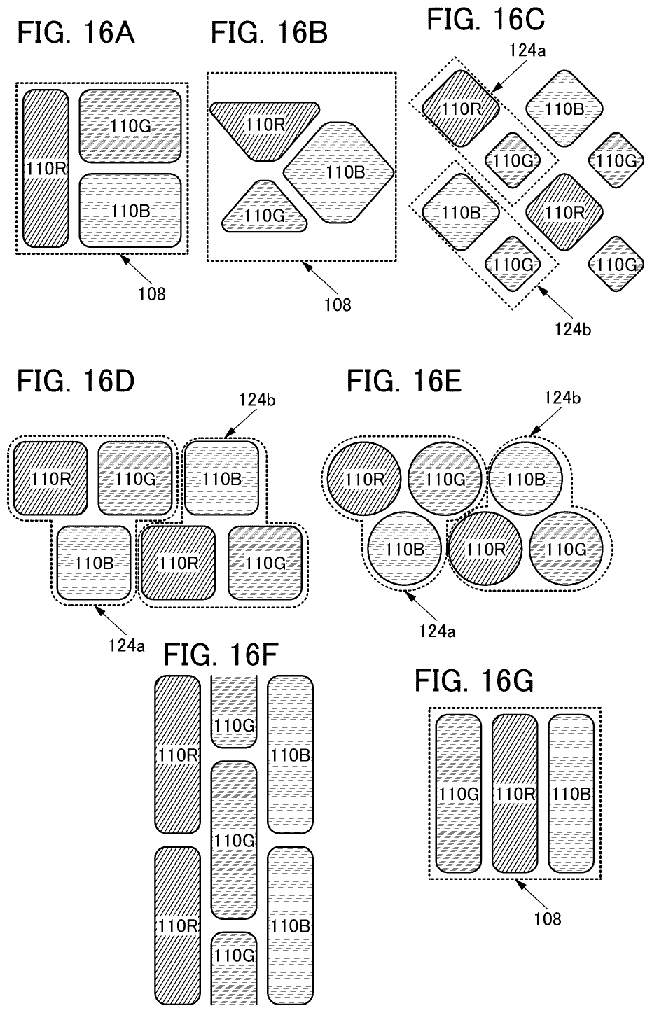

A pixel 108 illustrated in FIG. 16A employs S-stripe arrangement. The pixel 108 illustrated in FIG. 16A consists of three subpixels: the subpixel 110R, the subpixel 110G, and the subpixel 110B.

The pixel 108 illustrated in FIG. 16B includes the subpixel 110R whose top surface shape is a rough trapezoid with rounded corners, the subpixel 110G whose top surface shape is a rough triangle with rounded corners, and the subpixel 110B whose top surface shape is a rough tetragon or rough hexagon with rounded corners. The subpixel 110R has a larger light-emitting area than the subpixel 110G. In this manner, the shapes and sizes of the subpixels can be determined independently. For example, the size of a subpixel including a light-emitting element with higher reliability can be smaller.

A pixel 124a and a pixel 124b illustrated in FIG. 16C employ PenTile arrangement. FIG. 16C illustrates an example in which the pixels 124a including the subpixels 110R and the subpixels 110G and the pixels 124b including the subpixels 110G and the subpixels 110B are alternately arranged.

The pixel 124a and the pixel 124b illustrated in FIG. 16D and FIG. 16E employ delta arrangement. The pixel 124a includes two subpixels (the subpixel 110R and the subpixel 110G) in the upper row (first row) and one subpixel (the subpixel 110B) in the lower row (second row). The pixel 124b includes one subpixel (the subpixel 110B) in the upper row (first row) and two subpixels (the subpixel 110R and the subpixel 110G) in the lower row (second row).

FIG. 16D illustrates an example in which the top surface of each subpixel has a rough tetragonal shape with rounded corners, and FIG. 16E illustrates an example in which the top surface of each subpixel is circular.

FIG. 16F illustrates an example in which subpixels of different colors are arranged in a zigzag manner. Specifically, the positions of the top sides of two subpixels arranged in the column direction (e.g., the subpixel 110R and the subpixel 110G or the subpixel 110G and the subpixel 110B) are not aligned in the plan view.

In a photolithography method, as a pattern to be processed becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the display device of one embodiment of the present invention, the EL layer is processed with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film may have a shape different from a desired shape when processed. As a result, the top surface of the EL layer may have a polygonal shape with rounded corners, an elliptical shape, a circular shape, or the like. For example, when a resist mask with a square top surface shape is intended to be formed, a resist mask with a circular top surface shape might be formed, and the top surface shape of the EL layer might be circular.

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion of a figure on a mask pattern, for example.

Note that there is no particular limitation on the arrangement order of the subpixels in the pixel 108 illustrated in FIG. 1, which employs stripe arrangement; for example, as illustrated in FIG. 16G, the subpixel 110G, the subpixel 110R, and the subpixel 110B can be arranged in this order.

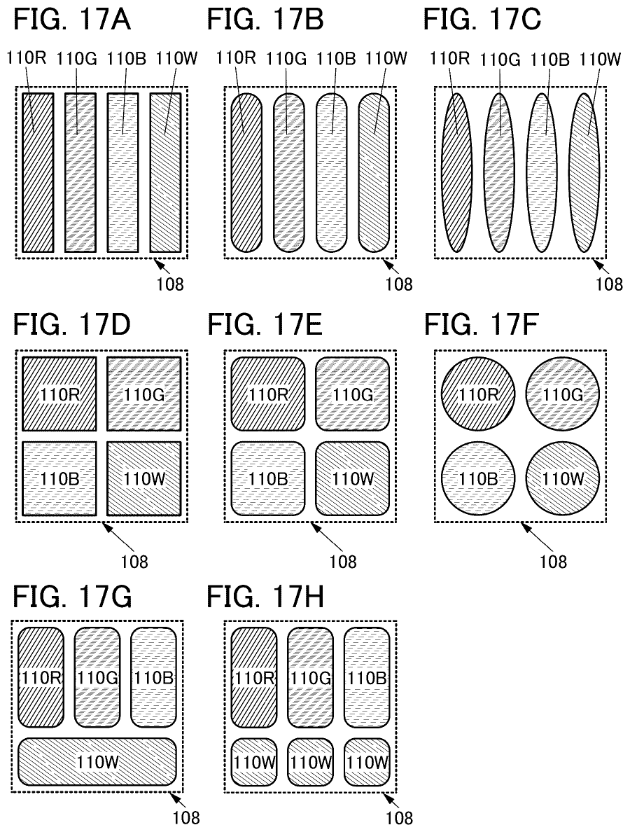

As illustrated in FIG. 17A to FIG. 17H, the pixel 108 can include a subpixel 110W in addition to the subpixel 110R, the subpixel 110G, and the subpixel 110B. Here, the subpixel 110W can exhibit white light.

The pixels 108 illustrated in FIG. 17A to FIG. 17C employ stripe arrangement.

FIG. 17A illustrates an example in which each subpixel has a rectangular top surface shape, FIG. 17B illustrates an example in which each subpixel has a top surface shape formed by combining two half circles and a rectangle, and FIG. 17C illustrates an example in which each subpixel has an elliptical top surface shape.

The pixels 108 illustrated in FIG. 17D to FIG. 17F employ matrix arrangement.

FIG. 17D illustrates an example in which each subpixel has a square top surface shape, FIG. 17E illustrates an example in which each subpixel has a rough square top surface shape with rounded corners, and FIG. 17F illustrates an example in which each subpixel has a circular top surface shape.

FIG. 17G and FIG. 17H each illustrate an example where one pixel 108 is composed of two rows and three columns.

The pixel 108 illustrated in FIG. 17G includes three subpixels (the subpixel 110R, the subpixel 110G, and the subpixel 110B) in the upper row (first row) and one subpixel (the subpixel 110W) in the lower row (second row). In other words, the pixel 108 includes the subpixel 110R in the left column (first column), the subpixel 110G in the center column (second column), the subpixel 110B in the right column (third column), and the subpixel 110W across these three columns.

The pixel 108 illustrated in FIG. 17H includes three subpixels (the subpixel 110R, the subpixel 110G, and the subpixel 110B) in the upper row (first row) and three subpixels 110W in the lower row (second row). In other words, the pixel 108 includes the subpixel 110R and the subpixel 110W in the left column (first column), the subpixel 110G and another subpixel 110W in the center column (second column), and the subpixel 110B and another subpixel 110W in the right column (third column). Matching the positions of the subpixels in the upper row and the lower row as illustrated in FIG. 17H enables dust and the like that would be produced in the manufacturing process to be removed efficiently, for example. Thus, a display device with high display quality can be provided.

The pixel 108 illustrated in FIG. 17A to FIG. 17H consists of four subpixels: the subpixel 110R, the subpixel 110G, the subpixel 110B, and the subpixel 110W. The subpixel 110R, the subpixel 110G, the subpixel 110B, and the subpixel 110W include light-emitting elements that emit light of different colors from one another.

As described above, the pixel composed of the subpixels each including the light-emitting element can employ any of a variety of layouts in the display device of one embodiment of the present invention.

At least part of the structure examples, the drawings corresponding thereto, and the like described in this embodiment as an example can be combined with the other structure examples, the other drawings, and the like as appropriate.

At least part of this embodiment can be implemented in combination with the other embodiments or an example described in this specification as appropriate.

### Embodiment 3

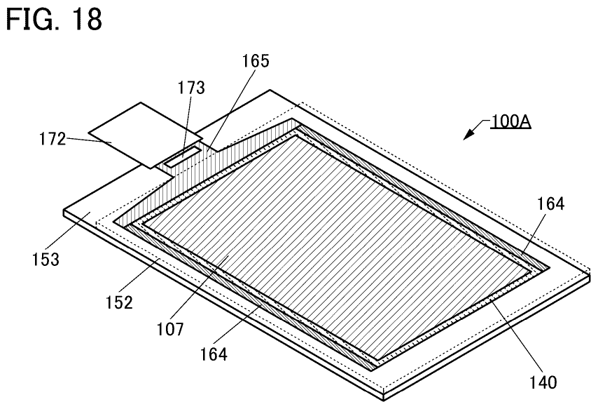

In this embodiment, a display device of one embodiment of the present invention is described with reference to FIG. 18 to FIG. 21.

The display device in this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### [Display Device 100A]

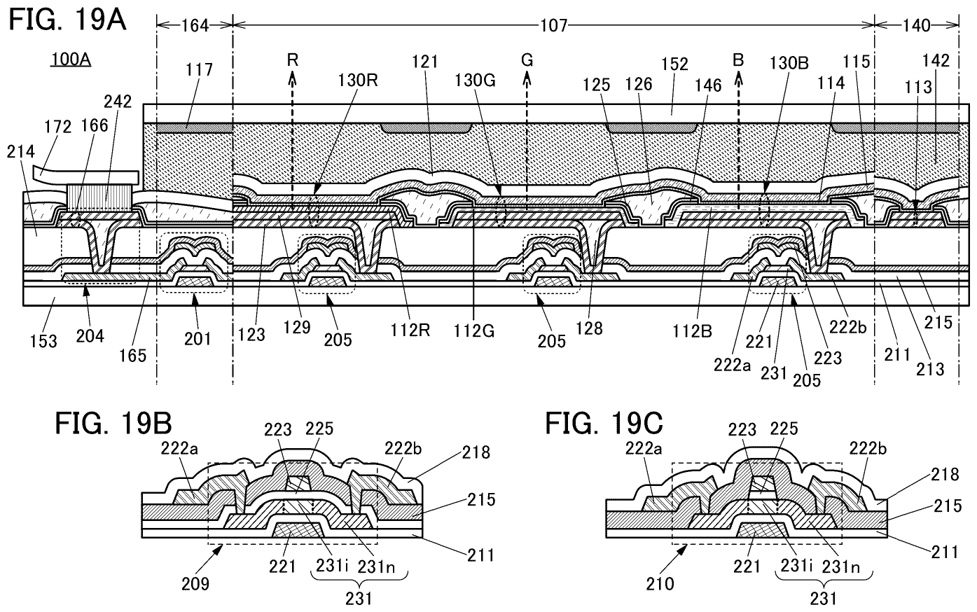

FIG. 18 is a perspective view of a display device 100A, and FIG. 19A is a cross-sectional view of the display device 100A.

The display device 100A has a structure in which a substrate 152 and a substrate 153 are bonded to each other. In FIG. 18, the substrate 152 is denoted by a dashed line.

The display device 100A includes the pixel portion 107, the connection portion 140, a circuit 164, a wiring 165, and the like. FIG. 18 illustrates an example in which an IC 173 and an FPC 172 are mounted on the display device 100A. Thus, the structure illustrated in FIG. 18 can be regarded as a display module including the display device 100A, the IC (integrated circuit), and the FPC.

The connection portion 140 is provided outside the pixel portion 107. The connection portion 140 can be provided along one or more sides of the pixel portion 107. The number of connection portions 140 can be one or more. FIG. 18 illustrates an example where the connection portion 140 is provided to surround the four sides of the display portion. A common electrode of a light-emitting element is electrically connected to a conductive layer in the connection portion 140, so that a potential can be supplied to the common electrode.

As the circuit 164, a scan line driver circuit can be used, for example.

The wiring 165 has a function of supplying a signal and power to the pixel portion 107 and the circuit 164. The signal and power are input to the wiring 165 from the outside through the FPC 172 or from the IC 173.

FIG. 18 illustrates an example in which the IC 173 is provided over the substrate 153 by a COG method, a COF (Chip On Film) method, or the like. An IC including a scan line driver circuit, a signal line driver circuit, or the like can be used as the IC 173, for example. Note that the display device 100A and the display module are not necessarily provided with an IC. The IC may be mounted on the FPC by a COF method or the like.

FIG. 19A illustrates an example of cross sections of part of a region including the FPC 172, part of the circuit 164, part of the pixel portion 107, part of the connection portion 140, and part of a region including an end portion of the display device 100A.

The display device 100A illustrated in FIG. 19A includes a transistor 201, a transistor 205, the light-emitting element 130, and the like between the substrate 153 and the substrate 152.

For the display device 100A, the pixel layout exemplified in Embodiment 1 or Embodiment 2 can be employed.

Other than a difference in the structure of a pixel electrode, the light-emitting element 130 has the stacked structure illustrated in FIG. 2A. For details of the light-emitting element 130, Embodiment 1 can be referred to.

The light-emitting element 130 includes a conductive layer 123 and a conductive layer 129 over the conductive layer 123. One or both of the conductive layer 123 and the conductive layer 129 can be referred to as a pixel electrode.

The conductive layer 123 is connected to a conductive layer 222b included in the transistor 205 through an opening provided in an insulating layer 214, an insulating layer 215, and an insulating layer 213. In the display device 100A, an end portion of the conductive layer 123 and an end portion of the conductive layer 129 are aligned or substantially aligned with each other; however, one embodiment of the present invention is not limited thereto. For example, the conductive layer 129 may be provided so as to cover an end portion of the conductive layer 123. The conductive layer 123 and the conductive layer 129 each preferably include a conductive layer functioning as a reflective electrode. The one or both of the conductive layer 123 and the conductive layer 129 may include a conductive layer functioning as a transparent electrode.

A depressed portion is formed in the conductive layer 123 so as to cover the opening provided in the insulating layer 214, the insulating layer 215, and the insulating layer 213. A layer 128 is embedded in the depressed portion.

The layer 128 has a function of planarizing the depressed portion of the conductive layer 123. The conductive layer 129 electrically connected to the conductive layer 123 is provided over the conductive layer 123 and the layer 128. Thus, a region overlapping with the depressed portion of the conductive layer 123 can also be used as the light-emitting region, increasing the aperture ratio of the pixel.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive material or a negative material can be used.

When a photosensitive resin is used, the layer 128 can be formed through only light-exposure and development steps, reducing the influence of dry etching, wet etching, or the like on the surface of the conductive layer 123. When the layer 128 is formed using a negative photosensitive resin, the layer 128 can sometimes be formed using the same photomask (light-exposure mask) as the photomask used for forming the opening in the insulating layer 214.

The top and side surfaces of the conductive layer 129 are covered with the EL layer 112. Note that the side surface of the conductive layer 129 is not necessarily covered with the EL layer 112. Moreover, part of the top surface of the conductive layer 129 is not necessarily covered with the EL layer 112.

The protective layer 146 is provided so as to cover part of the EL layer 112. Moreover, the insulating layer 125 is provided so as to cover the top and side surfaces of the protective layer 146 and the side surface of the EL layer 112. Furthermore, the insulating layer 126 is provided over the insulating layer 125. The common layer 114 is provided over the EL layer 112 and over the insulating layer 126, and the common electrode 115 is provided over the common layer 114. The common layer 114 and the common electrode 115 are each one continuous film shared by the plurality of light-emitting elements 130.

The protective layer 121 is provided over the light-emitting element 130. Providing the protective layer 121 covering the light-emitting element 130 inhibits entry of impurities such as water into the light-emitting element 130, leading to an increase in the reliability of the light-emitting element 130.

The protective layer 121 and the substrate 152 are bonded to each other with an adhesive layer 142. A solid sealing structure, a hollow sealing structure, or the like can be employed to seal the light-emitting elements. In FIG. 19A, a solid sealing structure is employed in which a space between the substrate 152 and the protective layer 121 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting element. The space may be filled with a resin different from that of the frame-like adhesive layer.

The connection electrode 113 is provided over the insulating layer 214 in the connection portion 140. An example is illustrated in which the connection electrode 113 has a stacked-layer structure of a conductive film obtained by processing the same conductive film as the conductive layer 123 and a conductive film obtained by processing the same conductive film as the conductive layer 129. The side surface of the connection electrode 113 is covered with the protective layer 146. The insulating layer 125 is provided over the protective layer 146, and the insulating layer 126 is provided over the insulating layer 125. The common layer 114 is provided over the connection electrode 113, and the common electrode 115 is provided over the common layer 114. The connection electrode 113 and the common electrode 115 are electrically connected to each other through the common layer 114. Note that the common layer 114 is not necessarily formed in the connection portion 140. In this case, the connection electrode 113 and the common electrode 115 are in direct contact with each other to be electrically connected to each other.

The display device 100A has a top emission structure. Light emitted from the light-emitting element is emitted toward the substrate 152 side. For the substrate 152, a material having a transmitting property with respect to visible light is preferably used.

The pixel electrode contains a material that reflects visible light, and the common electrode 115 contains a material that transmits visible light.

The transistor 201 and the transistor 205 are formed over the substrate 153. These transistors can be manufactured using the same material in the same step.

An insulating layer 211, the insulating layer 213, the insulating layer 215, and the insulating layer 214 are provided in this order over the substrate 153. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers that cover the transistors. This allows the insulating layer to function as a barrier layer. Such a structure can effectively inhibit diffusion of impurities into the transistors from the outside and increase the reliability of a display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 214 may have a stacked-layer structure including an organic insulating film and an inorganic insulating film. The outermost layer of the insulating layer 214 preferably has a function of an etching protective film. Accordingly, a depressed portion can be prevented from being formed in the insulating layer 214 at the time of processing the conductive layer 123, the conductive layer 129, or the like. Alternatively, a depressed portion may be provided in the insulating layer 214 at the time of processing the conductive layer 123, the conductive layer 129, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure where the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor). That is, a transistor including a metal oxide in its channel formation region (hereinafter, referred to as an OS transistor) is preferably used for the display device of this embodiment.

As the oxide semiconductor having crystallinity, a CAAC (c-axis aligned crystalline)-OS, an nc (nanocrystalline)-OS, and the like are given.

Alternatively, a transistor using silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display device can be simplified, and costs of parts and mounting costs can be reduced.

An OS transistor has extremely higher field-effect mobility than a transistor containing amorphous silicon. In addition, the OS transistor has an extremely low leakage current between a source and a drain in an off state (hereinafter also referred to as off-state current), and charge accumulated in a capacitor that is connected in series to the transistor can be retained for a long period. Furthermore, power consumption of the display device can be reduced with the use of an OS transistor.

The off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than the off-state current of a Si transistor by approximately ten orders of magnitude.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor in the pixel circuit, the amount of current flowing through the light-emitting element can be increased, so that the emission luminance of the light-emitting element can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting element can be controlled. Accordingly, the gray level in the pixel circuit can be increased.

Regarding saturation characteristics of current flowing when the transistor operates in a saturation region, an OS transistor can feed more stable current (saturation current) than a Si transistor even when the source-drain voltage gradually increases. Thus, by using an OS transistor as the driving transistor, a stable current can be fed through a light-emitting element even when the current-voltage characteristics of the light-emitting element vary, for example. In other words, when the OS transistor operates in the saturation region, the source-drain current hardly changes with an increase in the source-drain voltage; hence, the emission luminance of the light-emitting element can be stable.

As described above, with use of an OS transistor as the driving transistor included in the pixel circuit, it is possible to achieve “inhibition of black floating”, “increase in emission luminance”, “increase in gray level”, “inhibition of variation in light-emitting devices”, and the like.

The semiconductor layer preferably includes indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the semiconductor layer is In-M-Zn oxide, the atomic ratio of In is preferably greater than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistors included in the circuit 164 and the transistors included in the pixel portion 107 may have the same structure or different structures. One structure or two or more types of structures may be employed for a plurality of transistors included in the circuit 164. Similarly, a plurality of transistors included in the pixel portion 107 may have the same structure or two or more kinds of structures.

All of the transistors included in the pixel portion 107 may be OS transistors or all of the transistors included in the pixel portion 107 may be Si transistors. Alternatively, some of the transistors included in the pixel portion 107 may be OS transistors and the others may be Si transistors.

For example, when both an LTPS transistor and an OS transistor are used in the pixel portion 107, the display device with low power consumption and high drive capability can be achieved. Note that a structure where an LTPS transistor and an OS transistor are used in combination is referred to as LTPO in some cases. For example, it is preferable to use an OS transistor as a transistor functioning as a switch for controlling electrical continuity between wirings and an LTPS transistor as a transistor for controlling a current.

For example, one transistor included in the pixel portion 107 functions as a transistor for controlling current flowing through the light-emitting element and can also be referred to as a driving transistor. One of a source and a drain of the driving transistor is electrically connected to the pixel electrode of the light-emitting element. An LTPS transistor is preferably used as the driving transistor. In this case, the amount of current flowing through the light-emitting element can be increased in the pixel circuit.

By contrast, another transistor included in the pixel portion 107 functions as a switch for controlling selection or non-selection of a pixel and can also be referred to as a selection transistor. A gate of the selection transistor is electrically connected to a gate line, and one of a source and a drain thereof is electrically connected to a signal line. An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display device of one embodiment of the present invention can have all of a high aperture ratio, high resolution, high display quality, and low power consumption.

The display device of one embodiment of the present invention has a structure including an OS transistor and the light-emitting element having the MML (metal mask less) structure. With this structure, the leakage current that might flow through the transistor and the leakage current that might flow between adjacent light-emitting elements (also referred to as a lateral leakage current, a side leakage current, or the like) can become extremely low. With this structure, a viewer can notice any one or more of the image crispness, the image sharpness, a high chroma, and a high contrast ratio in an image displayed on the display device. With the structure where the leakage current that might flow through the transistor and the lateral leakage current between light-emitting elements are extremely low, display with little leakage of light at the time of black display can be achieved, for example.

FIG. 19B and FIG. 19C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the low-resistance regions 231n, the conductive layer 222b connected to the other low-resistance region 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 19B illustrates an example of the transistor 209 in which the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 19C, the insulating layer 225 overlaps with the channel formation region 231i of the semiconductor layer 231 and does not overlap with the low-resistance regions 231n. The structure illustrated in FIG. 19C can be manufactured by processing the insulating layer 225 using the conductive layer 223 as a mask, for example. In FIG. 19C, the insulating layer 215 is provided to cover the insulating layer 225 and the conductive layer 223, and the conductive layer 222a and the conductive layer 222b are connected to the corresponding low-resistance regions 231n through the openings in the insulating layer 215.

A connection portion 204 is provided in a region of the substrate 153 where the substrate 152 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layer 123 and a conductive film obtained by processing the same conductive film as the conductive layer 129. The conductive layer 166 is exposed on the top surface of the connection portion 204. Thus, the connection portion 204 and the FPC 172 can be electrically connected to each other through the connection layer 242.

A light-blocking layer 117 is preferably provided on the surface of the substrate 152 on the substrate 153 side. Moreover, a coloring layer (also referred to as a color filter) may be provided on the surface of the substrate 152 on the substrate 153 side.

For each of the substrate 153 and the substrate 152, glass, quartz, ceramic, sapphire, resin, or the like can be used. When a flexible material is used for each of the substrate 153 and the substrate 152, the flexibility of the display device 100 can be increased.

For the adhesive layer 142, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used, for example.

As the connection layer 242, an anisotropic conductive film (ACF), an anisotropic conductive paste (ACP), or the like can be used.

As materials that can be used for conductive layers such as a variety of wirings and electrodes that constitute a display device, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the thickness is preferably set small enough to transmit light. A stacked film of any of the above materials can be used as a conductive layer. For example, a stacked film of indium tin oxide and an alloy of silver and magnesium is preferably used, in which case the conductivity can be increased. These materials can also be used for the conductive layers such as a variety of wirings and electrodes included in a display device, and conductive layers (conductive layers functioning as a pixel electrode or a common electrode) included in the light-emitting element.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

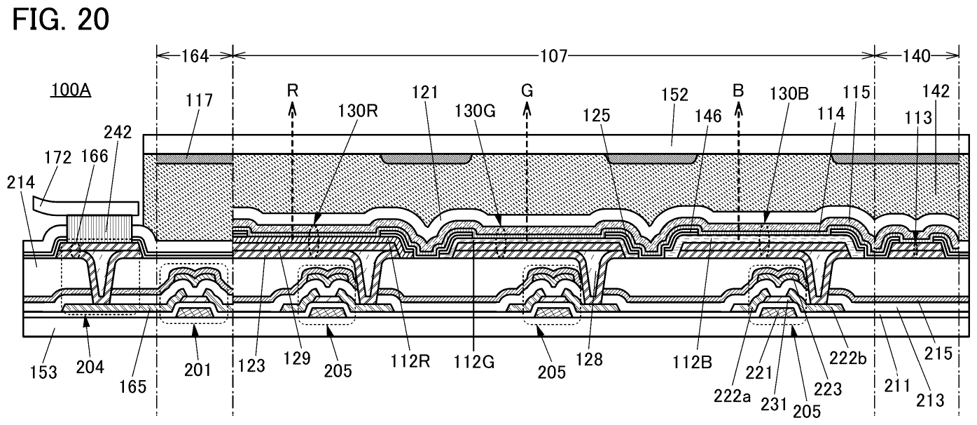

FIG. 20 is a modification example of the display device 100A illustrated in FIG. 19A and illustrates an example in which the insulating layer 126 is not provided.

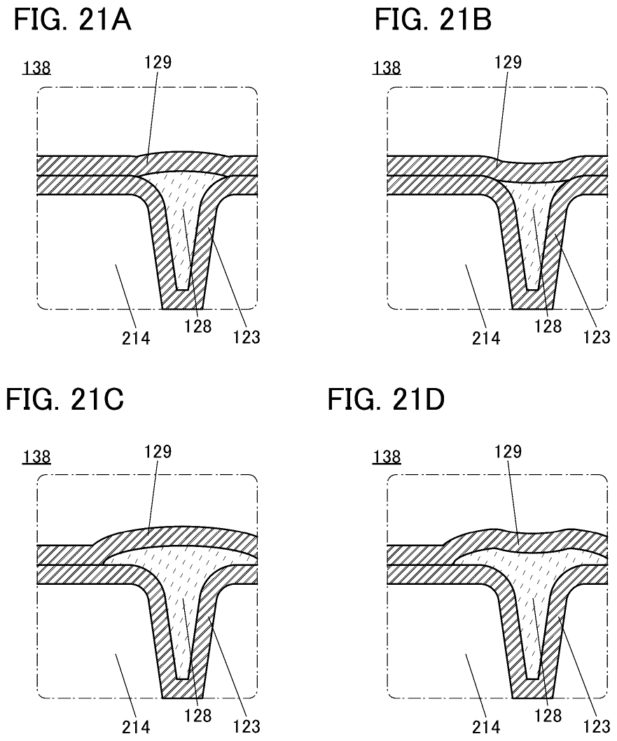

Here, FIG. 21A to FIG. 21D illustrate cross-sectional structures of a region 138 including the conductive layer 123, the layer 128, and the vicinity thereof.

FIG. 19A illustrates an example in which the top surface of the layer 128 and the top surface of the conductive layer 123 are substantially at the same level; however, the present invention is not limited to such an example. For example, as illustrated in FIG. 21A, the top surface of the layer 128 is at a higher level than the top surface of the conductive layer 123 in some cases. In this case, the top surface of the layer 128 has a projecting shape that is gently bulged toward the center.

As illustrated in FIG. 21B, the top surface of the layer 128 is at a lower level than the top surface of the conductive layer 123 in some cases. In this case, the top surface of the layer 128 has a depressed shape that is gently recessed toward the center.

When the top surface of the layer 128 is at a higher level than the top surface of the conductive layer 123 as illustrated in FIG. 21C, the upper portion of the layer 128 is sometimes formed to be wider than a depressed portion formed in the conductive layer 123. In this case, part of the layer 128 may be formed to cover part of a substantially flat region of the conductive layer 123.

As illustrated in FIG. 21D, part of the top surface of layer 128 has another depressed portion in the structure illustrated in FIG. 21C, in some cases. The depressed portion has a shape that is gently recessed toward the center.

At least part of the structure examples, the drawings corresponding thereto, and the like described in this embodiment as an example can be combined with the other structure examples, the other drawings, and the like as appropriate.

At least part of this embodiment can be implemented in combination with the other embodiments or an example described in this specification as appropriate.

### Embodiment 4

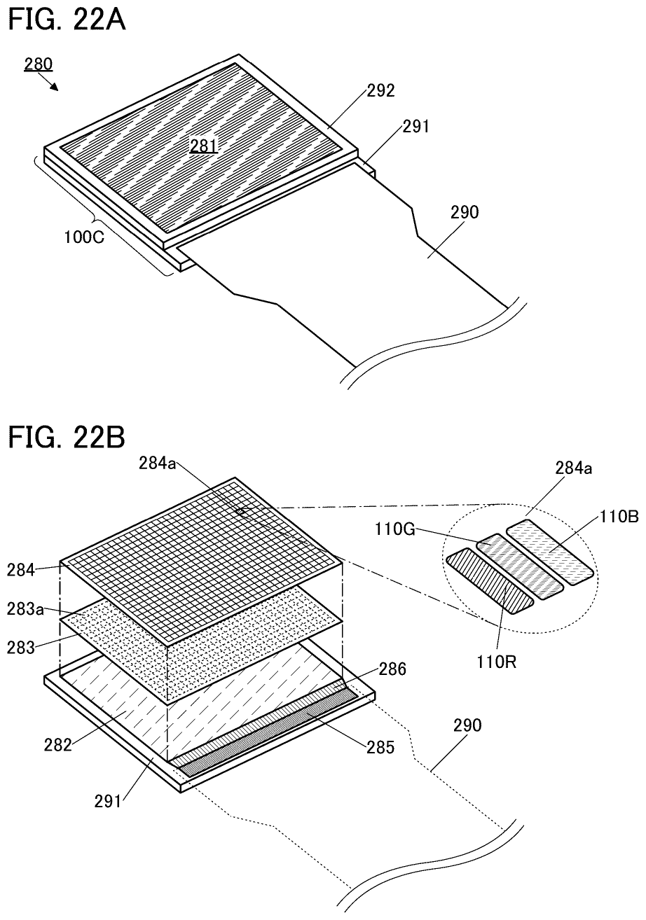

In this embodiment, a display device of one embodiment of the present invention is described with reference to FIG. 22 to FIG. 32.

The display device of this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display and a glasses-type AR device.

### [Display Module]

FIG. 22A is a perspective view of a display module 280. The display module 280 includes a display device 100C and an FPC 290. Note that the display device included in the display module 280 is not limited to the display device 100C and may be any of a display device 100D to a display device 100G described later.

The display module 280 includes a substrate 291 and a substrate 292. The display module 280 includes a display portion 281. The display portion 281 is a region of the display module 280 where an image is displayed and is a region where light from pixels provided in a pixel portion 284 described later can be perceived.

FIG. 22B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion that is over the substrate 291 and does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 22B. In the pixel 284a, the subpixel 110R emitting red light, the subpixel 110G emitting green light, and the subpixel 110B emitting blue light are arranged in this order. Embodiment 1 and Embodiment 2 can be referred to as a pixel layout applicable to the pixel portion 284.

The pixel circuit portion 283 includes a plurality of pixel circuits 283a arranged periodically.

One pixel circuit 283a is a circuit that controls light emission of three light-emitting elements included in one pixel 284a. One pixel circuit 283a may be provided with three circuits each of which controls light emission of one light-emitting element. For example, the pixel circuit 283a can include at least one selection transistor, one current control transistor (driving transistor), and a capacitor for one light-emitting element. In this case, a gate signal is input to a gate of the selection transistor, and a video signal is input to one of a source and a drain of the selection transistor. With such a structure, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. In addition, an IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even in the case of a structure in which the display portion of the display module 280 is perceived through a lens, pixels of the extremely-high-resolution display portion 281 included in the display module 280 are not perceived when the display portion is enlarged by the lens, so that display providing a high sense of immersion can be performed. Without limitation to the above, the display module 280 can also be suitably used for an electronic device having a relatively small display portion. For example, the display module 280 can be suitably used in a display portion of a wearable electronic device such as a wrist watch.

### <Display Device 100C>

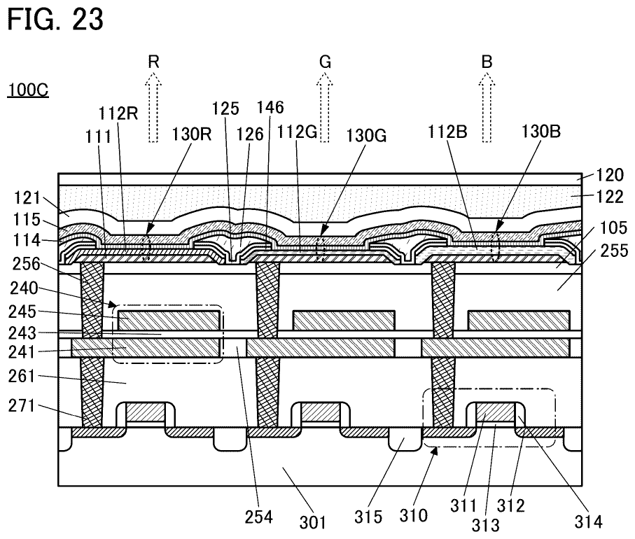

The display device 100C illustrated in FIG. 23 includes a substrate 301, the light-emitting element 130, a capacitor 240, and a transistor 310.

The substrate 301 corresponds to the substrate 291 illustrated in FIG. 22A and FIG. 22B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 so as to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, and the insulating layer 105 is provided over the insulating layer 255.

As each of the insulating layers 255, a variety of inorganic insulating films such as an oxide insulating film, a nitride insulating film, an oxynitride insulating film, and a nitride oxide insulating film can be suitably used. As the insulating layer 255, an oxide insulating film or an oxynitride insulating film, such as a silicon oxide film, a silicon oxynitride film, or an aluminum oxide film, is preferably used. Although this embodiment illustrates an example in which a depressed portion is provided in the insulating layer 105, a depressed portion is not necessarily provided in the insulating layer 105.

The light-emitting element 130 is provided over the insulating layer 105. In this embodiment, an example in which the light-emitting element 130 has the stacked-layer structure illustrated in FIG. 2A is shown.

The protective layer 146 is provided so as to cover part of the EL layer 112. The insulating layer 125 is provided so as to cover the top and side surfaces of the protective layer 146 and the side surface of the EL layer 112. Moreover, the insulating layer 126 is provided over the insulating layer 125. The common layer 114 is provided over the EL layer 112 and over the insulating layer 126, and the common electrode 115 is provided over the common layer 114. The common layer 114 and the common electrode 115 are each one continuous film shared by a plurality of light-emitting elements 130.

The pixel electrode 111 of the light-emitting element 130 is electrically connected to one of the source and the drain of the transistor 310 through a plug 256 embedded in the insulating layer 243, the insulating layer 255, and the insulating layer 105, the conductive layer 241 embedded in the insulating layer 254, and the plug 271 embedded in the insulating layer 261. The top surface of the insulating layer 105 and the top surface of the plug 256 are level with or substantially level with each other. A variety of conductive materials can be used for the plugs.

The protective layer 121 is provided over the light-emitting elements 130. A substrate 120 is bonded to the protective layer 121 with a resin layer 122. The substrate 120 corresponds to the substrate 292 illustrated in FIG. 22A.

As the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used, for example.

An end portion of the top surface of the pixel electrode 111 is not covered with an insulating layer. Thus, the distance between adjacent light-emitting elements can be extremely small. Accordingly, the display device can have high resolution or high definition.

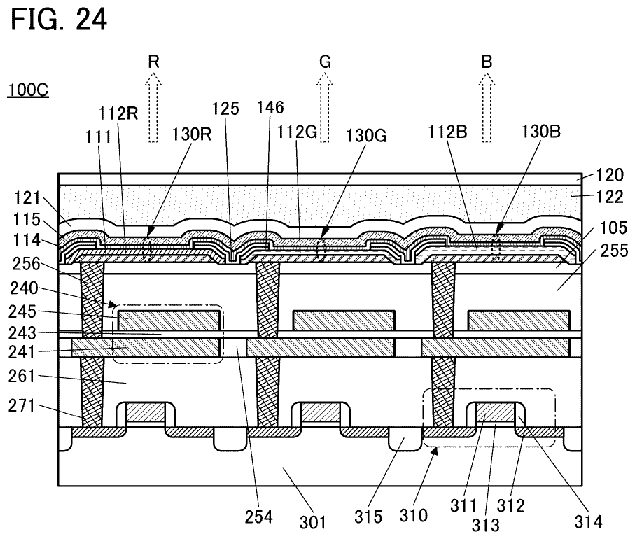

FIG. 24 is a modification example of the display device 100C illustrated in FIG. 23 and illustrates an example in which the insulating layer 126 is not provided.

### <Display Device 100D>

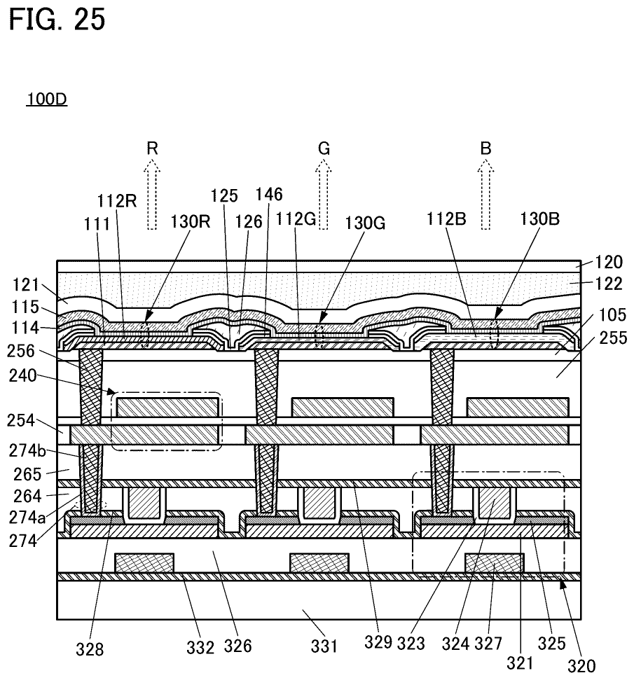

A display device 100D illustrated in FIG. 25 differs from the display device 100C mainly in a structure of a transistor. Note that in the description of the display device below, portions similar to those of the above-mentioned display device are not described in some cases.

A transistor 320 is a transistor that contains a metal oxide in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 22A and FIG. 22B. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, it is possible to use, for example, a film in which hydrogen or oxygen is less likely to be diffused than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics is preferably used as the semiconductor layer 321.

The pair of conductive layers 325 are provided over and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material in which hydrogen and oxygen are unlikely to diffuse is preferably used for the conductive layer 274a.

A structure including the insulating layer 254 and components thereover up to the substrate 120 in the display device 100D is similar to that of the display device 100C.

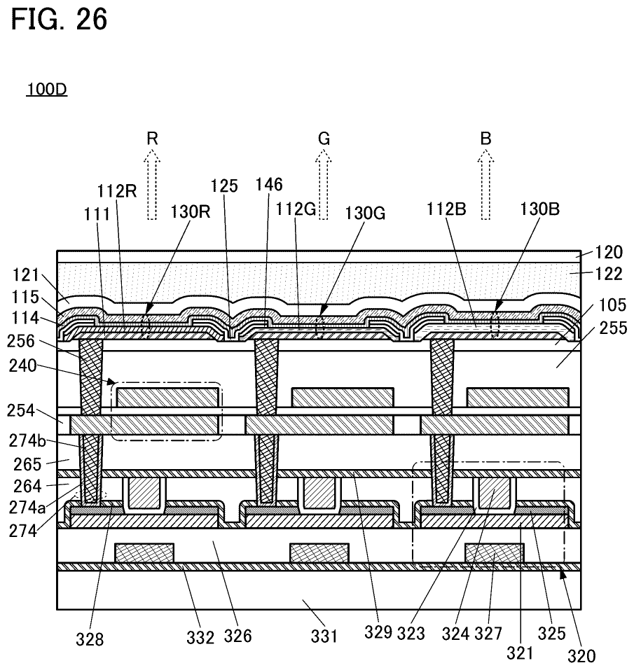

FIG. 26 is a modification example of the display device 100D illustrated in FIG. 25 and illustrates an example in which the insulating layer 126 is not provided.

### <Display Device 100E>

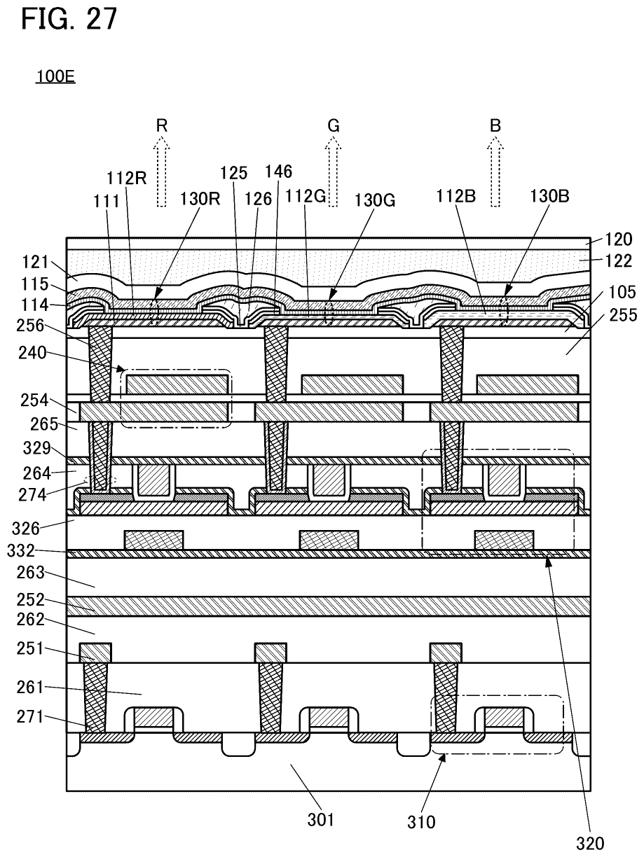

A display device 100E illustrated in FIG. 27 has a structure in which the transistor 310 whose channel is formed in the substrate 301 and the transistor 320 including a metal oxide in the semiconductor layer in which the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit for driving the pixel circuit (a gate line driver circuit or a source line driver circuit). Furthermore, the transistor 310 and the transistor 320 can be used as transistors included in a variety of circuits such as an arithmetic circuit and a memory circuit.

With such a structure, not only the pixel circuit but also, for example, the driver circuit can be formed directly under the light-emitting element; thus, the display device can be downsized as compared with the case where the driver circuit is provided around a display region.

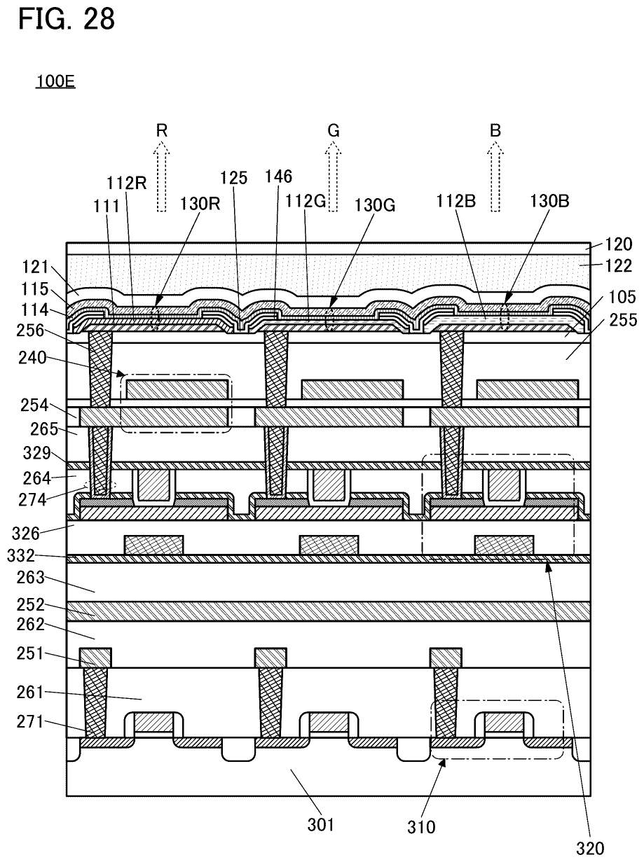

FIG. 28 is a modification example of the display device 100E illustrated in FIG. 27 and illustrates an example in which the insulating layer 126 is not provided.

### <Display Device 100F>

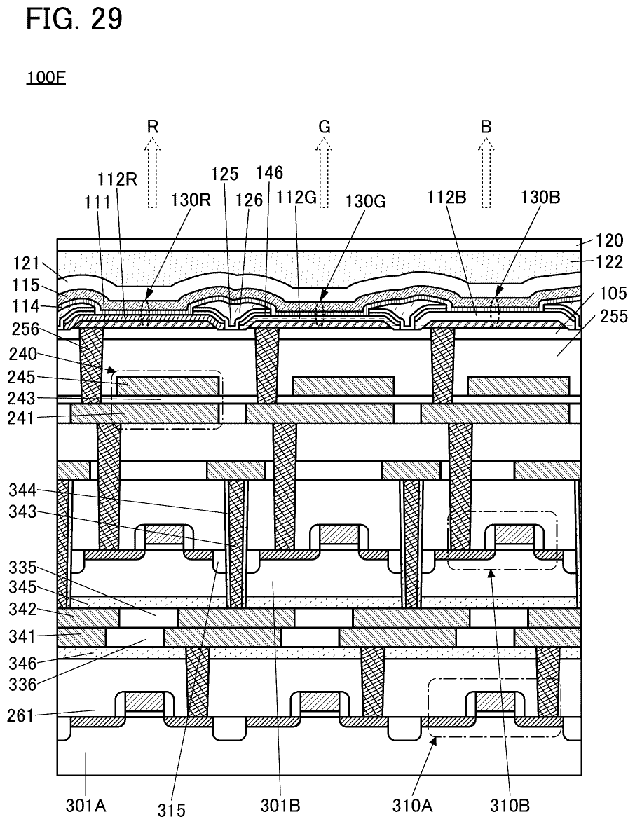

A display device 100F illustrated in FIG. 29 has a structure in which a transistor 310A and a transistor 310B in each of which a channel is formed in a semiconductor substrate are stacked.

In the display device 100F, a substrate 301B provided with the transistor 310B, the capacitor 240, and light-emitting elements is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 121 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. For the insulating layer 344, an inorganic insulating film that can be used for the protective layer 121 can be used.

A conductive layer 342 is provided under the insulating layer 345 on the rear surface of the substrate 301B (the surface of the substrate 301A). The conductive layer 342 is preferably provided so as to be embedded in an insulating layer 335. The bottom surfaces of the conductive layer 342 and the insulating layer 335 are preferably planarized. Here, the conductive layer 342 is electrically connected to the plug 343.

On the other hand, a conductive layer 341 is provided over the insulating layer 346 over the substrate 301A. The conductive layer 341 is preferably provided so as to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

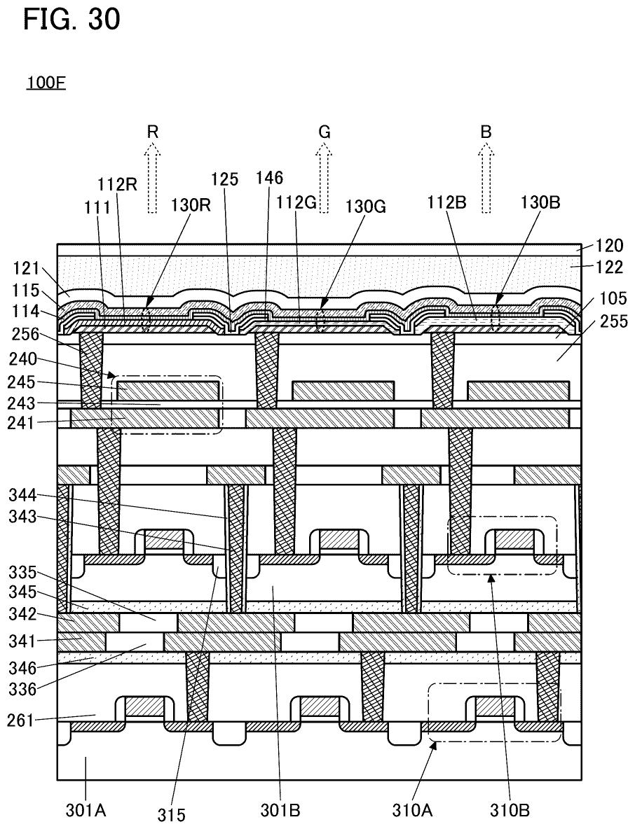

FIG. 30 is a modification example of the display device 100F illustrated in FIG. 29 and illustrates an example in which the insulating layer 126 is not provided.

### <Display Device 100G>

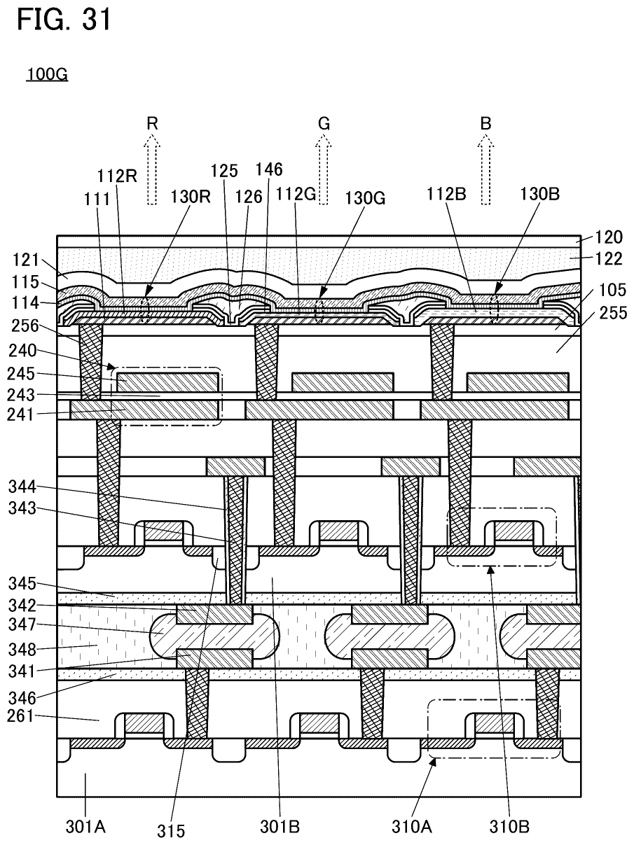

Although FIG. 29 illustrates an example in which Cu—Cu direct bonding technique is used to bond the conductive layer 341 and the conductive layer 342, the present invention is not limited thereto. As illustrated in FIG. 31, the conductive layer 341 and the conductive layer 342 may be bonded to each other through a bump 347 in the display device 100G.

As illustrated in FIG. 31, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

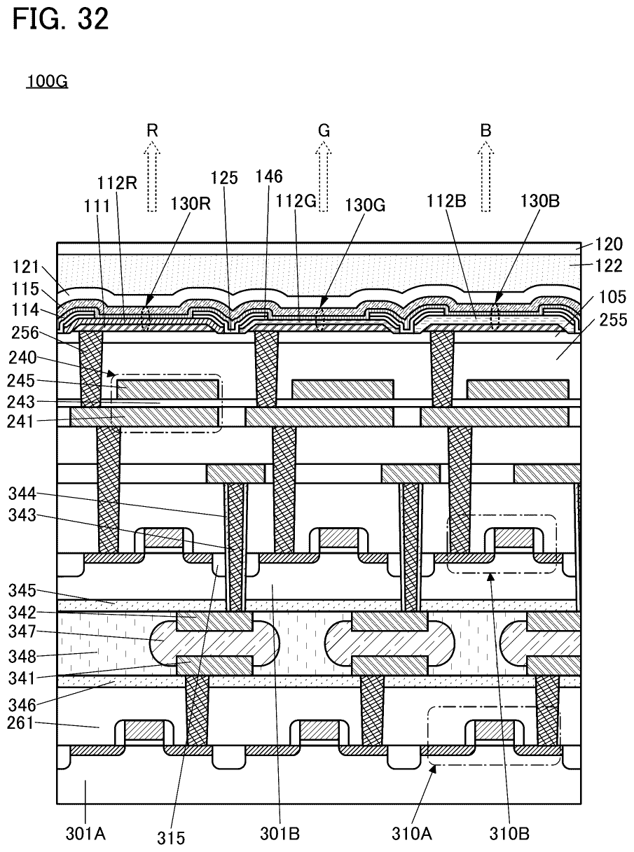

FIG. 32 is a modification example of the display device 100G illustrated in FIG. 31 and illustrates an example in which the insulating layer 126 is not provided.

At least part of the structure examples, the drawings corresponding thereto, and the like described in this embodiment as an example can be combined with the other structure examples, the other drawings, and the like as appropriate.

At least part of this embodiment can be implemented in combination with the other embodiments or an example described in this specification as appropriate.

### Embodiment 5

In this embodiment, light-emitting elements that can be used in a display device of one embodiment of the present invention will be described.

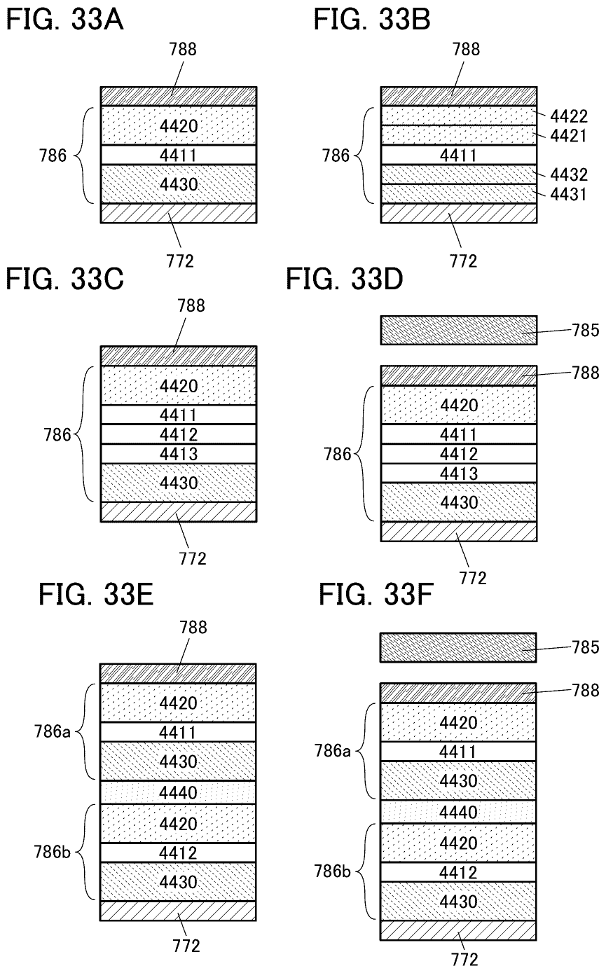

As illustrated in FIG. 33A, the light-emitting element includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance having a high electron-injection property (an electron-injection layer) and a layer containing a substance having a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can function as a single light-emitting unit, and the structure in FIG. 33A is referred to as a single structure in this specification.

FIG. 33B is a modification example of the EL layer 786 included in the light-emitting element illustrated in FIG. 33A. Specifically, the light-emitting element illustrated in FIG. 33B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. When the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layer structure, carriers can be efficiently injected to the light-emitting layer 4411, and the efficiency of the recombination of carriers in the light-emitting layer 4411 can be enhanced.

Note that a structure in which a plurality of light-emitting layers (the light-emitting layer 4411, a light-emitting layer 4412, and a light-emitting layer 4413) are provided between the layer 4420 and the layer 4430 as illustrated in FIG. 33C and FIG. 33D is a variation of the single structure.

A structure in which a plurality of light-emitting units (an EL layer 786a and an EL layer 786b) are connected in series with a charge-generation layer 4440 therebetween as illustrated in FIG. 33E and FIG. 33F is referred to as a tandem structure in this specification. Note that a tandem structure may be referred to as a stack structure. Note that the tandem structure enables a light-emitting element to emit light at high luminance.

In FIG. 33C and FIG. 33D, light-emitting materials that emit the same light or the same material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 33D.

Alternatively, light-emitting materials that emit light of different colors may be used for the light-emitting layer 4411, the light-emitting layer 4412, and the light-emitting layer 4413. White light emission can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 33D. When white light passes through the color filter, light of a desired color can be obtained.

In FIG. 33E and FIG. 33F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when the light-emitting layer 4411 and the light-emitting layer 4412 emit light of complementary colors. FIG. 33F illustrates an example in which the layer 785 is further provided. One or both of a color conversion layer and a color filter (coloring layer) can be used as the layer 785.

In FIG. 33C, FIG. 33D, FIG. 33E, and FIG. 33F, the layer 4420 and the layer 4430 may each have a stacked-layer structure of two or more layers as illustrated in FIG. 33B.

A structure in which light-emitting elements that emit light of different colors (e.g., blue (B), green (G), and red (R)) are separately formed is referred to as an SBS (Side By Side) structure in some cases.

The emission color of the light-emitting element can be red, green, blue, cyan, magenta, yellow, white, or the like depending on the material that constitutes the EL layer 786. Furthermore, the color purity can be further increased when the light-emitting element has a microcavity structure.

The light-emitting element that emits white light preferably contains two or more kinds of light-emitting substances in the light-emitting layer. To obtain white light emission, two or more light-emitting substances are selected such that their emission colors are complementary colors. For example, when the emission color of a first light-emitting layer and the emission color of a second light-emitting layer have a relationship of complementary colors, it is possible to obtain the light-emitting element which emits white light as a whole. The same applies to a light-emitting element including three or more light-emitting layers.

The light-emitting layer preferably contains two or more kinds selected from light-emitting substances that emit light of R (red), G (green), B (blue), Y (yellow), O (orange), and the like.

At least part of the structure examples, the drawings corresponding thereto, and the like described in this embodiment as an example can be combined with the other structure examples, the other drawings, and the like as appropriate.

At least part of this embodiment can be implemented in combination with the other embodiments or an example described in this specification as appropriate.

### Embodiment 6

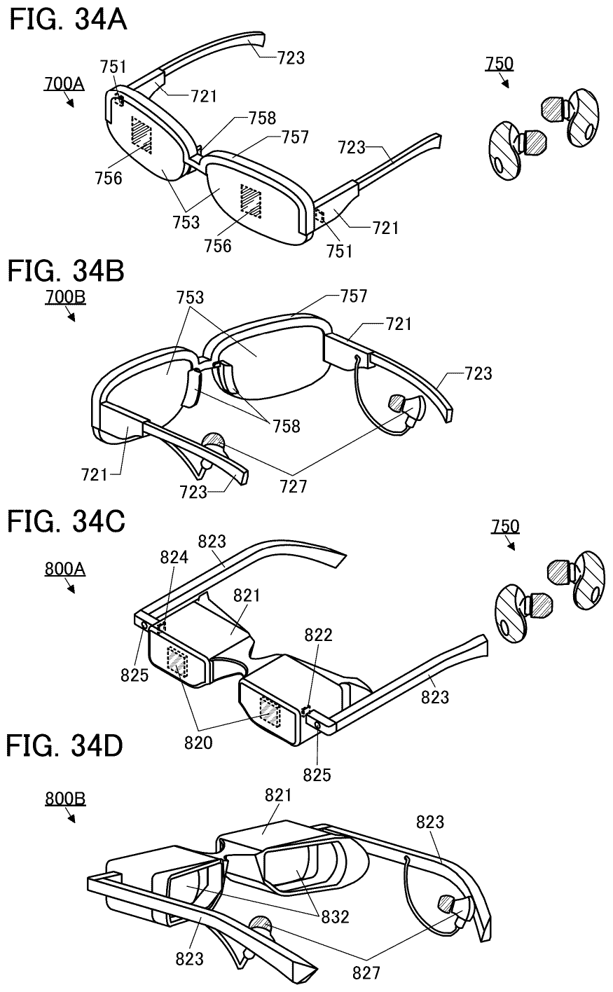

In this embodiment, electronic devices of one embodiment of the present invention are described with reference to FIG. 34 to FIG. 37.

Electronic devices of this embodiment each include the display device of one embodiment of the present invention in a display portion. The display device of one embodiment of the present invention can be easily increased in resolution and definition. In addition, the display device of one embodiment of the present invention has high reliability. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display device of one embodiment of the present invention can have a high resolution, and thus can be suitably used for an electronic device having a relatively small display portion. Examples of such an electronic device include a watch-type or a bracelet-type information terminal device (wearable device), and a wearable device that can be worn on a head, such as a device for VR such as a head mounted display, a glasses-type device for AR, and a device for MR.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. Furthermore, the pixel density (resolution) of the display device of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display device with one or both of high resolution and high definition, the electronic device can have higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 34A to FIG. 34D. These wearable devices have one or both of a function of displaying AR contents and a function of displaying VR contents. Note that these wearable devices may have a function of displaying SR or MR contents, in addition to AR and VR contents. The electronic device having a function of displaying contents of AR, VR, SR, MR, or the like enables the user to reach a higher level of immersion.

An electronic device 700A illustrated in FIG. 34A and an electronic device 700B illustrated in FIG. 34B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when each of the electronic device 700A and the electronic device 700B is provided with an acceleration sensor such as a gyroscope sensor, the orientation of the user's head can be sensed and an image corresponding to the orientation can be displayed on the display region 756.

The communication portion includes a wireless communication device, and a picture signal, for example, can be supplied by the wireless communication device. Note that instead of or in addition to the wireless communication device, a connector to which a cable for supplying a picture signal and a power supply potential can be connected may be provided.

In addition, each of the electronic device 700A and the electronic device 700B is provided with a battery so that each of the electronic device 700A and the electronic device 700B can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

Various touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 34C and an electronic device 800B illustrated in FIG. 34D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic device can perform display with extremely high resolution. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. Note that FIG. 34C illustrates an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is shown here, a range sensor capable of measuring a distance between the user and an object (hereinafter also referred to as a sensing portion) may be provided. In other words, the image capturing portion 825 is one embodiment of the sensing portion. For the sensing portion, an image sensor or a distance image sensor such as LIDAR (Light Detection and Ranging) can be used, for example. With the use of images obtained by the camera and images obtained by the range image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A illustrated in FIG. 34A has a function of transmitting information to the earphones 750 with the wireless communication function. As another example, the electronic device 800A illustrated in FIG. 34C has a function of transmitting information to the earphones 750 with the wireless communication function.

The electronic device may include an earphone portion. The electronic device 700B illustrated in FIG. 34B includes earphone portions 727. For example, the earphone portion 727 and the control portion can be connected to each other by wire. Part of a wiring that connects the earphone portions 727 and the control portion may be positioned inside the housing 721 or the wearing portion 723.

Similarly, the electronic device 800B illustrated in FIG. 34D includes earphone portions 827. For example, the earphone portion 827 and the control portion 824 can be connected to each other by wire. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (the electronic device 700A, the electronic device 700B, or the like) and the goggles-type device (the electronic device 800A, the electronic device 800B, or the like) are suitable for the electronic device of one embodiment of the present invention.

The electronic device of one embodiment of the present invention can transmit information to earphones by wire or wirelessly.

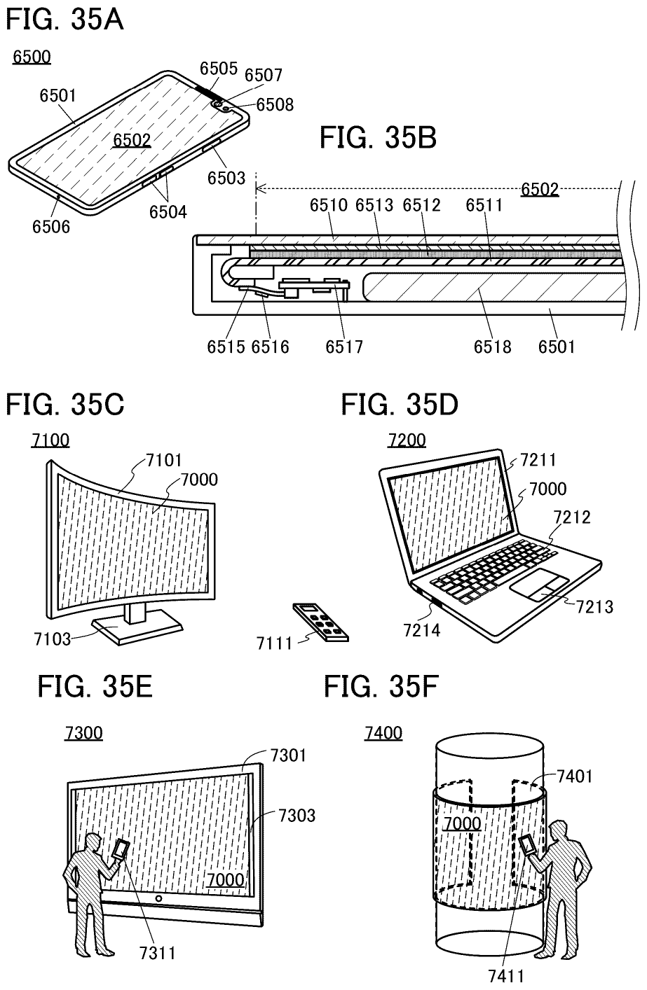

An electronic device 6500 illustrated in FIG. 35A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 35B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 35C illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 35C can be performed with an operation switch provided in the housing 7101 and a separate remote control 7111. Alternatively, the display portion 7000 may include a touch sensor, and the television device 7100 may be operated by a touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 35D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 35E and FIG. 35F illustrate examples of digital signage.

Digital signage 7300 illustrated in FIG. 35E includes a housing 7301, the display portion 7000, a speaker 7303, and the like. Furthermore, the digital signage can include an LED lamp, operation keys (including a power switch or an operation switch), a connection terminal, a variety of sensors, a microphone, and the like.

FIG. 35F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 35E and FIG. 35F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 35E and FIG. 35F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

Furthermore, it is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

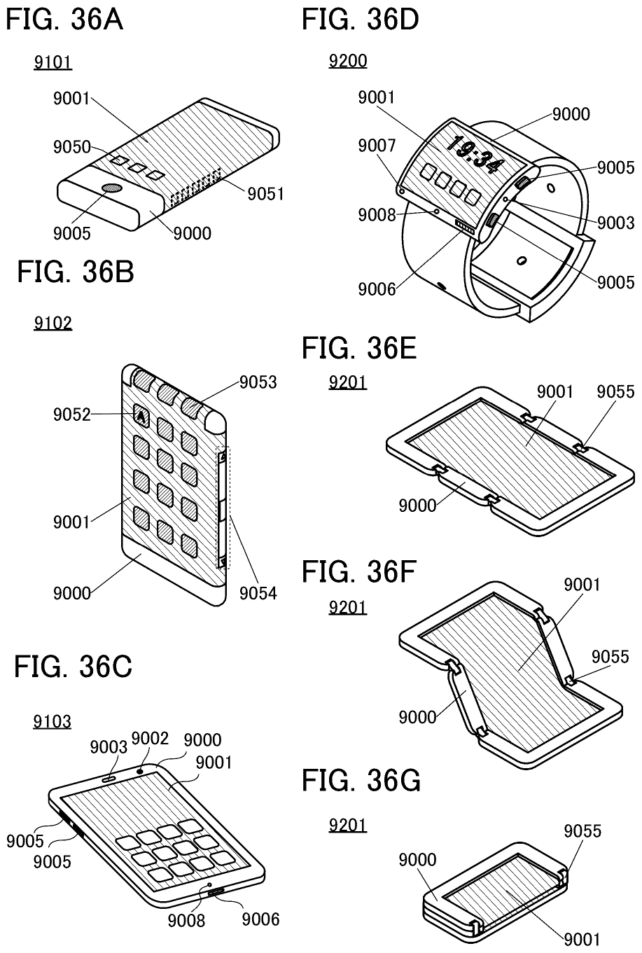

Electronic devices illustrated in FIG. 36A to FIG. 36G include a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 36A to FIG. 36G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each include a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 36A to FIG. 36G are described in detail below.

FIG. 36A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 36A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 36B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 36C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 36D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 36E to FIG. 36G are perspective views illustrating a foldable portable information terminal 9201. FIG. 36E is a perspective view of an opened state of the portable information terminal 9201, FIG. 36G is a perspective view of a folded state thereof, and FIG. 36F is a perspective view of a state in the middle of change from one of FIG. 36E and FIG. 36G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

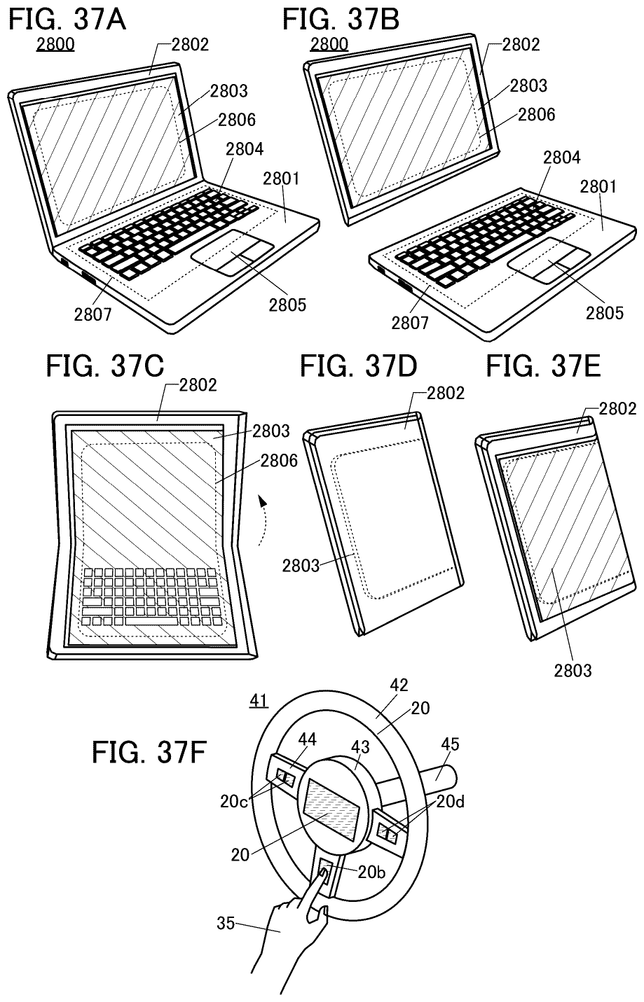

A personal computer 2800 illustrated in FIG. 37A includes a housing 2801, a housing 2802, a display portion 2803, a keyboard 2804, a pointing device 2805, and the like. A secondary battery 2807 is provided inside the housing 2801, and a secondary battery 2806 is provided inside the housing 2802. The display portion 2803 includes the display device of one embodiment of the present invention, and has a touch panel function. As illustrated in FIG. 37B, the housing 2801 and the housing 2802 of the personal computer 2800 can be detached and the housing 2802 can be used alone as a tablet terminal.

In a modification example of a personal computer illustrated in FIG. 37C, a flexible display is employed for the display portion 2803. With use of a flexible film as an exterior body, the secondary battery 2806 can be a bendable secondary battery. Accordingly, the housing 2802, the display portion 2803, and the secondary battery 2806 can be used in a bent state as illustrated in FIG. 37C. In that case, part of the display portion 2803 can be used as a keyboard as illustrated in FIG. 37C.

Furthermore, the housing 2802 can be folded such that the display portion 2803 is placed inward as illustrated in FIG. 37D, and the housing 2802 can be folded such that the display portion 2803 faces outward as illustrated in FIG. 37E.

FIG. 37F is a perspective view of a steering wheel of a vehicle. A steering wheel 41 includes a rim 42, a hub 43, spokes 44, a shaft 45, and the like. A display portion 20 is provided on the surface of the hub 43. The number of spokes 44 here is three. The spoke 44 located on the lower side is provided with a light-receiving and light-emitting portion 20b; the spoke 44 located on the left side is provided with a plurality of light-receiving and light-emitting portions 20c; and the spoke 44 located on the right side is provided with a plurality of light-receiving and light-emitting portions 20d. When a driver holds a finger of a hand 35 over the light-receiving and light-emitting portion 20b, information on a fingerprint of the driver is obtained, and user authentication can be performed with the information. Touching the light-receiving and light-emitting portions 20c, the light-receiving and light-emitting portions 20d, and the like, the driver can operate a navigation system, an audio system, a call system, and the like included in the vehicle. In addition, a variety of operations such as adjustment of a rearview mirror and a sideview mirror, turning on/off of an interior light, adjustment of luminance, and opening/closing a window are possible.

At least part of the structure examples, the drawings corresponding thereto, and the like described in this embodiment as an example can be combined with the other structure examples, the other drawings, and the like as appropriate.

At least part of this embodiment can be implemented in combination with the other embodiments or an example described in this specification as appropriate.

### Example 1

In this example, a result of fabricating a sample including the EL layer 112R and the EL layer 112G described in Embodiment 1 is described.

In this example, through steps illustrated in FIG. 9A to FIG. 9D1, the sample including the pixel electrode 111R, the pixel electrode 111G, the EL layer 112R, the EL layer 112G, the sacrificial layer 145Ra, the sacrificial layer 145Ga, the sacrificial layer 145Rb, and the sacrificial layer 145Gb illustrated in FIG. 10A was fabricated. Here, the pixel electrode 111R and the pixel electrode 111G each had a structure in which a titanium layer, an aluminum layer, a titanium layer, and an indium tin oxide layer containing silicon were stacked in this order from the bottom. A target thickness of the EL film 112Rf to be the EL layer 112R was 120 nm, and a target thickness of the EL film 112Gf to be the EL layer 112G was 95 nm. The sacrificial layer 145Ra and the sacrificial layer 145Ga were each an aluminum oxide formed by an ALD method. Furthermore, the sacrificial layer 145Rb and the sacrificial layer 145Gb were each tungsten formed by a sputtering method.

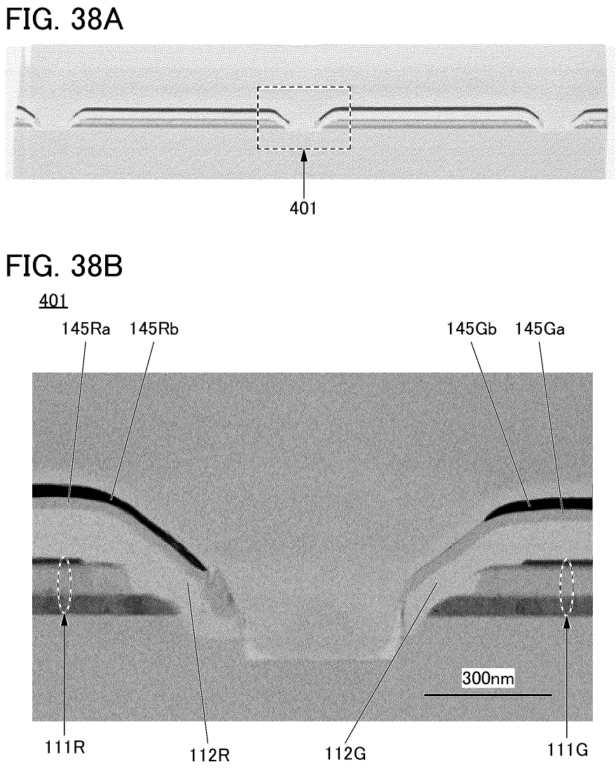

FIG. 38A is a STEM (Scanning Transmission Electron Microscope) image of a cross section of the fabricated sample. FIG. 38B is an enlarged view of a region 401 shown in FIG. 38A. As shown in FIG. 38B, it was confirmed that the sacrificial layer 145a and the sacrificial layer 145b do not remain in a region between the EL layer 112R and the EL layer 112G. Thus, it was suggested that a highly reliable display device can be fabricated by a method for manufacturing a display device of one embodiment of the present invention.

At least part of this example can be implemented in combination with any of the other embodiments or examples described in this specification as appropriate.

### Example 2

In this example, description is made on a fabrication of a display panel including a display device of one embodiment of the present invention and results of performed display.

In this example, the display panel including a display device having the structure illustrated in FIG. 3C was fabricated. Table 1 shows specifications of the fabricated display panel. Here, “H” means the horizontal direction and, for example, corresponds to the X direction illustrated in FIG. 1. “V” means the vertical direction and, for example, corresponds to the Y direction illustrated in FIG. 1. Furthermore, “L” means the channel length, and “W” means the channel width.

TABLE 1

| | |
|---|---|
| Size | 1.50 inches (diagonal size) |
| | 30.41 mm (H) × 22.81 mm (V) |
| Pixel number | 3840 (H) × 2880 (V) |
| Pixel density | 3207 ppi |
| Pixel pitch | 7.92 μm (H) × 7.92 μm (V) |
| Pixel | RGB S-stripe |
| arrangement | |
| Aperture ratio | 42.4% (designed value) |
| Frame | 120 Hz |
| frequency | |
| Transistor | OS transistor (L = 200 nm, W = 60 nm, |
| | withstand voltage >10 V) |

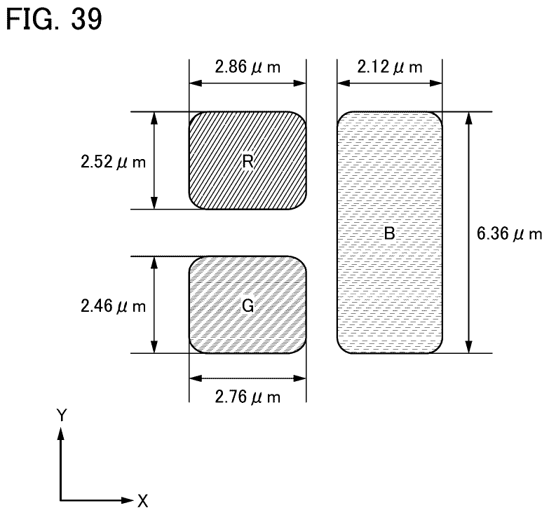

FIG. 39 is a plan view illustrating a structure of a pixel included in the fabricated display panel. FIG. 39 illustrates the lengths of a red subpixel R, a green subpixel G, and a blue subpixel B in the X direction and the Y direction.

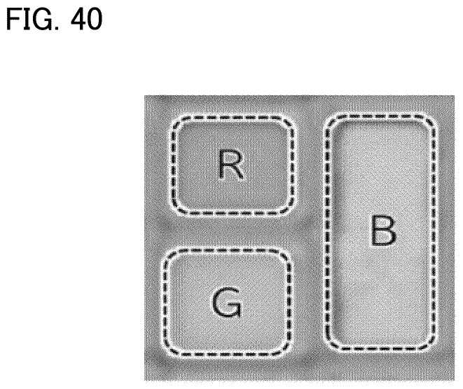

FIG. 40 is an optical micrograph of the subpixel R, the subpixel G, and the subpixel B. As shown in FIG. 40, it was confirmed that a pixel in S-stripe arrangement was fabricated.

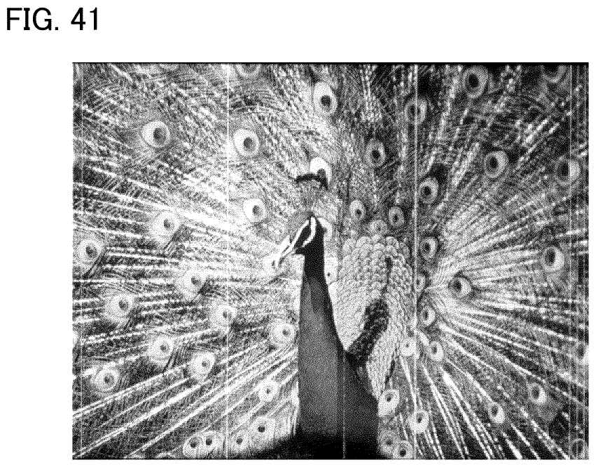

FIG. 41 is a display photograph of the fabricated display panel. It was confirmed that an image with extremely high resolution can be displayed by a separate coloring method without using a metal mask. Here, FIG. 41 is a full-color image.

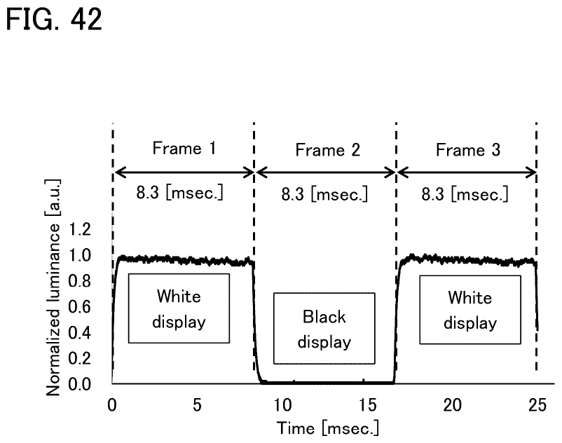

FIG. 42 is a graph showing the display results of the fabricated display panel and is a graph showing a change over time in normalized luminance. In this example, displays for three frames were performed, and white display was performed in Frame 1 and Frame 3. In addition, black display was performed in Frame 2. The maximum luminance of the normalized luminance in the displays for three frames was set to 1.

It was confirmed that almost no light emission was observed in black display as compared with that in white display, and light leakage at the time of black display was extremely small as shown in FIG. 42.

In this example, the spectrum of the fabricated display panel was measured. The wavelength dependence of spectral radiance was measured in states where all the pixels of the display panel display each of red (R), green (G), and blue (B). Specifically, displays for red, green, and blue were performed at 42.8 cd/m² and 0.35 cd/m², 147 cd/m² and 0.85 cd/m², and 19.9 cd/m² and 0.18 cd/m², respectively.

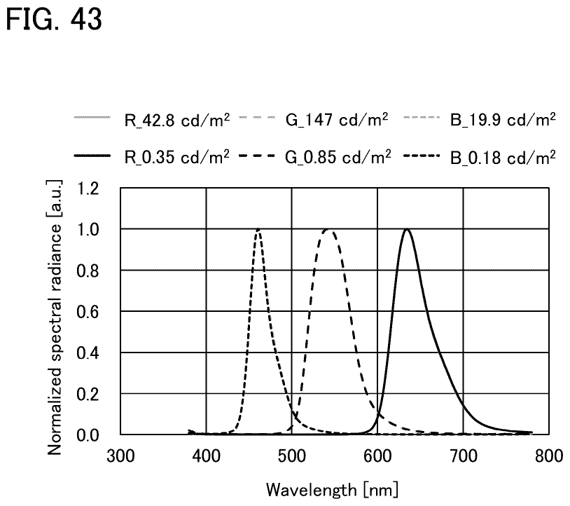

FIG. 43 is a graph showing measurement results of the wavelength dependence of a normalized spectral radiance. The maximum luminance of the normalized spectral radiance for each spectrum was 1.

It was confirmed that R, G, and B each had a small half width and almost no overlap among spectra of the colors were observed, as illustrated in FIG. 43. In addition, it was confirmed that the spectra of R, G, and B hardly depend on the luminance.

At least part of this example can be implemented in combination with any of the other embodiments or examples described in this specification as appropriate.

### REFERENCE NUMERALS

20b: light-receiving and light-emitting portion, 20c: light-receiving and light-emitting portion, 20d: light-receiving and light-emitting portion, 20: display portion, 35: hand, 41: steering wheel, 42: rim, 43: hub, 44: spoke, 45: shaft, 100A: display device, 100C: display device, 100D: display device, 100E: display device, 100F: display device, 100G: display device, 100: display device, 101: insulating layer, 102a: conductive layer, 102b: conductive layer, 103: insulating layer, 104: insulating layer, 105: insulating layer, 106: plug, 107: pixel portion, 108: pixel, 110B: subpixel, 110G: subpixel, 110R: subpixel, 110W: subpixel, 110: subpixel, 111B: pixel electrode, 111G: pixel electrode, 111R: pixel electrode, 111: pixel electrode, 112B: EL layer, 112Bf: EL film, 112f: EL film, 112G: EL layer, 112Gf: EL film, 112R: EL layer, 112Rf: EL film, 112: EL layer, 113: connection electrode, 114: common layer, 115: common electrode, 117: light-blocking layer, 120: substrate, 121: protective layer, 122: resin layer, 123: conductive layer, 124a: pixel, 124b: pixel, 125f: insulating film, 125: insulating layer, 126: insulating layer, 127f: protective film, 127: protective layer, 128: layer, 129: conductive layer, 130B: light-emitting element, 130G: light-emitting element, 130R: light-emitting element, 130: light-emitting element, 131a: region, 131b: region, 132: region, 133: upper end portion, 134: upper end portion, 138: region, 140: connection portion, 141: region, 142: adhesive layer, 143a: resist mask, 143b: resist mask, 143c: resist mask, 143: resist mask, 144a: sacrificial film, 144b: sacrificial film, 144Ba: sacrificial film, 144Bb: sacrificial film, 144Ga: sacrificial film, 144Gb: sacrificial film, 144Ra: sacrificial film, 144Rb: sacrificial film, 144: sacrificial film, 145a: sacrificial layer, 145b: sacrificial layer, 145Ba: sacrificial layer, 145Bb: sacrificial layer, 145G: sacrificial layer, 145Ga: sacrificial layer, 145Gb: sacrificial layer, 145R: sacrificial layer, 145Ra: sacrificial layer, 145Rb: sacrificial layer, 145: sacrificial layer, 146: protective layer, 147: resist mask, 151: protective layer, 152: substrate, 153: substrate, 164: circuit, 165: wiring, 166: conductive layer, 172: FPC, 173: IC, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 401: region, 700A: electronic device, 700B: electronic device, 721: housing, 723: wearing portion, 727: earphone portion, 750: earphone, 751: display panel, 753: optical member, 756: display region, 757: frame, 758: nose pad, 772: lower electrode, 785: layer, 786a: EL layer, 786b: EL layer, 786: EL layer, 788: upper electrode, 800A: electronic device, 800B: electronic device, 820: display portion, 821: housing, 822: communication portion, 823: wearing portion, 824: control portion, 825: image capturing portion, 827: earphone portion, 832: lens, 2800: personal computer, 2801: housing, 2802: housing, 2803: display portion, 2804: keyboard, 2805: pointing device, 2806: secondary battery, 2807: secondary battery, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising a first light-emitting element and a second light-emitting element adjacent to the first light-emitting element,
wherein the first light-emitting element comprises a first pixel electrode, a first EL layer over the first pixel electrode, and a common electrode over the first EL layer,
wherein the second light-emitting element comprises a second pixel electrode, a second EL layer over the second pixel electrode, and the common electrode over the second EL layer,
wherein each of an end portion of the first pixel electrode and an end portion of the second pixel electrode has a tapered shape,
wherein the first EL layer covers the end portion of the first pixel electrode,
wherein the second EL layer covers the end portion of the second pixel electrode, and
wherein the first EL layer comprises a region where a thickness is less than or equal to 150 nm.

2. The display device according to claim 1,
wherein the first light-emitting element comprises a common layer between the first EL layer and the common electrode,
wherein the second light-emitting element comprises the common layer between the second EL layer and the common electrode, and
wherein a region between a top surface of the first pixel electrode and a bottom surface of the common layer comprises a portion having a distance less than or equal to 150 nm.

3. A display device comprising a first light-emitting element and a second light-emitting element adjacent to the first light-emitting element,
wherein the first light-emitting element comprises a first pixel electrode, a first EL layer over the first pixel electrode, and a common electrode over the first EL layer,
wherein the second light-emitting element comprises a second pixel electrode, a second EL layer over the second pixel electrode, and the common electrode over the second EL layer,
wherein an end portion of the first pixel electrode and an end portion of the second pixel electrode each have a tapered shape,
wherein the first EL layer covers the end portion of the first pixel electrode,
wherein the second EL layer covers the end portion of the second pixel electrode, and
wherein a region between a thickness of the first EL layer and a thickness of the second EL layer comprises a portion having a distance less than or equal to 100 nm.

4. The display device according to claim 3,
wherein the first light-emitting element comprises a common layer between the first EL layer and the common electrode,
wherein the second light-emitting element comprises the common layer between the second EL layer and the common electrode, and
wherein the display device comprises a region where a difference between a distance between a top surface of the first pixel electrode and a bottom surface of the common layer and a distance between a top surface of the second pixel electrode and the bottom surface of the common layer is less than or equal to 100 nm.

5. The display device according to claim 2, wherein the common layer comprises a carrier-injection layer.

6. The display device according to claim 1, wherein an insulating layer is provided in a region between the first EL layer and the second EL layer.

7. The display device according to claim 6, wherein the insulating layer comprises an organic material.

8. The display device according to claim 1, further comprising a pixel portion and a connection portion,
wherein the pixel portion comprises the first light-emitting element and the second light-emitting element,
wherein the connection portion comprises a connection electrode and the common electrode which is over the connection electrode and electrically connected to the connection electrode,
wherein a third EL layer is in a region between the pixel portion and the connection portion, and
wherein an end portion of the connection electrode and an end portion of the third EL layer are covered with a protective layer.

9. A display module comprising:
the display device according to claim 1; and
at least one of a connector and an integrated circuit.

10. An electronic device comprising:
the display module according to claim 9; and
at least one of a battery, a camera, a speaker and a microphone.

11. A method for manufacturing a display device, comprising:
forming a first pixel electrode and a second pixel electrode adjacent to the first pixel electrode so as to have tapered end portions;
forming a first EL film over the first pixel electrode and the second pixel electrode;
forming a first sacrificial film over the first EL film;
forming a first EL layer covering the end portion of the first pixel electrode and comprising a region where a thickness is less than or equal to 150 nm, and a first sacrificial layer over the first EL layer by processing the first EL film and the first sacrificial film;
forming a second EL film over the first sacrificial layer and over the second pixel electrode;
forming a second sacrificial film over the second EL film;
forming a second EL layer covering the end portion of the second pixel electrode, and a second sacrificial layer over the second EL layer by processing the second EL film and the second sacrificial film;
removing at least a part of the first sacrificial layer and at least a part of the second sacrificial layer; and
forming a common electrode over the first EL layer and over the second EL layer.

12. The method for manufacturing a display device, according to claim 11, comprising the steps of:
forming a common layer over the first EL layer and over the second EL layer after at least the part of the first sacrificial layer and at least the part of the second sacrificial layer are removed; and
forming the common electrode over the common layer,
wherein a region between a top surface of the first pixel electrode and a bottom surface of the common layer comprises a portion having a distance less than or equal to 150 nm.

13. A method for manufacturing a display device, comprising:
forming a first pixel electrode and a second pixel electrode adjacent to the first pixel electrode so as to have tapered end portions;
forming a first EL film over the first pixel electrode and the second pixel electrode;
forming a first sacrificial film over the first EL film;
forming a first EL layer covering the end portion of the first pixel electrode, and a first sacrificial layer over the first EL layer by processing the first EL film and the first sacrificial film;
forming a second EL film over the first sacrificial layer and over the second pixel electrode;
forming a second sacrificial film over the second EL film;
forming a second EL layer covering the end portion of the second pixel electrode and comprising a region where a difference from a thickness of the first EL layer is less than or equal to 100 nm, and a second sacrificial layer over the second EL layer by processing the second EL film and the second sacrificial film;
removing at least a part of the first sacrificial layer and at least a part of the second sacrificial layer; and
forming a common electrode over the first EL layer and over the second EL layer.

14. The method for manufacturing a display device, according to claim 13, comprising the steps of:
forming a common layer over the first EL layer and the second EL layer after at least the part of the first sacrificial layer and at least the part of the second sacrificial layer are removed; and
forming the common electrode over the common layer,
wherein a region where a difference between a distance between a top surface of the first pixel electrode and a bottom surface of the common layer and a distance between a top surface of a second pixel electrode and the bottom surface of the common layer is less than or equal to 100 nm is included in the display device.

15. The method for manufacturing a display device, according to claim 12, wherein the common layer comprises a carrier-injection layer.

16. The method for manufacturing a display device, according to claim 11, further comprising the step of forming an insulating layer in a region between the first EL layer and the second EL layer after the first sacrificial layer and the second sacrificial layer are formed and before said at least part of the first sacrificial layer and said at least part of the second sacrificial layer are removed.

17. The method for manufacturing a display device, according to claim 16, wherein the insulating layer is formed using a spin coating method, a spraying method, a screen printing method or a painting method.

18. The method for manufacturing a display device, according to claim 11, further comprising the step of forming a conductive film,
wherein the first pixel electrode, the second pixel electrode, and a connection electrode is formed so as to have tapered end portions by processing the conductive film,
wherein the first sacrificial film is formed so as to cover an end portion of the first EL film after the first EL film is formed,
wherein a third EL layer and a third sacrificial layer that covers an end portion of the connection electrode and an end portion of the third EL layer is formed in a region between the first pixel electrode and the second pixel electrode and the connection electrode by processing the first EL film and the first sacrificial film,
wherein at least a part of a region of the third sacrificial layer that overlaps with the connection electrode is removed in parallel with a removal of at least the part of the first sacrificial layer and at least the part of the second sacrificial layer, and
wherein the common electrode is formed over the connection electrode.

19. The method for manufacturing a display device, according to claim 18, wherein the common electrode is not electrically connected to the third EL layer.
